(19) United States
(12) Patent Application Publication
(10) Pub. No.: US 2015/0236265 A1
(43) Pub. Date: Aug. 20, 2015

(54) INDENE-BASED COMPOUNDS AND ORGANIC LIGHT-EMITTING DEVICES COMPRISING THE SAME

(71) Applicants: Samsung Display Co., Ltd., Yongin-City (KR); Sungkyunkwan University Research & Business Foundation, Suwon-si (KR)

(72) Inventors: Jin-Soo Hwang, Yongin-City (KR); Myeong-Suk Kim, Yongin-City (KR); Sung-Wook Kim, Yongin-City (KR); Jae-Hong Kim, Yongin-City (KR); Seung-Soo Yoon, Suwon-si (KR)

(21) Appl. No.: 14/335,673

(22) Filed: Jul. 18, 2014

(30) Foreign Application Priority Data
Feb. 14, 2014 (KR) 10-2014-0017521

(51) Int. Cl. H01L 51/00; H01L 51/50

(52) U.S. Cl. CPC H01L 51/0058; H01L 51/0074; H01L 51/0052; H01L 51/5012; H01L 51/5056; H01L 51/5088; H01L 51/5072; H01L 51/5092; H01L 51/5096

(57) ABSTRACT

An indene-based compound and an organic light-emitting device including the same, the compound being represented by Formula 1:

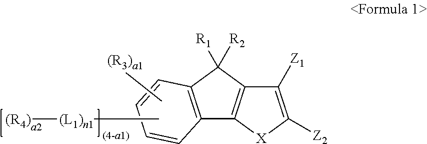

### CROSS-REFERENCE TO RELATED APPLICATIONS

This application claims the benefit of Korean Patent Application No. 10-2014-0017521, filed on Feb. 14, 2014, in the Korean Intellectual Property Office, the disclosure of which is incorporated herein in its entirety by reference.

### BACKGROUND

1. Field

One or more embodiments of the present disclosure relate to indene-based compounds and organic light-emitting devices including the indene-based compounds.

2. Description of the Related Art

Organic light-emitting devices (OLEDs), which are self-emitting devices, have advantages such as wide viewing angles, excellent contrast, quick response, high brightness, excellent driving voltage characteristics, and can provide multicolored images.

A typical OLED has a structure including a substrate, and an anode, a hole transport layer (HTL), an emission layer (EML), an electron transport layer (ETL), and a cathode which are sequentially stacked on the substrate. In this regard, the HTL, the EML, and the ETL are organic thin films comprising organic compounds.

An operating principle of an OLED having the above-described structure is as follows.

When a voltage is applied between the anode and the cathode, holes injected from the anode move to the EML via the HTL, and electrons injected from the cathode move to the EML via the ETL. The holes and electrons recombine in the EML to generate excitons. When the excitons drop from an excited state to a ground state, light is emitted.

### SUMMARY

One or more embodiments include a high-quality organic light-emitting device.

Additional aspects will be set forth in part in the description which follows and, in part, will be apparent from the description, or may be learned by practice of the presented embodiments.

According to one or more embodiments of the present disclosure, there is provided an indene-based compound represented by Formula 1:

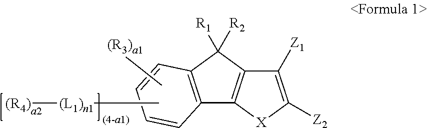

wherein, in Formula 1,

X is an oxygen atom, a sulfur atom, NQ₁, or CQ₂Q₃;

L₁ is selected from a substituted or unsubstituted C₃-C₁₀ cycloalkylene group, a substituted or unsubstituted C₃-C₁₀ cycloalkenylene group, a substituted or unsubstituted C₆-C₆₀ arylene group, a substituted or unsubstituted C₁-C₁₀ heterocycloalkylene group, a substituted or unsubstituted heterocycloalkenylene group, and a substituted or unsubstituted C₁-C₆₀ heteroarylene group;

n1 is an integer of 0 to 6, and when n1 is an integer of 2 or greater, a plurality of L₁s are identical to or different to each other, and are optionally linked to each other to form a substituted or unsubstituted C₆-C₂₀ saturated ring or a substituted or unsubstituted C₆-C₂₀ unsaturated ring;

Z₁, Z₂, R₁, and R₂ are each independently selected from a hydrogen, a deuterium, —F, —Cl, —Br, —I, a hydroxyl group, a cyano group, a nitro group, an amino group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₃-C₃₀ cycloalkyl group, a substituted or unsubstituted C₃-C₃₀ cycloalkenyl group, a substituted or unsubstituted C₆-C₃₀ aryl group, a substituted or unsubstituted C₆-C₃₀ aryloxy group, a substituted or unsubstituted C₆-C₃₀ arylthio group, and a substituted or unsubstituted C₁-C₃₀ heteroaryl group; and R₁ and R₂ are optionally linked to each other to form a substituted or unsubstituted C₆-C₂₀ saturated ring, or a substituted or unsubstituted C₆-C₂₀ unsaturated ring; and Z₁ and Z₂ are optionally linked to each other to form a substituted or unsubstituted C₆-C₂₀ saturated ring or a substituted or unsubstituted C₆-C₂₀ unsaturated ring;

R₃, R₄, and Q₁ to Q₃ are each independently selected from a hydrogen, a deuterium, —F, —Cl, —Br, —I, a hydroxyl group, a cyano group, a nitro group, an amino group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₃-C₃₀ cycloalkyl group, a substituted or unsubstituted C₃-C₃₀ cycloalkenyl group, a substituted or unsubstituted C₆-C₃₀ aryl group, a substituted or unsubstituted C₆-C₃₀ aryloxy group, a substituted or unsubstituted C₆-C₃₀ arylthio group, and a substituted or unsubstituted C₁-C₃₀ heteroaryl group; and

a1 and a2 are each independently an integer of 0 to 3.

According to one or more embodiments of the present disclosure, an organic light-emitting device includes: a first electrode; a second electrode disposed opposite to the first electrode; and an organic layer disposed between the first electrode and the second electrode and including an emission layer, wherein the organic layer includes at least one of the indene-based compounds of Formula 1 defined above.

### BRIEF DESCRIPTION OF THE DRAWING

These and/or other aspects will become apparent and more readily appreciated from the following description of the embodiments, taken in conjunction with the accompanying drawing in which:

FIG. 1 is a schematic cross-sectional view of an organic light-emitting device according to an embodiment of the present disclosure.

### DETAILED DESCRIPTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

According to an embodiment of the present disclosure, there is provided an indene-based compound represented by Formula 1:

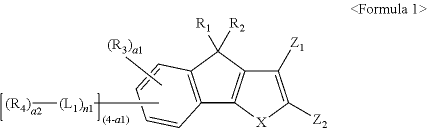

In Formula 1, X may be an oxygen atom (—O—), a sulfur atom (—S—), N(Q₁), or C(Q₂)(Q₃).

In some embodiments, in Formula 1, X may be —O— or —S—, but is not limited thereto. For example, in Formula 1, X may be —S—, but is not limited thereto.

In Formula 1, L₁ may be selected from a substituted or unsubstituted C₃-C₁₀ cycloalkylene group, a substituted or unsubstituted C₃-C₁₀ cycloalkenylene group, a substituted or unsubstituted C₆-C₆₀ arylene group, a substituted or unsubstituted C₁-C₁₀ heterocycloalkylene group, a substituted or unsubstituted C₁-C₁₀ heterocycloalkenylene group, and a substituted or unsubstituted C₁-C₆₀ heteroarylene group.

For example, L₁ in Formula 1 may be selected from, but is not limited to, a substituted or unsubstituted a phenylene group, a substituted or unsubstituted a pentalenylene group, a substituted or unsubstituted an indenylene group, a substituted or unsubstituted a naphthylene group, a substituted or unsubstituted an azulenylene group, a substituted or unsubstituted a heptalenylene group, a substituted or unsubstituted an indacenylene group, a substituted or unsubstituted an acenaphthylene group, a substituted or unsubstituted a fluorenylene group, a substituted or unsubstituted a spiro-fluorenylene group, a substituted or unsubstituted a phenalenylene group, a substituted or unsubstituted a phenanthrenylene group, a substituted or unsubstituted an anthracenylene group, a substituted or unsubstituted a fluoranthenylene group, a substituted or unsubstituted a triphenylenylene group, a substituted or unsubstituted a pyrenylene group, a substituted or unsubstituted a chrysenylene group, a substituted or unsubstituted a naphthacenylene group, a substituted or unsubstituted a picenylene group, a substituted or unsubstituted a perylenylene group, a substituted or unsubstituted a pentaphenylene group, a substituted or unsubstituted a hexacenylene group, a substituted or unsubstituted pyrrolylene group, a substituted or unsubstituted imidazolylene group, a substituted or unsubstituted pyrazolylene group, a substituted or unsubstituted pyridinylene group, a substituted or unsubstituted pyrazinylene group, a substituted or unsubstituted pyrimidinylene group, a substituted or unsubstituted pyridazinylene group, a substituted or unsubstituted isoindolylene group, a substituted or unsubstituted indolylene group, a substituted or unsubstituted indazolylene group, a substituted or unsubstituted a purinylene group, a substituted or unsubstituted quinolinylene group, a substituted or unsubstituted benzoquinolinylene group, a substituted or unsubstituted a phthalazinylene group, a substituted or unsubstituted a naphthyridinylene group, a substituted or unsubstituted quinoxalinylene group, a substituted or unsubstituted quinazolinylene group, a substituted or unsubstituted a cinnolinylene group, a substituted or unsubstituted a carbazolylene group, a substituted or unsubstituted phenanthridinylene group, a substituted or unsubstituted acridinylene group, a substituted or unsubstituted phenanthrolinylene group, a substituted or unsubstituted phenazinylene group, a substituted or unsubstituted benzooxazolylene group, a substituted or unsubstituted benzoimidazolylene group, a substituted or unsubstituted a furanylene group, a substituted or unsubstituted a benzofuranylene group, a substituted or unsubstituted a thiophenylene group, a substituted or unsubstituted a benzothiophenylene group, a substituted or unsubstituted thiazolylene group, a substituted or unsubstituted isothiazolylene group, a substituted or unsubstituted a benzothiazolylene group, a substituted or unsubstituted an isoxazolylene group, a substituted or unsubstituted oxazolylene group, a substituted or unsubstituted triazolylene group, a substituted or unsubstituted a tetrazolylene group, a substituted or unsubstituted oxadiazolylene group, a substituted or unsubstituted triazinylene group, a substituted or unsubstituted benzooxazolylene group, a substituted or unsubstituted a dibenzofuranylene group, a substituted or unsubstituted a dibenzothiophenylene group, and a substituted or unsubstituted a benzocarbazolyl group.

For example, in Formula 1, L₁ may be selected from, but is not limited to,

i) a phenylene group, a naphthylene group, an anthracenyl group, a fluorenylene group, a chrysenylene group, and a pyrenylene group; and

ii) a phenylene group, a naphthylene group, an anthracenyl group, a fluorenylene group, a chrysenylene group, and a pyrenylene group, each substituted with at least one of;

a deuterium, —F, —Cl, —Br, —I, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, and a C₁-C₁₀ alkyl group,

a C₁-C₁₀ alkyl group substituted with at least one of a deuterium, —F, —Cl, —Br, —I, a hydroxyl group, a cyano group, a nitro group, an amino group, an amidino group, a hydrazine, a hydrazone, a carboxylic acid group or a salt thereof, a sulfonic acid group or a salt thereof, and a phosphoric acid group or a salt thereof,

a C₆-C₁₆ aryl group and a C₁-C₁₆ heteroaryl group, and

a C₆-C₁₆ aryl group and a C₁-C₁₆ heteroaryl group, each substituted with at least one selected from a deuterium, —F, —Cl, —Br, —I, a hydroxyl group, a cyano group, a nitro group, an amino group, an amidino group, a hydrazine, a hydrazone, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, a C₆-C₁₆ aryl group, and a C₁-C₁₆ heteroaryl group.

For example, in Formula 1, L₁ may be selected from, but is not limited to,

i) a phenylene group, an anthracenyl group, a fluorenylene group, a chrysenylene group, and a pyrenylene group; and

ii) a phenylene group, an anthracenyl group, a fluorenylene group, a chrysenylene group, and a pyrenylene group, each substituted with at least one selected from

a deuterium, —F, —Cl, —Br, —I, a hydroxyl group, a cyano group, a nitro group, a methyl group, an ethyl group, an n-propyl group, an iso-propyl group, an n-butyl group, a sec-butyl group, an iso-butyl group, and a tert-butyl group,

a phenyl group, a naphthyl group, a pyridyl group, and a triazinyl group, and

a phenyl group, a naphthyl group, a pyridyl group, and a triazinyl group, each substituted with at least one selected from a deuterium, —F, —Cl, —Br, —I, a hydroxyl group, a cyano group, a nitro group, a methyl group, an ethyl group, an n-propyl group, an iso-propyl group, an n-butyl group, a sec-butyl group, an iso-butyl group, and a tert-butyl group.

For example, L₁ in Formula 1 may be selected from, but is not limited to, a phenylene group, an anthracenyl group, a chrysenylene group, and a pyrenylene group.

In Formula 1, n1, which indicates the number of L₁s, may be an integer of 0 to 6. When n1 is an integer of 2 or greater, a plurality of L₁s may be identical to or different from each other.

For example, in Formula 1 n1 may be an integer of 1 or 2, but is not limited thereto.

In Formula 1, when n1 is an integer of 2 or greater, a plurality of L₁s may be optionally linked to one another to form a substituted or unsubstituted C₆-C₂₀ saturated ring or a substituted or unsubstituted C₆-C₂₀ unsaturated ring.

For example, in Formula 1, (L₁)ₙ₁ may be a moiety represented by one of Formulae 2-1 to 2-4, but is not limited thereto:

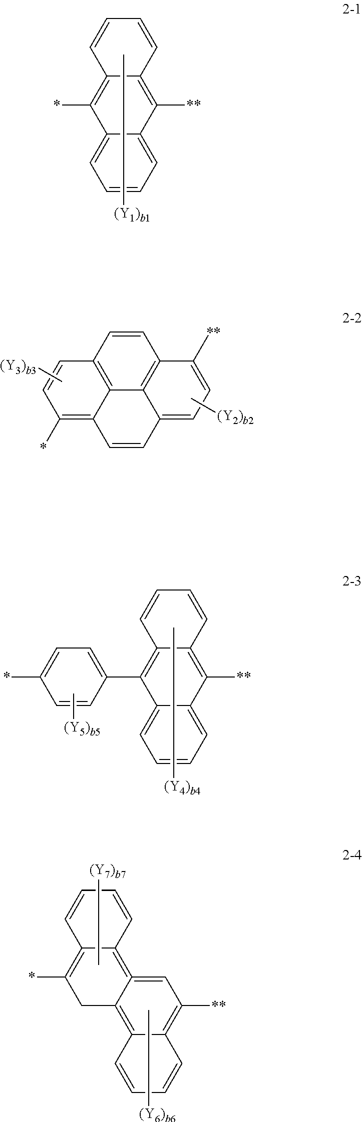

In Formulae 2-1 to 2-4, Y₁ to Y₇ may be each independently selected from

i) a hydrogen, a deuterium, —F, —Cl, —Br, —I, a hydroxyl group, a cyano group, a nitro group, a methyl group, an ethyl group, an n-propyl group, an iso-propyl group, an n-butyl group, a sec-butyl group, an iso-butyl group, and a tert-butyl group,

ii) a phenyl group, a naphthyl group, a pyridyl group, and an anthryl group, and

iii) a phenyl group, a naphthyl group, a pyridyl group, and a triazinyl group, each substituted with at least one of a deuterium, —F, —Cl, —Br, —I, a hydroxyl group, a cyano group, a nitro group, a methyl group, an ethyl group, an n-propyl group, an iso-propyl group, an n-butyl group, a sec-butyl group, an iso-butyl group, and a tert-butyl group;

b1 to b7 may be each independently an integer of 0 to 4; and

* indicates a binding site to R₄; and ** indicates a binding site to an indene-based core.

For example, in Formula 1, (L₁)ₙ₁ may be a moiety represented by one of Formulae 2-1 to 2-4, but is not limited thereto:

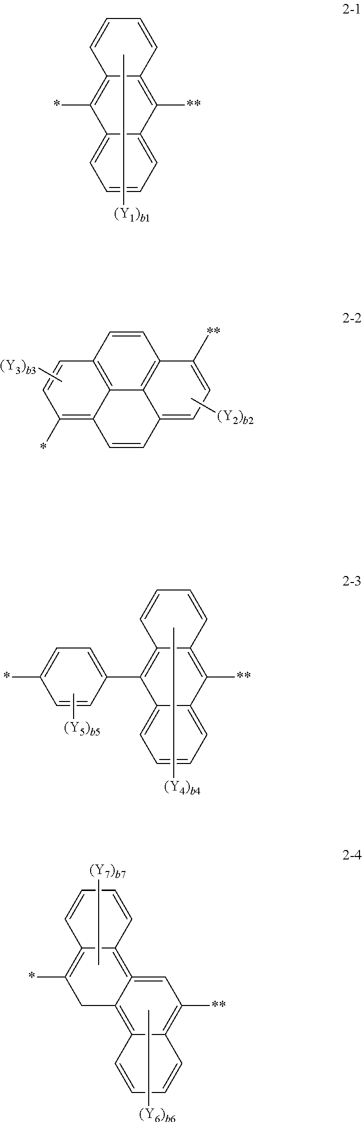

In Formulae 2-1 to 2-4,

Y₁ to Y₇ may be each independently selected from a hydrogen, a deuterium, —F, a cyano group, a nitro group, a methyl group, an ethyl group, an n-propyl group, an iso-propyl group, a tert-butyl group, a phenyl group, a naphthyl group, a pyridyl group, and a triazinyl group;

b1 to b7 may be each independently an integer of 0 or 1; and

* indicates a binding site to R₄; and ** indicates a binding site to an indene-based core.

For example, in Formula 1, (L₁)ₙ₁ may be a moiety represented by one of Formulae 3-1 to 3-4, but is not limited thereto:

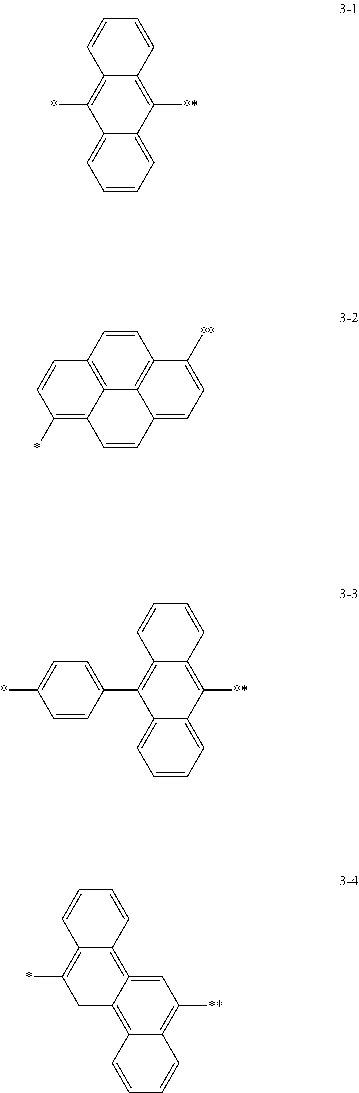

In Formulae 3-1 to 3-4, * indicates a binding site to R₄; and ** indicates a binding site to an indene-based core.

In Formula 1, Z₁, Z₂, R₁, and R₂ may be each independently selected from

a hydrogen, a deuterium, —F, —Cl, —Br, —I, a hydroxyl group, a cyano group, a nitro group, an amino group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₃-C₃₀ cycloalkyl group, a substituted or unsubstituted C₃-C₃₀ cycloalkenyl group, a substituted or unsubstituted C₆-C₃₀ aryl group, a substituted or unsubstituted C₆-C₃₀ aryloxy group, a substituted or unsubstituted C₆-C₃₀ arylthio group, and a substituted or unsubstituted C₁-C₃₀ heteroaryl group, and

R₁ and R₂ may be optionally linked to each other to form a substituted or unsubstituted C₆-C₂₀ saturated ring or a substituted or unsubstituted C₆-C₂₀ unsaturated ring, and

Z₁ and Z₂ may be optionally linked to each other to form a substituted or unsubstituted C₆-C₂₀ saturated ring or a substituted or unsubstituted C₆-C₂₀ unsaturated ring.

For example, in Formula 1, Z₁ and Z₂ may be each independently selected from a hydrogen, a deuterium, —F, —Cl, —Br, —I, a hydroxyl group, a cyano group, a nitro group, a substituted or unsubstituted C₁-C₁₀ alkyl group, a substituted or unsubstituted C₆-C₁₆ aryl group, and a substituted or unsubstituted C₁-C₃₀ heteroaryl group; and Z₁ and Z₂ may be optionally linked to each other to form a substituted or unsubstituted C₆-C₂₀ saturated ring or a substituted or unsubstituted C₆-C₂₀ unsaturated ring. However, embodiments of the present disclosure are not limited thereto.

For example, in Formula 1, Z₁ and Z₂ may be each independently selected from

i) a hydrogen, a deuterium, —F, —Cl, —Br, —I, a cyano group, a nitro group, a methyl group, an ethyl group, an n-propyl group, an iso-propyl group, an n-butyl group, a sec-butyl group, an iso-butyl group, and a tert-butyl group,

ii) a methyl group, an ethyl group, an n-propyl group, an iso-propyl group, an n-butyl group, a sec-butyl group, an iso-butyl group, and a tert-butyl group, each substituted with at least one of a deuterium, —F, —Cl, —Br, —I, a cyano group, and a nitro group,

iii) a phenyl group, a naphthyl group, an anthryl group, a pyridyl group, a pyrimidyl group, and a triazinyl group, and

iv) a phenyl group, a naphthyl group, an anthryl group, a pyridyl group, a pyrimidyl group, and a triazinyl group, each substituted with at least one of a deuterium, —F, —Cl, —Br, —I, a cyano group, a nitro group, a methyl group, an ethyl group, an n-propyl group, an iso-propyl group, an n-butyl group, a sec-butyl group, an iso-butyl group, and a tert-butyl group; or

Z₁ and Z₂ may be linked to each other to form a benzene ring, a naphthalene ring, or an anthracene ring, each substituted with at least one of a deuterium, —F, —Cl, —Br, —I, a cyano group, a nitro group, a methyl group, an ethyl group, an n-propyl group, an iso-propyl group, an n-butyl group, a sec-butyl group, an iso-butyl group, and a tert-butyl group. However, embodiments of the present disclosure are not limited thereto.

For example, in Formula 1, Z₁ and Z₂ may be each independently selected from

i) a hydrogen, a cyano group, and a methyl group,

ii) a phenyl group and a pyridyl group, and

iii) a phenyl group and a pyridyl group, each substituted with at least one of a deuterium, a cyano group, and a methyl group, or

Z₁ and Z₂ may be linked to each other to form a benzene ring substituted with at least one of a deuterium, a cyano group, and a methyl group. However, embodiments of the present disclosure are not limited thereto.

In some embodiments, in Formula 1, R₁ and R₂ may be each independently selected from a hydrogen, a deuterium, —F, —Cl, —Br, —I, a hydroxyl group, a cyano group, a nitro group, a substituted or unsubstituted C₁-C₁₀ alkyl group, and a substituted or unsubstituted C₆-C₁₆ aryl group; and R₁ and R₂ may be optionally linked to each other to form an unsubstituted C₆-C₂₀ saturated ring or an unsubstituted C₆-C₂₀ unsaturated ring. However, embodiments of the present disclosure are not limited thereto.

For example, in Formula 1, R₁ and R₂ may be each independently selected from a hydrogen, a deuterium, —F, a hydroxyl group, a cyano group, a nitro group, a methyl group, an ethyl group, an n-propyl group, an iso-propyl group, a tert-butyl group, a phenyl group, and a naphthyl group; or R₁ and R₂ may be optionally linked to each other to form an unsubstituted C₆-C₂₀ saturated ring or a unsubstituted C₆-C₂₀ unsaturated ring. However, embodiments of the present disclosure are not limited thereto.

For example, R₁ and R₂ in Formula 1 may be each independently selected from, but are not limited to, a hydrogen, a deuterium, a methyl group, a phenyl group, and a group represented by Formula 5:

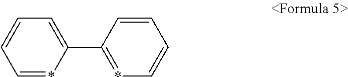 [SMILES: *1ccccc1-c1*cccc1]

In Formula 5, * indicates a binding site with an indene-based core.

In Formula 1, R₃, R₄, and Q₁ to Q₃ may be each independently selected from a hydrogen, a deuterium, —F, —Cl, —Br, —I, a hydroxyl group, a cyano group, a nitro group, an amino group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₃-C₃₀ cycloalkyl group, a substituted or unsubstituted C₃-C₃₀ cycloalkenyl group, a substituted or unsubstituted C₆-C₃₀ aryl group, a substituted or unsubstituted C₆-C₃₀ aryloxy group, a substituted or unsubstituted C₆-C₃₀ arylthio group, and a substituted or unsubstituted C₁-C₃₀ heteroaryl group.

For example, in Formula 1, R₃ may be selected from, but is not limited to,

a hydrogen, a deuterium, —F, —Cl, —Br, —I, a hydroxyl group, a cyano group, a nitro group, a methyl group, an ethyl group, an n-propyl group, an iso-propyl group, an n-butyl group, a sec-butyl group, an iso-butyl group, and a tert-butyl group,

a phenyl group, a naphthyl group, a pyridyl group, and a triazinyl group, and

a phenyl group, a naphthyl group, a pyridyl group, and a triazinyl group, each substituted with at least one selected from a deuterium, —F, —Cl, —Br, —I, a hydroxyl group, a cyano group, a nitro group, a methyl group, an ethyl group, an n-propyl group, an iso-propyl group, an n-butyl group, a sec-butyl group, an iso-butyl group, and a tert-butyl group.

For example, R₃ in Formula 1 may be selected from, but are not limited to, a hydrogen, a deuterium, —F, a cyano group, a nitro group, a methyl group, an ethyl group, an n-propyl group, an iso-propyl group, an n-butyl group, a sec-butyl group, an iso-butyl group, and a tert-butyl group.

For example, R₃ in Formula 1 may be selected from, but are not limited to, a hydrogen, a deuterium, —F, a cyano group, a nitro group, and a methyl group.

In some embodiments, R₄ in Formula 1 may be selected from a substituted or unsubstituted C₆-C₂₀ aryl group, and a substituted or unsubstituted C₁-C₂₀ heteroaryl group, but is not limited thereto.

For example, in Formula 1, R₄ may be selected from, but is not limited to, a phenyl group, a pentalenyl group, an indenyl group, a naphthyl group, an azulenyl group, a heptalenyl group, an indacenyl group, an acenaphtyl group, a fluorenyl group, a spiro-fluorenyl group, a phenalenyl group, a phenanthrenyl group, an anthryl group, a fluoranthenyl group, a triphenylenyl group, a pyrenyl group, a chrysenyl group, a naphthacenyl group, a picenyl group, a perylenyl group, a pentaphenyl group, a hexacenyl group, a pyrrolyl group, an imidazolyl group, a pyrazolyl group, a pyridyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a benzooxazolyl group, a dibenzofuranyl group, a dibenzothiophenyl group, and a benzocarbazolyl group, and a phenyl group, a pentalenyl group, an indenyl group, a naphthyl group, an azulenyl group, a heptalenyl group, an indacenyl group, an acenaphtyl group, a fluorenyl group, a spiro-fluorenyl group, a phenalenyl group, a phenanthrenyl group, an anthryl group, a fluoranthenyl group, a triphenylenyl group, a pyrenyl group, a chrysenyl group, a naphthacenyl group, a picenyl group, a perylenyl group, a pentaphenyl group, a hexacenyl group, a pyrrolyl group, an imidazolyl group, a pyrazolyl group, a pyridyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a benzooxazolyl group, a dibenzofuranyl group, a dibenzothiophenyl group, and a benzocarbazolyl group, each substituted with at least one of a deuterium, —F, —Cl, —Br, —I, a hydroxyl group, a cyano group, a nitro group, an amino group, an amidino group, a hydrazine, a hydrazone, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, and a substituted or unsubstituted C₁-C₆₀ heteroaryl group.

For example, in Formula 1, R₄ may be selected from, but is not limited to,

i) a phenyl group, a naphthyl group, and an anthryl group, and

ii) a phenyl group, a naphthyl group, and an anthryl group, each substituted with at least one of a deuterium, —F, —Cl, —Br, —I, a hydroxyl group, a cyano group, a nitro group, a methyl group, an ethyl group, an n-butyl group, an iso-propyl group, a tert-butyl group, a phenyl group, a naphthyl group, and an anthryl group.

For example, in Formula 1, R₄ may be selected from, but is not limited to,

i) a phenyl group, a 1-naphthyl group, and a 2-naphthyl group, and

ii) a phenyl group, a 1-naphthyl group, and a 2-naphthyl group, each substituted with at least one of a deuterium, —F, —Cl, —Br, —I, a hydroxyl group, a cyano group, a nitro group, a methyl group, an ethyl group, an n-propyl group, an iso-propyl group, and a tert-butyl group.

For example, R₄ in Formula 1 may be a group represented by one of Formulae 4-1 to 4-9, but is not limited thereto:

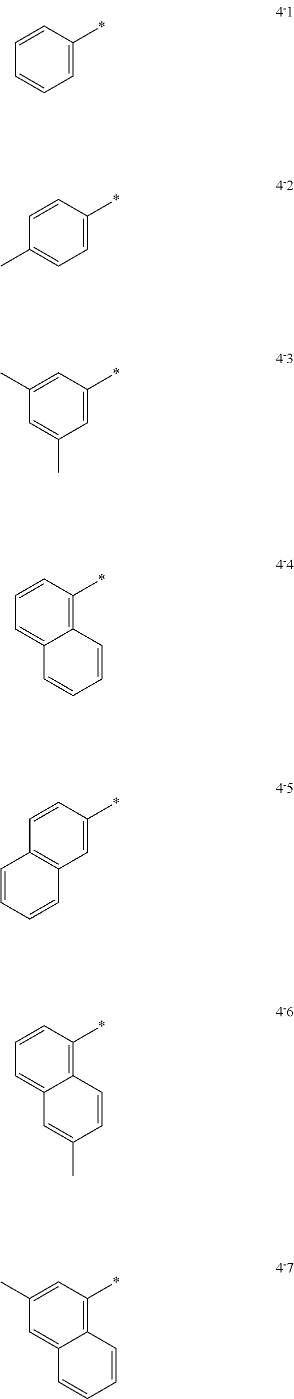

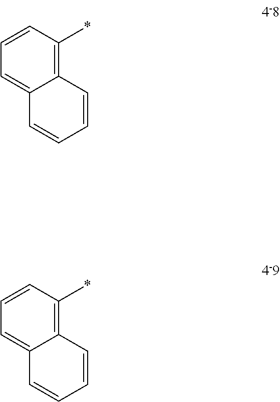 [SMILES: *c1cccc2ccccc12 ; *c1cccc2ccccc12]

In some embodiments, Q₁ to Q₃ in Formula 1 may be each independently selected from a hydrogen, a deuterium, —F, —Cl, —Br, —I, a hydroxyl group, a cyano group, a nitro group, an amino group, a carboxyl group, a methyl group, an ethyl group, and a phenyl group, but are not limited thereto. For example, Q₁ to Q₃ in Formula 1 may be each independently selected from, but are not limited to, a hydrogen, a deuterium, a methyl group, and a phenyl group.

In Formula 1, a1, which indicates the number of R₃s, may be an integer of 0 to 3. When a1 is an integer of 2 or greater, a plurality of R₃s may be identical to or different from each other.

In Formula 1, a2, which indicates the number of R₄s, may be an integer of 0 to 3. When a2 is an integer of 2 or greater, a plurality of R₄s may be identical to or different from each other.

For example, a1 in Formula 1 may be an integer of 0 or 1, but is not limited thereto.

For example, a2 in Formula 1 may be an integer of 0 or 1, but is not limited thereto.

In Formula 1, Q₁ to Q₃ may be each independently linked to Z₂ to form a saturated or unsaturated ring. For example, in Formula 1, Q₁ to Q₃ may be each independently linked to Z₂ to form an unsaturated ring. However, embodiments of the present disclosure are not limited thereto.

In some embodiments, the indene-based compound of Formula 1 may be a compound represented by Formula 1a or 1b, but is not limited thereto:

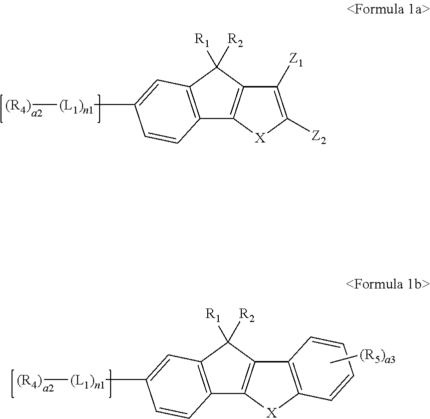

In Formulas 1a and 1b,

X may be an oxygen atom, a sulfur atom, N(Q₁), or C(Q₂)(Q₃);

Z₁ and Z₂ may be each independently selected from

i) a hydrogen, a cyano group, and a methyl group,

ii) a phenyl group and a pyridyl group, and

iii) a phenyl group and a pyridyl group, each substituted with at least one of a deuterium, a cyano group, and a methyl group;

(L₁)ₙ₁ is a moiety represented by one of Formulae 3-1 to 3-4;

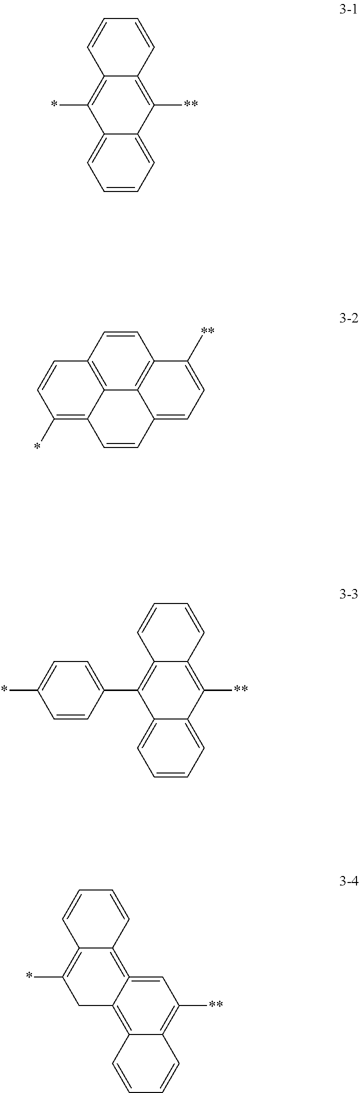

wherein, in Formulae 3-1 to 3-4, * indicates a binding site to R₄, and ** indicates a binding site to the Indene-based core;

R₁ and R₂ may be each independently selected from a hydrogen, a deuterium, a methyl group, a phenyl group, and a group represented by Formula 5,

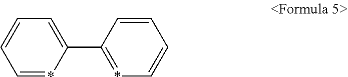

wherein, in Formula 5, * indicates a binding site to the Indene-based core;

R₄ may be a group represented by one of Formulae 4-1 to 4-9;

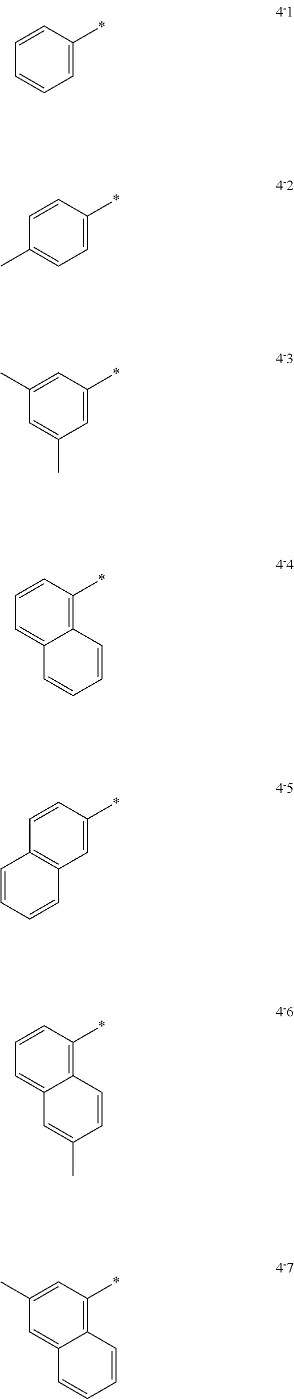

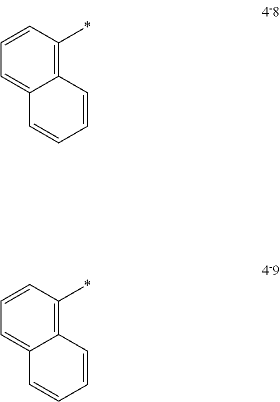 [SMILES: *c1cccc2ccccc12 ; *c1cccc2ccccc12]

R₅ may be selected from a hydrogen, a deuterium, a cyano group, and a methyl group;

a3 may be an integer of 0 to 2; and

Q₁ to Q₃ may be each independently selected from, a hydrogen, a deuterium, —F, —Cl, —Br, —I, a hydroxyl group, a cyano group, a nitro group, an amino group, a carboxyl group, a methyl group, an ethyl group, and a phenyl group.

In some other embodiments, the indene-based compound of Formula 1 may be selected from compounds 1 to 75, but is not limited thereto:

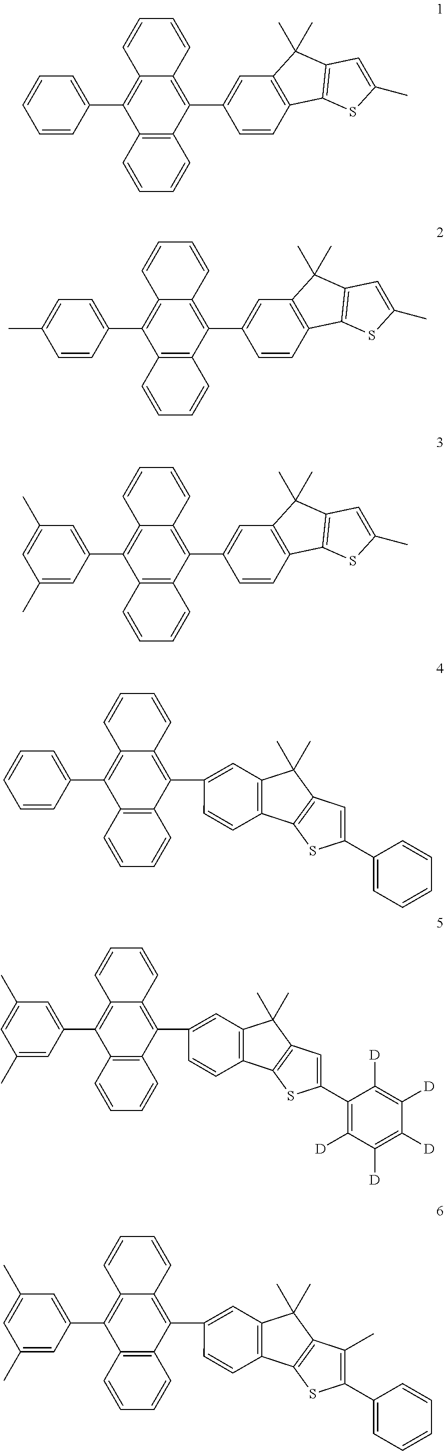

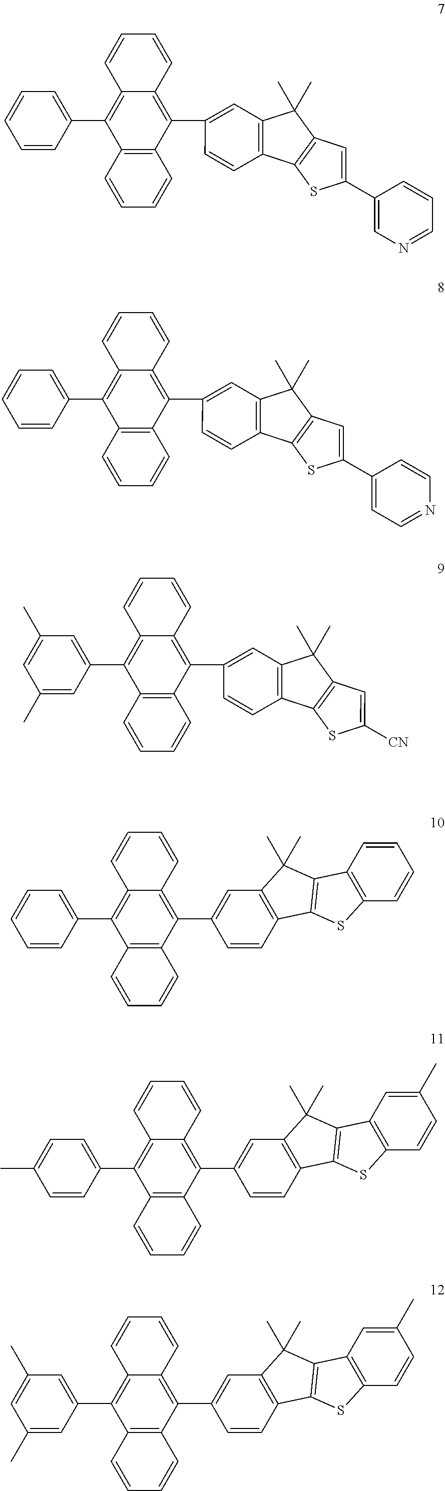

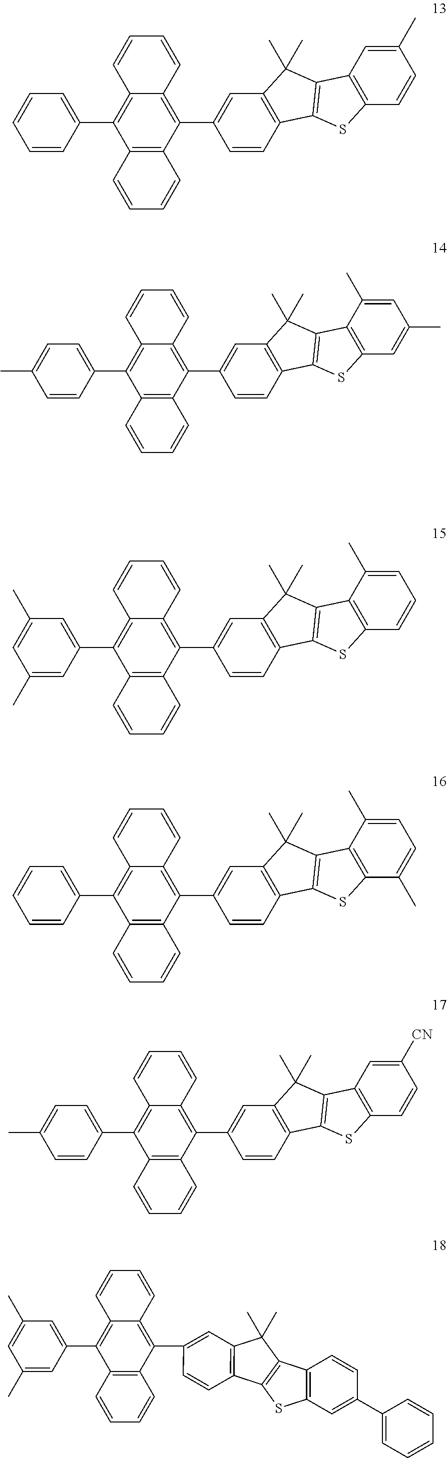

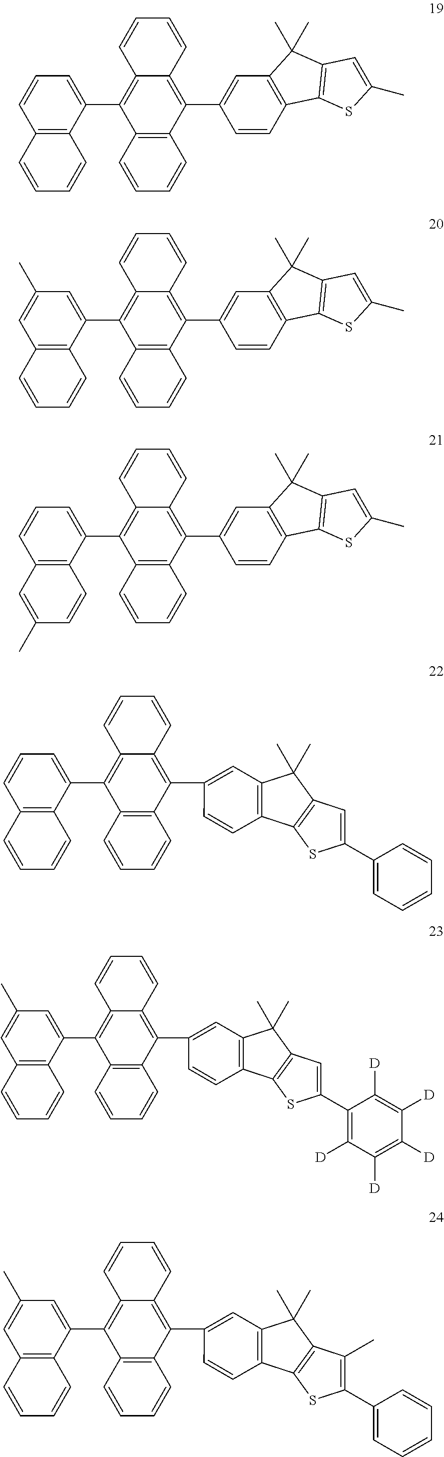

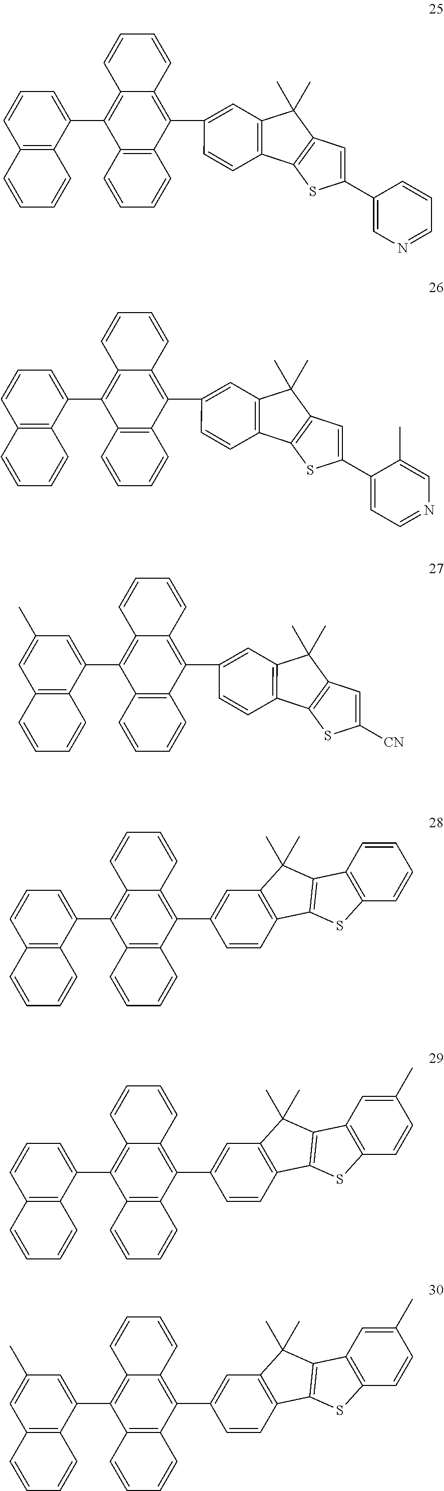 [SMILES: CC1(C)c2cc(-c3c4ccccc4c(-c4cccc5ccccc45)c4ccccc34)ccc2-c2sc(-c3cccnc3)cc21 ; Cc1cnccc1-c1cc2c(s1)-c1ccc(-c3c4ccccc4c(-c4cccc5ccccc45)c4ccccc34)cc1C2(C)C ; Cc1cc(-c2c3ccccc3c(-c3ccc4c(c3)C(C)(C)c3cc(C#N)sc3-4)c3ccccc23)c2ccccc2c1 ; CC1(C)c2cc(-c3c4ccccc4c(-c4cccc5ccccc45)c4ccccc34)ccc2-c2sc3ccccc3c21 ; Cc1ccc2sc3c(c2c1)C(C)(C)c1cc(-c2c4ccccc4c(-c4cccc5ccccc45)c4ccccc24)ccc1-3 ; Cc1cc(-c2c3ccccc3c(-c3ccc4c(c3)C(C)(C)c3c-4sc4ccc(C)cc34)c3ccccc23)c2ccccc2c1]

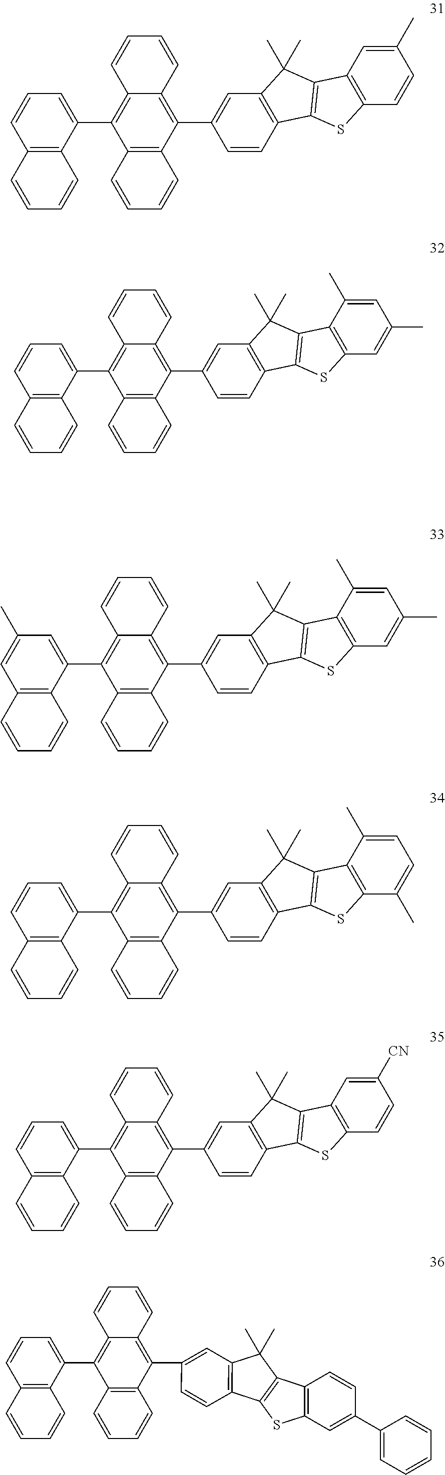 [SMILES: Cc1ccc2sc3c(c2c1)C(C)(C)c1cc(-c2c4ccccc4c(-c4cccc5ccccc45)c4ccccc24)ccc1-3 ; Cc1cc(C)c2c3c(sc2c1)-c1ccc(-c2c4ccccc4c(-c4cccc5ccccc45)c4ccccc24)cc1C3(C)C ; Cc1cc(-c2c3ccccc3c(-c3ccc4c(c3)C(C)(C)c3c-4sc4cc(C)cc(C)c34)c3ccccc23)c2ccccc2c1 ; Cc1ccc(C)c2c3c(sc12)-c1ccc(-c2c4ccccc4c(-c4cccc5ccccc45)c4ccccc24)cc1C3(C)C ; CC1(C)c2cc(-c3c4ccccc4c(-c4cccc5ccccc45)c4ccccc34)ccc2-c2sc3ccc(C#N)cc3c21 ; CC1(C)c2cc(-c3c4ccccc4c(-c4cccc5ccccc45)c4ccccc34)ccc2-c2sc3cc(-c4ccccc4)ccc3c21]

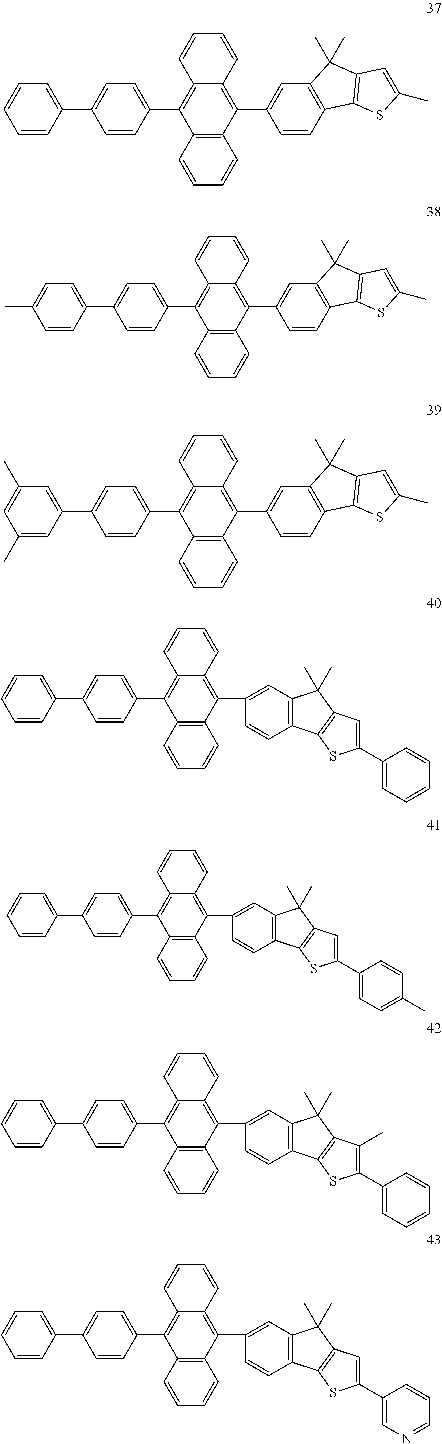

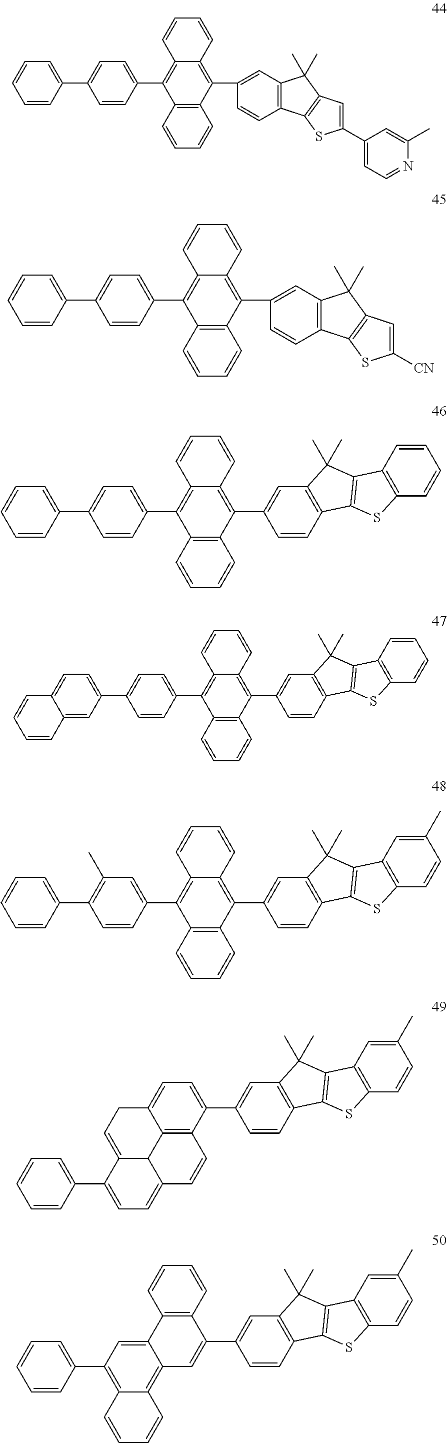

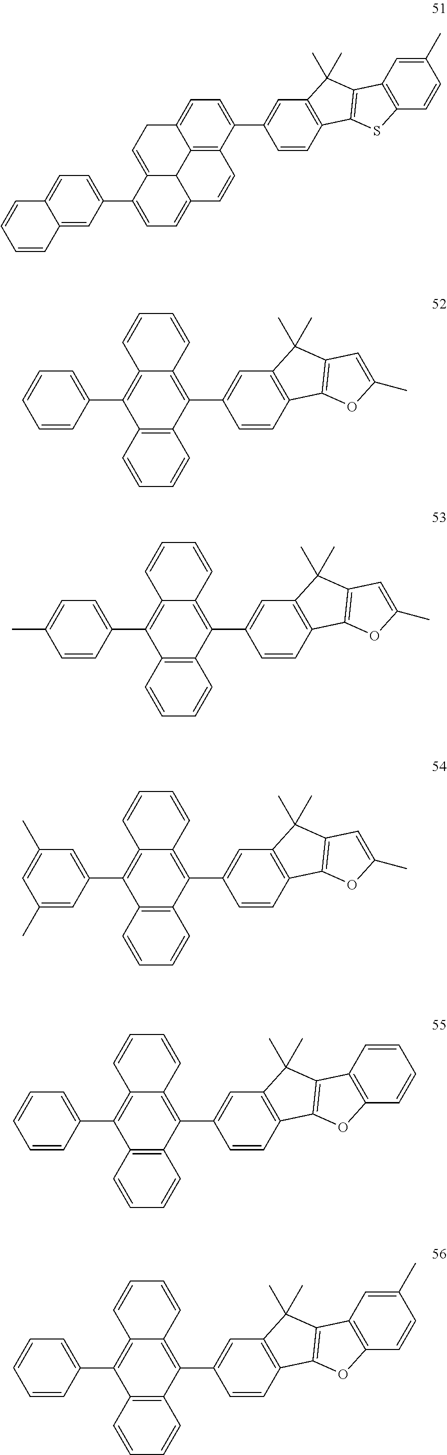

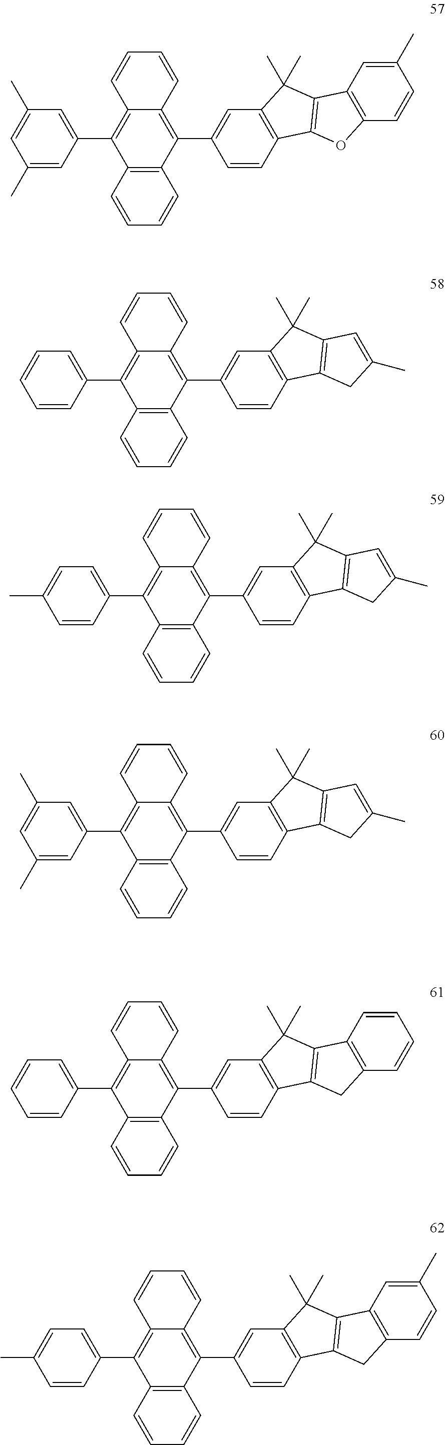

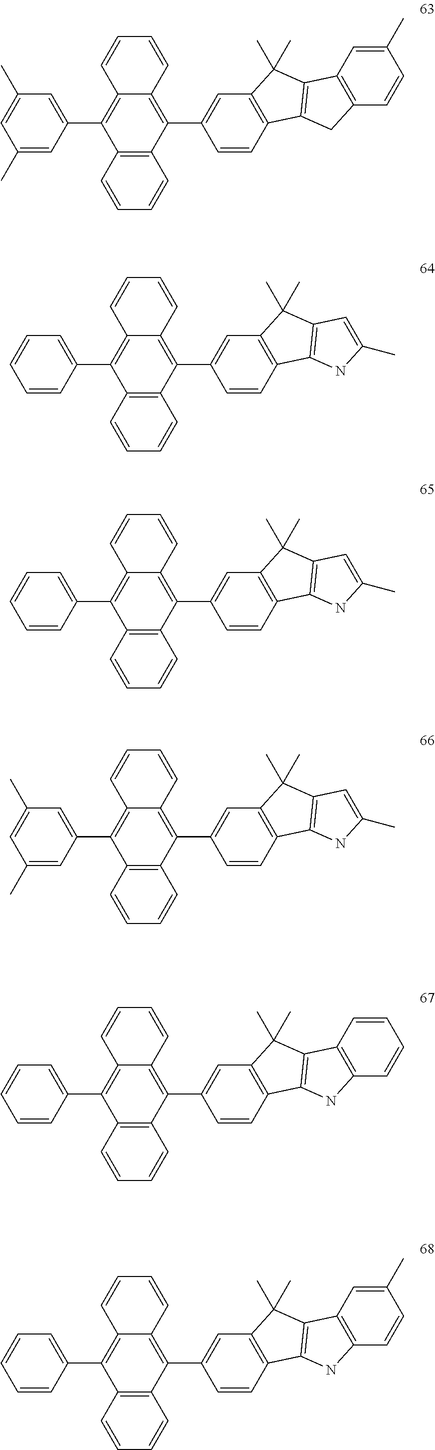

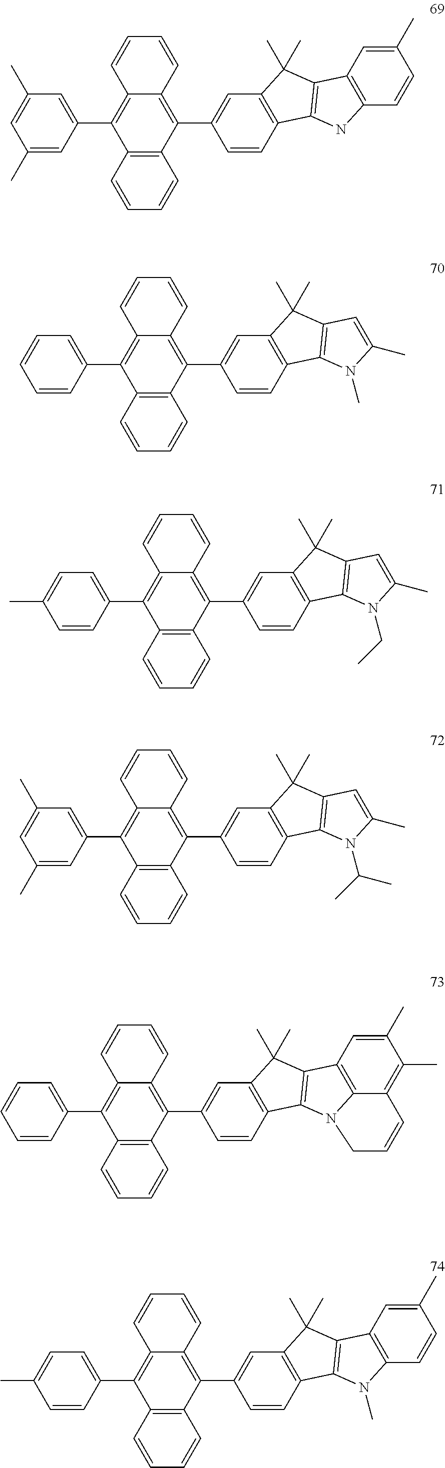

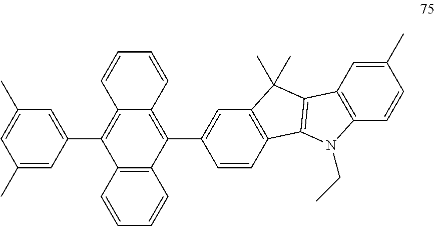 [SMILES: CCn1c2c(c3cc(C)ccc31)C(C)(C)c1cc(-c3c4ccccc4c(-c4cc(C)cc(C)c4)c4ccccc34)ccc1-2]

The indene-based compound of Formula 1 may have a three-dimensional, not planar, core structure as represented by Formula 1′, and thus may less undergo change in color coordinates (toward red emission) caused by stacking of molecules of the compound.

In the indene-based compound of Formula 1, a plurality of rings are condensed to the core, so that the indene-based compound of Formula 1 may have improved molecular rigidity. Accordingly, an organic light-emitting device including the indene-based compound of Formula 1 may have improved thermal stability and improved thin film stability.

Therefore, an organic light-emitting device including any of the indene-based compounds represented by Formula 1 according to the above-described embodiments may have a high efficiency and a low driving voltage.

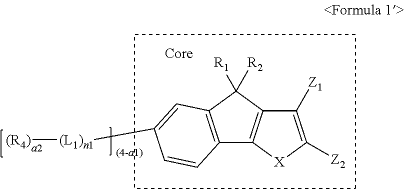

The indene-based compounds of Formula 1 according to the above-described embodiments may be synthesized via organic synthesis. A synthesis method of the indene-based compounds of Formula 1 may be understood by those of ordinary skill in the art with reference to the examples that will be described below.

At least one of the indene-based compounds of Formula 1 may be used between a pair of electrodes in an organic light-emitting device. In some embodiments, at least one of the indene-based compounds of Formula 1 may be used in an emission layer. For example, at least one of the indene-based compounds of Formula 1 may be used as a host in the emission layer. For example, at least one of the indene-based compounds of Formula 1 may be used as a host of a blue emission layer.

According to another embodiment of the present disclosure, an organic light-emitting device includes a substrate, a first electrode, a second electrode disposed opposite to the first electrode, and an organic layer disposed between the first electrode and the second electrode, wherein the organic layer includes at least one of the indene-based compounds of Formula 1 described above.

As used herein, “(for example, the organic layer) including at least one indene-based compound means that “(the organic layer) including one of the indene-based compounds of Formula 1, or at least two of the indene-based compounds of Formula 1 above”.

In some embodiments, the organic layer may include only Compound 1 as the indene-based compound. For example, the emission layer of the organic light-emitting device may include Compound 1. In some embodiments, the organic layer may include Compounds 1 and 2 as the indene-based compounds. For example, Compound 1 and Compound 2 may be in the same layer, for example, in the emission layer, or in different layers, respectively, for example, in first and second emission layers of the organic light-emitting device.

The term “organic layer” as used herein refers to a single layer and/or a plurality of layers disposed between the first and second electrodes of the organic light-emitting device.

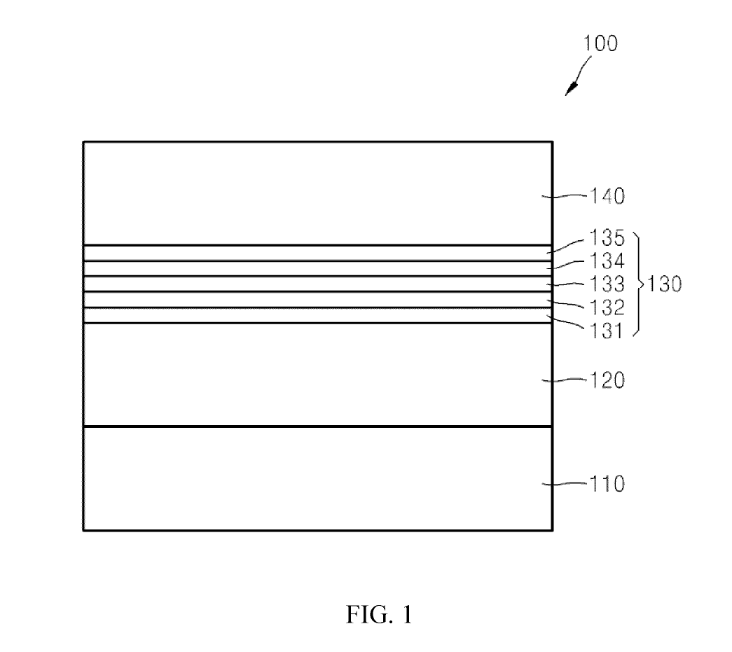

FIG. 1 is a schematic sectional view of an organic light-emitting device 100 according to an embodiment of the present disclosure. Hereinafter, a structure of an organic light-emitting device according to an embodiment of the present disclosure and a method of manufacturing the same will now be described with reference to FIG. 1.

Referring to FIG. 1, the organic light-emitting device 100 includes a substrate 110, a first electrode 120, an organic layer 130, and a second electrode 140.

The substrate 110, which may be any substrate used in general OLEDs, may be a glass substrate or a transparent plastic substrate with excellent mechanical strength, thermal stability, transparency, surface smoothness, ease of handling, and water resistance.

The first electrode 120 may be formed by depositing or sputtering a first electrode-forming material on the substrate 110. When the first electrode 120 is an anode, a material for forming the first electrode 120 may be selected from materials having a high work function to facilitate hole injection. The first electrode 120 may be a reflective electrode or a transmissive electrode. Transparent materials having good conductivity such as ITO, IZO, SnO₂, and ZnO may be used as the material for forming the first electrode 120. For example, the first electrode 120 may be formed as a reflective electrode by using magnesium (Mg), aluminum (Al), aluminum-lithium (Al—Li), calcium (Ca), magnesium-indium (Mg—In), magnesium-silver (Mg—Ag), or the like.

The first electrode 120 may have a single-layer structure or a multi-layer structure including at least two layers. For example, the first electrode 120 may have a three-layered structure of ITO/Ag/ITO, but is not limited thereto.

The organic layer 130 may be disposed on the first electrode 120.

The organic layer 130 may include a hole injection layer (HIL) 131, a hole transport layer (HTL) 132, a functional layer having both hole injection and transport capabilities (referred to as a H-functional layer), a buffer layer, an emission layer (EML) 133, an electron transport layer (ETL) 134, and an electron injection layer (EIL) 135.

The HIL 131 may be formed on the first electrode 120 by any of a variety of methods, for example, including vacuum deposition, spin coating, casting, Langmuir-Blodgett (LB) deposition, or the like.

When the HIL 131 is formed using vacuum deposition, vacuum deposition conditions may vary depending on the material that is used to form the HIL 131, and the desired structure and thermal properties of the HIL 131. For example, vacuum deposition may be performed at a temperature of about 100° C. to about 500° C., a pressure of about 10⁻⁸ torr to about 10⁻³ torr, and a deposition rate of about 0.01 to about 100 Å/sec. However, the deposition conditions are not limited thereto.

When the HIL 131 is formed using spin coating, the coating conditions may vary depending on the material that is used to form the HIL 131, and the desired structure and thermal properties of the HIL 131. For example, the coating rate may be in the range of about 2000 rpm to about 5000 rpm, and a temperature at which heat treatment is performed to remove a solvent after coating may be in the range of about 80° C. to about 200° C. However, the coating conditions are not limited thereto.

A material for forming the HIL 131 may be a known hole injecting material. Non-limiting examples of the hole injecting material are N,N′-diphenyl-N,N′-bis-[4-(phenyl-m-tolyl-amino)-phenyl]-biphenyl-4,4′-diamine (DNTPD), phthalocyanine compounds such as copper phthalocyanine, 4,4′,4″-tris(3-methylphenylphenylamino)triphenylamine (m-MTDATA), N,N′-di(1-naphthyl)-N,N′-diphenylbenzidine (NPB), 4,4′,4″-tris(N,N-diphenylamino)triphenylamine (TDATA), 4,4′,4″-tris[2-naphthyl(phenyl)amino]triphenylamine (2-TNATA), polyaniline/dodecylbenzenesulfonic acid (PANI/DBSA), poly(3,4-ethylenedioxythiophene)/poly(4-styrene sulfonate) (PEDOT/PSS), polyaniline/camphor sulfonic acid (PANI/CSA), and polyaniline)/poly(4-styrenesulfonate (PANI/PSS).

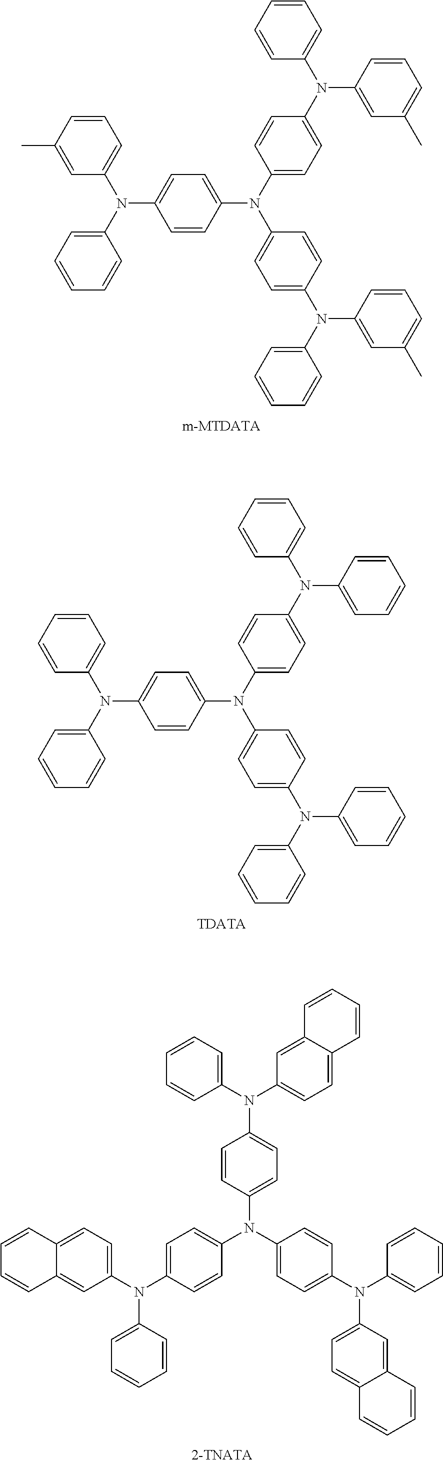

A thickness of the HIL 131 may be in a range of about 100 Å to about 10000 Å, and in some embodiments, about 100 Å to about 1000 Å. When the thickness of the HIL 131 is within these ranges, the HIL 131 may have good hole injecting ability without a substantial increase in driving voltage.

Then, the HTL 132 may be formed on the HIL 131 by using any of a variety of methods, for example, vacuum deposition, spin coating, casting, Langmuir-Blodgett (LB) deposition, or the like. When the HTL 132 is formed using vacuum deposition or spin coating, the conditions for deposition and coating may be similar to those for the formation of the HIL 131, though the conditions for deposition and coating may vary depending on the material that is used to form the HTL 132.

Non-limiting examples of suitable known hole transport materials are carbazole derivatives, such as N-phenylcarbazole or polyvinylcarbazole, N,N-bis(3-methylphenyl)-N,N-diphenyl-[1,1-biphenyl]-4,4′-diamine (TPD), 4,4′,4″-tris(N-carbazolyl)triphenylamine (TCTA), and N,N′-di(1-naphthyl)-N,N′-diphenylbenzidine) (NPB).

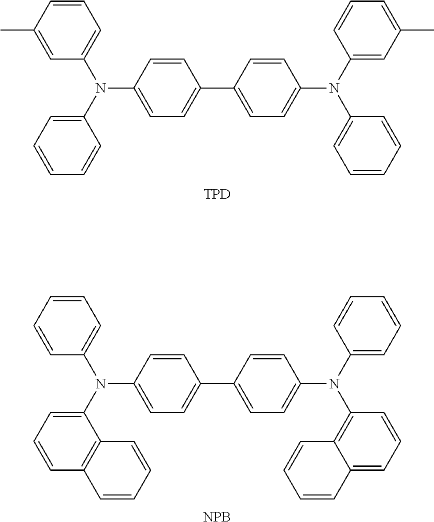

A thickness of the HTL 132 may be in a range of about 50 Å to about 2000 Å, and in some embodiments, about 100 Å to about 1500 Å. When the thickness of the HTL 132 is within these ranges, the HTL 132 may have good hole transporting ability without a substantial increase in driving voltage.

The H-functional layer (having both hole injection and hole transport capabilities) may contain at least one material selected from each group of the hole injection layer materials and hole transport layer materials. The thickness of the H-functional layer may be in a range of about 500 Å to about 10,000 Å, and in some embodiments, about 100 Å to about 1,000 Å. When the thickness of the H-functional layer is within these ranges, the H-functional layer may have good hole injection and transport capabilities without a substantial increase in driving voltage.

In some embodiments, at least one of the HIL 131, HTL 132, and H-functional layer may include at least one of a compound of Formula 300 and a compound of Formula 350:

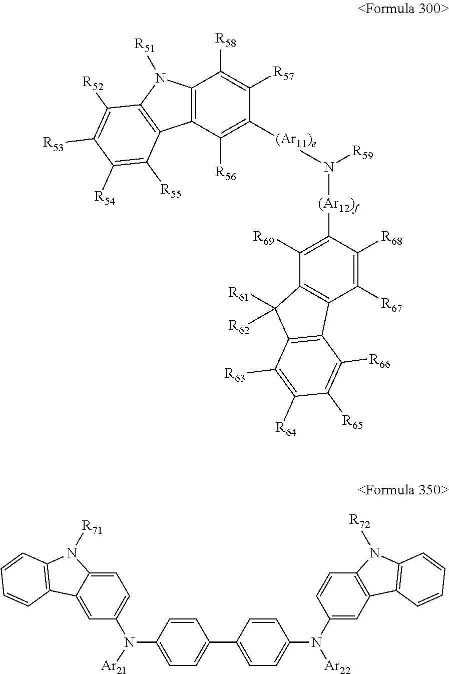

In Formulae 300 and 350, Ar₁₁, Ar₁₂, Ar₂, and Ar₂₂ may be each independently a substituted or unsubstituted C₆-C₆₀ arylene group. Ar₁₁, Ar₁₂, Ar₂₁ and Ar₂₂ in Formulae 300 and 350 may be defined as described above in conjunction with L₁ of Formula 1, and thus detailed descriptions thereof will not be provided here.

In Formula 300, e and f may be each independently an integer of 0 to 5, for example, may be 0, 1, or 2. For example, e may be 1, and f may be 0, but not limited thereto.

In Formulae 300 and 350 above, R₅₁ to R₅₈, R₆₁ to R₆₉, and R₇₁ and R₇₂ may be each independently a hydrogen atom, a deuterium atom, —F, —Cl, —Br, —I, a hydroxyl group, a cyano group, a nitro group, an amino group, an amidino group, a hydrazine group, a hydrazone, a carboxyl group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀alkynyl group, a substituted or unsubstituted C₁-C₆₀ alkoxy group, a substituted or unsubstituted C₃-C₆₀ cycloalkyl group, a substituted or unsubstituted C₅-C₆₀ aryl group, a substituted or unsubstituted C₅-C₆₀ aryloxy group, or a substituted or unsubstituted C₅-C₆₀ arylthio group. In some embodiments, R₅₁ to R₅₈, R₆₁ to R₆₉, R₇₁, and R₇₂ may be each independently one of a hydrogen atom; a deuterium atom; —F, —Cl, —Br, —I; a hydroxyl group; a cyano group; a nitro group; an amino group; an amidino group; a hydrazine; a hydrazone; a carboxyl group or a salt thereof; a sulfonic acid group or a salt thereof; a phosphoric acid group or a salt thereof; a C₁-C₁₀ alkyl group (for example, a methyl group, an ethyl group, a propyl group, a butyl group, a pentyl group, a hexyl group, or the like); a C₁-C₁₀ alkoxy group (for example, a methoxy group, an ethoxy group, a propoxy group, a butoxy group, a pentoxy group, or the like); a C₁-C₁₀ alkyl group and a C₁-C₁₀ alkoxy group that are substituted with at least one of a deuterium atom, —F, —Cl, —Br, —I, a hydroxyl group, a cyano group, a nitro group, an amino group, an amidino group, a hydrazine, a hydrazone, a carboxyl group or a salt thereof, a sulfonic acid group or a salt thereof, and a phosphoric acid group or a salt thereof; a phenyl group; a naphthyl group; an anthryl group; a fluorenyl group; a pyrenyl group; and a phenyl group, a naphthyl group, an anthryl group, a fluorenyl group, and a pyrenyl group that are substituted with at least one of a deuterium atom, —F, —Cl, —Br, —I, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a C₁-C₁₀ alkyl group, and a C₁-C₁₀ alkoxy group.

In Formula 300, R₅₉ may be one of a phenyl group, a naphthyl group, an anthryl group, a biphenyl group, a pyridyl group; and a phenyl group, a naphthyl group, an anthryl group, a biphenyl group, and a pyridyl group that are substituted with at least one of a deuterium atom, —F, —Cl, —Br, —I, a hydroxyl group, a cyano group, a nitro group, an amino group, an amidino group, a hydrazine, a hydrazone, a carboxyl group or a salt thereof, a sulfonic acid group or a salt thereof, a phosphoric acid group or a salt thereof, a substituted or unsubstituted C₁-C₂₀ alkyl group, and a substituted or unsubstituted C₁-C₂₀ alkoxy group.

In an embodiment, the compound of Formula 300 may be a compound represented by Formula 300A:

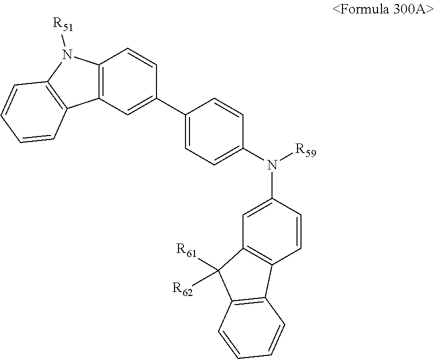

In Formula 300A, R₅₁, R₆₀, R₆₁, and R₅₉ may be as defined above.

In some embodiments, at least one of the HIL 131, HTL 132, and H-functional layer may include at least one of compounds represented by Formulae 301 to 320. However, embodiments of the present disclosure are not limited thereto.

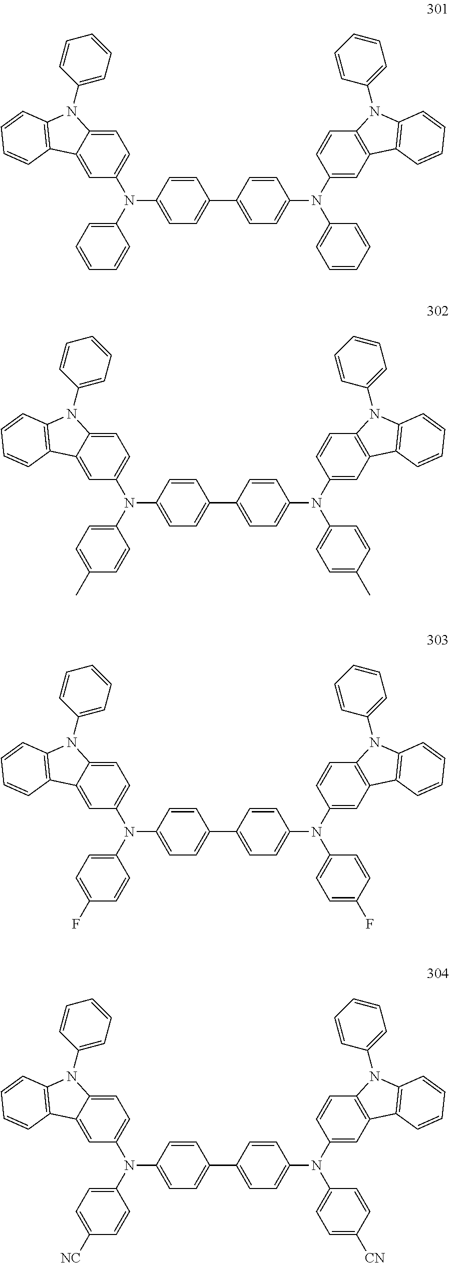 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1]

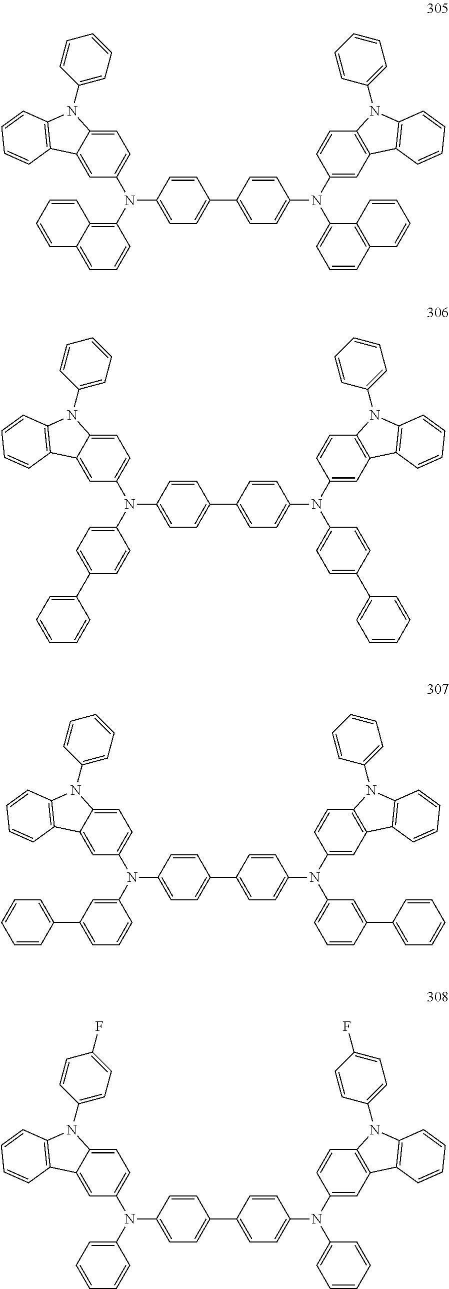 [SMILES: c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

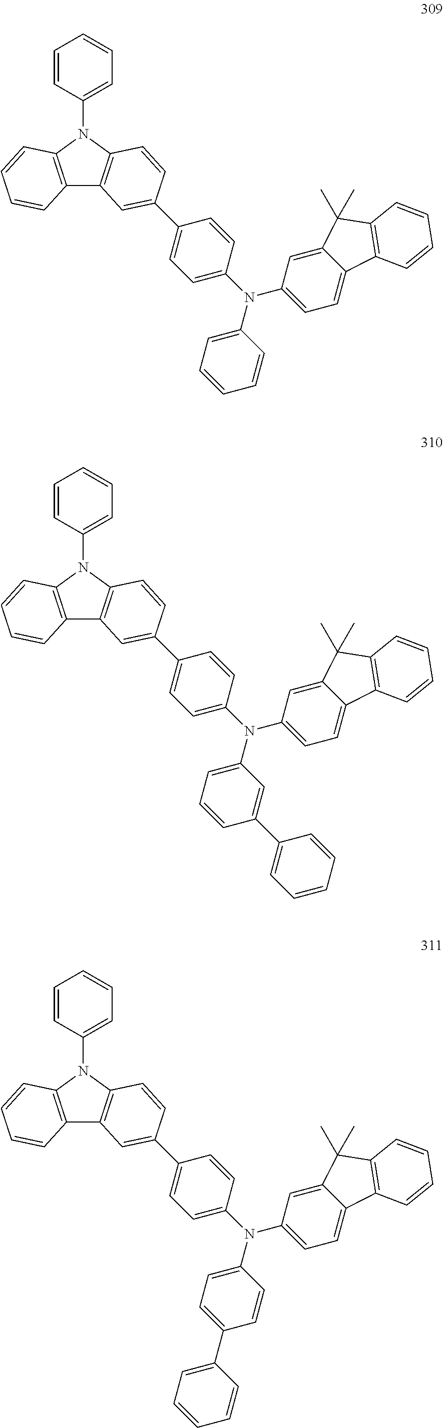 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

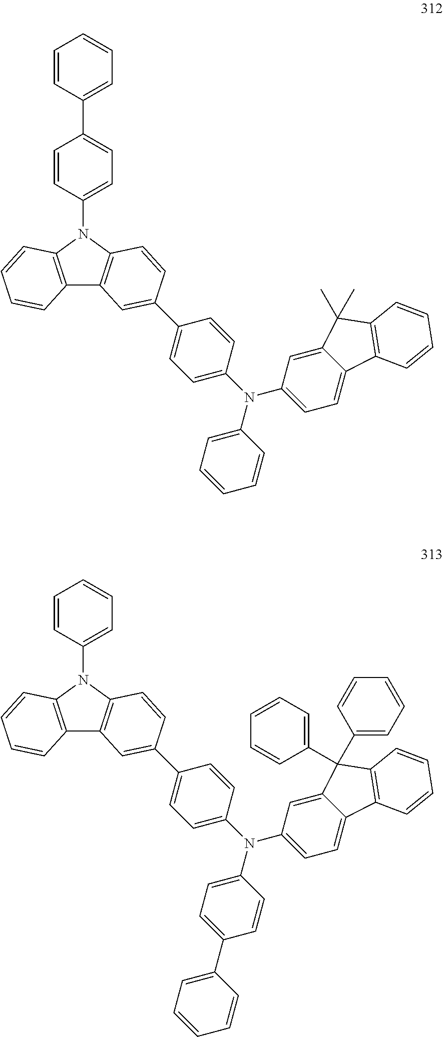 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

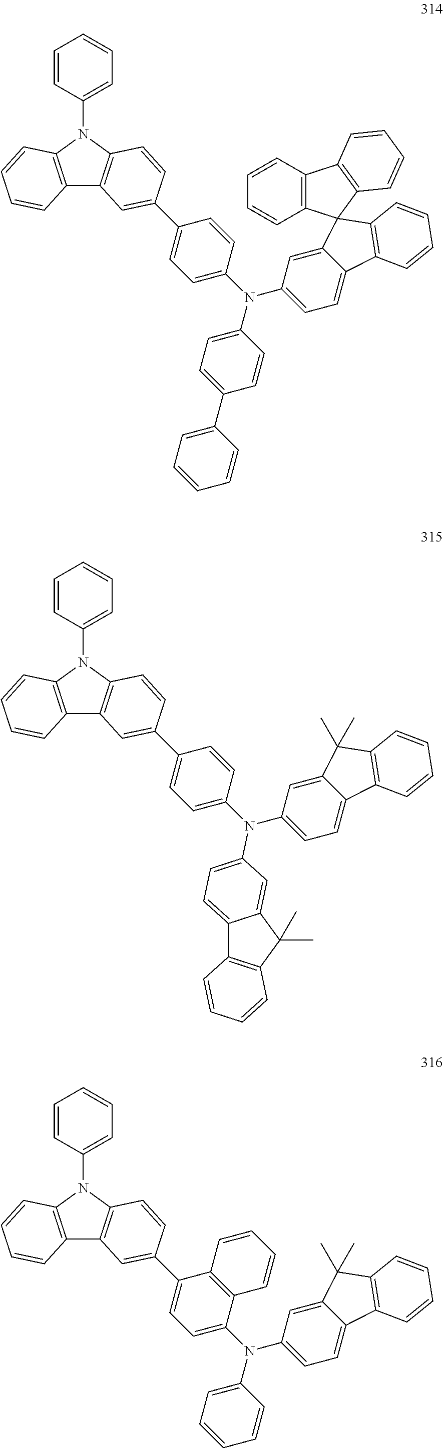 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21]

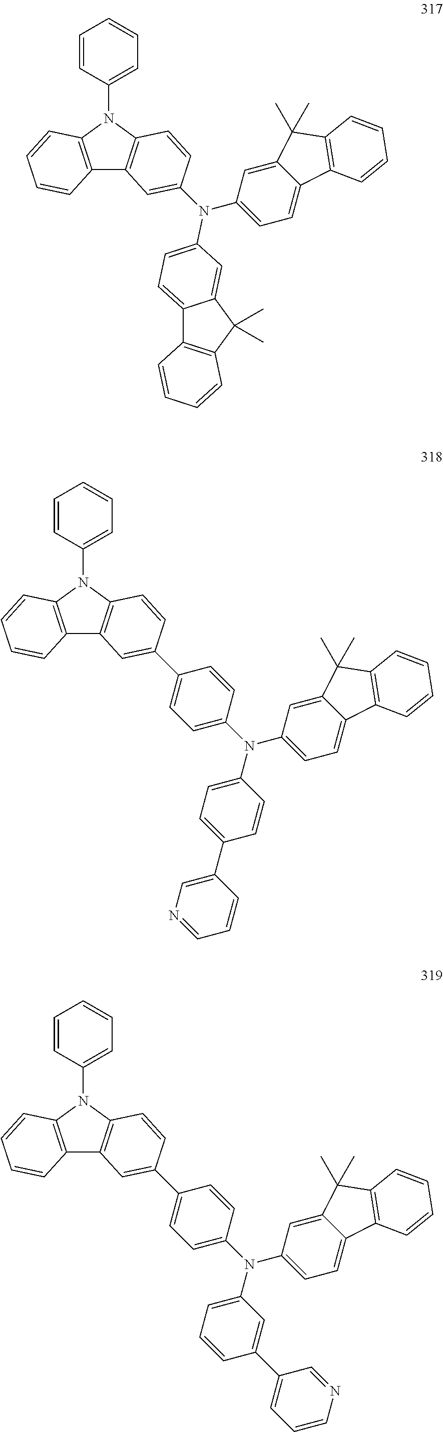 [SMILES: CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21]

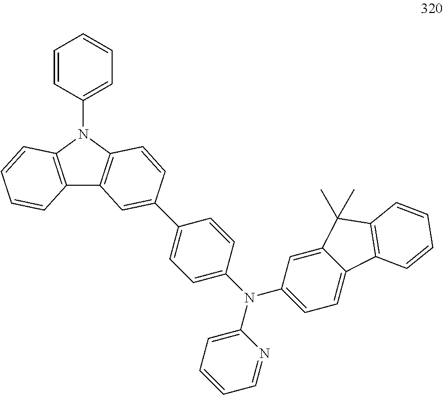 [SMILES: CC1(C)c2ccccc2-c2ccc(N(c3ccc(-c4ccc5c(c4)c4ccccc4n5-c4ccccc4)cc3)c3ccccn3)cc21]

At least one of the HIL 131, HTL 132, and H-functional layer may further include a charge-generating material for improved layer conductivity, in addition to a known hole injecting material, hole transport material, and/or material having both hole injection and hole transport capabilities as described above.

The charge-generating material may be one of quinine derivatives, metal oxides, and compounds with a cyano group, but is not limited thereto. Non-limiting examples of the p-dopant include quinone derivatives such as tetracyanoquinonedimethane (TCNQ), 2,3,5,6-tetrafluoro-tetracyano-1,4-benzoquinonedimethane (F4-TCNQ), and the like; metal oxides such as tungsten oxide, molybdenum oxide, and the like; and cyano-containing compounds such as Compound 100 (HAT-CN).

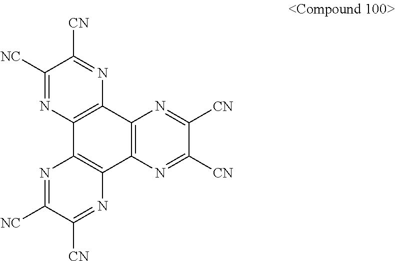 [SMILES: N#Cc1nc2c3nc(C#N)c(C#N)nc3c3nc(C#N)c(C#N)nc3c2nc1C#N]

When the HIL 131, HTL 132, or H-functional layer further includes a charge-generating material, the charge-generating material may be homogeneously dispersed or inhomogeneously distributed in the HIL 131, HTL 132, or H-functional layer. However, embodiments of the present disclosure are not limited thereto.

A buffer layer may be disposed between at least one of the HIL 131, HTL 132, and H-functional layer, and the EML 133. The buffer layer may compensate for an optical resonance distance of light according to a wavelength of the light emitted from the EML 133, and thus may increase efficiency. The butter layer may include any known hole injecting material or hole transporting material. In some other embodiments, the buffer layer may include the same material as one of the materials included in the HIL 131, HTL 132, and H-functional layer that underly the buffer layer.

Then, the EML 133 may be formed on the HTL 132, H-functional layer, or buffer layer by vacuum deposition, spin coating, casting, LB deposition, or the like. When the EML 133 is formed using vacuum deposition or spin coating, the deposition and coating conditions may be similar to those for the formation of the HIL 131, though the conditions for deposition and coating may vary depending on the material that is used to form the EML 133.

The EML 133 may include the indene-based compound of Formula 1. In some embodiment, the EML 23 may further include a host and a dopant that are widely known.

Non-limiting example of known hosts are Alq₃, 4,4′-N,N′-dicarbazole-biphenyl (CBP), poly(n-vinylcarbazole) (PVK), 9,10-di(naphthalene-2-yl)anthracene (ADN), TCTA, 1,3,5-tris(N-phenylbenzimidazole-2-yl)benzene (TPBI), 3-tert-butyl-9,10-di-2-naphthylanthracene (TBADN), E3, distyrylarylene (DSA), dmCBP (see a formula below), and Compounds 501 to 509.

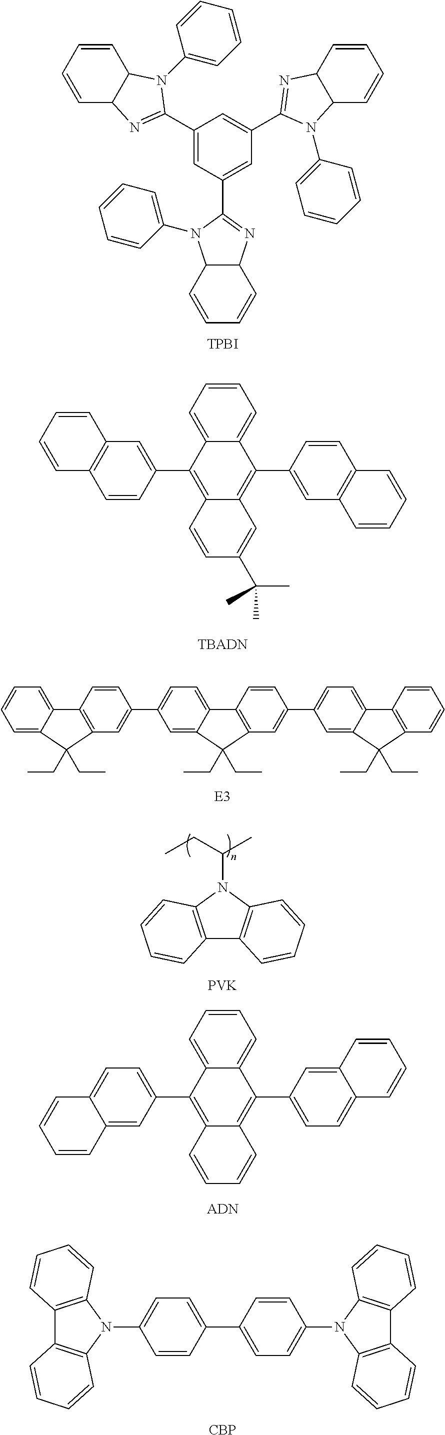

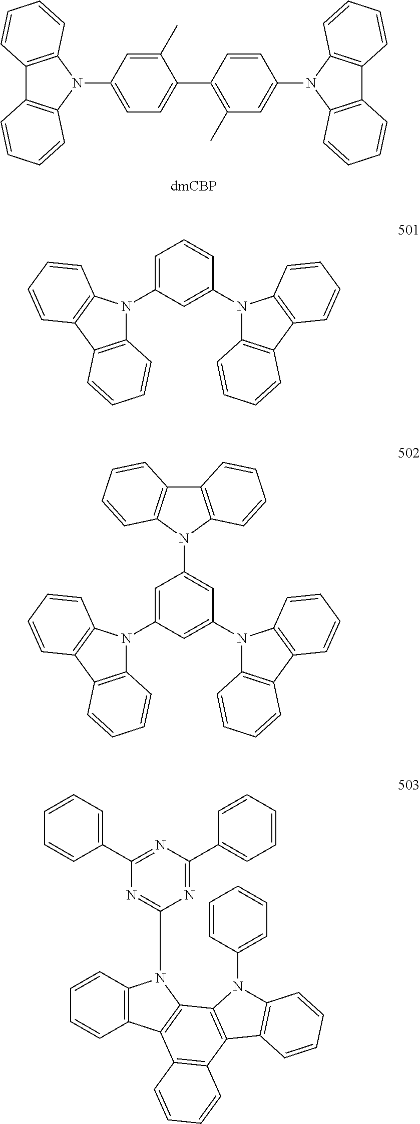 [SMILES: Cc1cc(-n2c3ccccc3c3ccccc32)ccc1-c1ccc(-n2c3ccccc3c3ccccc32)cc1C ; "dmCBP" ; c1cc(-n2c3ccccc3c3ccccc32)cc(-n2c3ccccc3c3ccccc32)c1 ; c1ccc2c(c1)c1ccccc1n2-c1cc(-n2c3ccccc3c3ccccc32)cc(-n2c3ccccc3c3ccccc32)c1 ; c1ccc(-c2nc(-c3ccccc3)nc(-n3c4ccccc4c4c5ccccc5c5c6ccccc6n(-c6ccccc6)c5c43)n2)cc1]

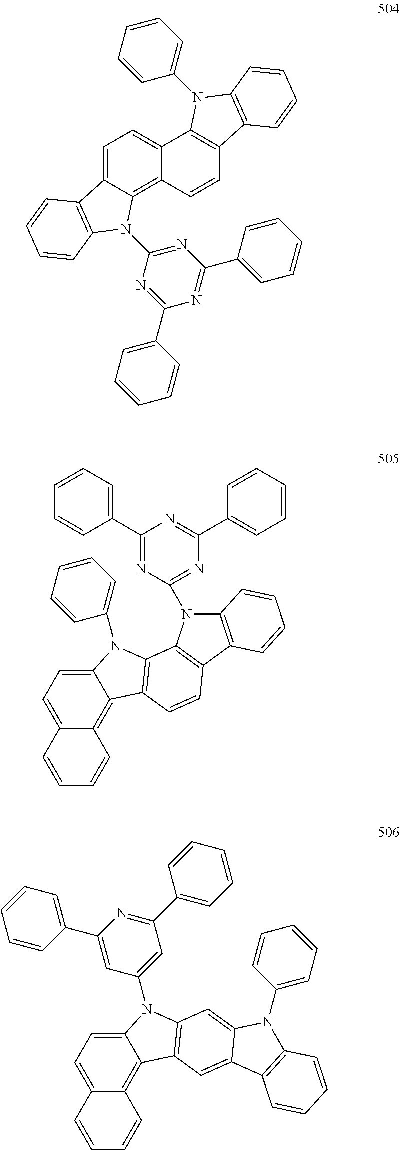 [SMILES: c1ccc(-c2nc(-c3ccccc3)nc(-n3c4ccccc4c4ccc5c(ccc6c7ccccc7n(-c7ccccc7)c65)c43)n2)cc1 ; c1ccc(-c2nc(-c3ccccc3)nc(-n3c4ccccc4c4ccc5c6c7ccccc7ccc6n(-c6ccccc6)c5c43)n2)cc1 ; c1ccc(-c2cc(-n3c4cc5c(cc4c4c6ccccc6ccc43)c3ccccc3n5-c3ccccc3)cc(-c3ccccc3)n2)cc1]

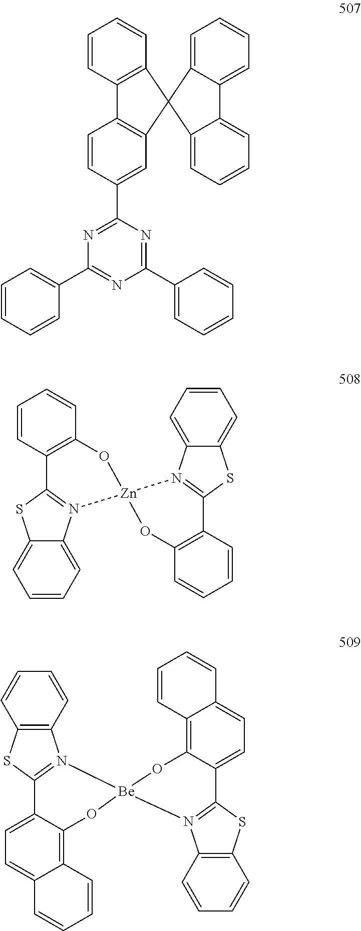

In some embodiments, an anthracene-based compound represented by Formula 400 may be used as the host.

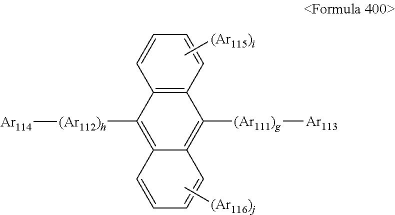

In Formula 400, Ar₁₁₁ and Ar₁₁₂ may be each independently a substituted or unsubstituted C₆-C₆₀ arylene group; Ar₁₁₃ to Ar₁₁₆ are each independently a substituted or unsubstituted C₁-C₁₀ alkyl group, or a substituted or unsubstituted C₅-C₆₀ aryl group; and g, h, I, and j may be each independently an integer of 0 to 4.

In some embodiments, Ar₁₁₁ and Ar₁₁₂ in Formula 60 may be each independently a phenylene group, a naphthylene group, a phenanthrenylene group, or a pyrenylene group; or a phenylene group, a naphthylene group, a phenanthrenylene group, a fluorenyl group, or a pyrenylene group that are substituted with at least one of a phenyl group, a naphthyl group, and an anthryl group.

In Formula 60, g, h, I, and j may be each independently 0, 1, or 2.

In some embodiments, Ar₁₁₃ to Ar₁₁₆ in Formula 400 may be each independently one of a C₁-C₁₀ alkyl group substituted with at least one of a phenyl group, a naphthyl group, and an anthryl group; a phenyl group; a naphthyl group; an anthryl group; a pyrenyl group; a phenanthrenyl group; a fluorenyl group; a phenyl group, a naphthyl group, an anthryl group, a pyrenyl group, a phenanthrenyl group, and a fluorenyl group that are substituted with at least one of a deuterium atom, —F, —Cl, —Br, —I, a hydroxyl group, a cyano group, a nitro group, an amino group, an amidino group, hydrazine, hydrazone, a carboxyl group or a salt thereof, a sulfonic acid group or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthryl group, a pyrenyl group, a phenanthrenyl group, and a fluorenyl group; and

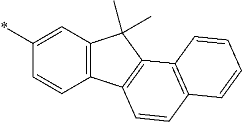 [SMILES: *c1ccc2c(c1)C(C)(C)c1c-2ccc2ccccc12]

but are not limited thereto.

For example, the anthracene-based compound of Formula 400 may be one of the compounds represented by the following formulae, but is not limited thereto:

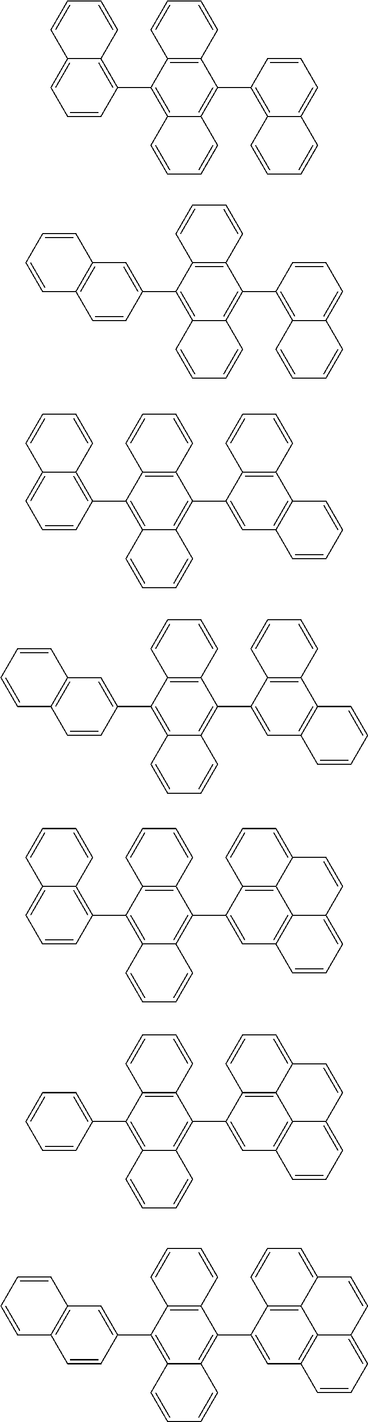

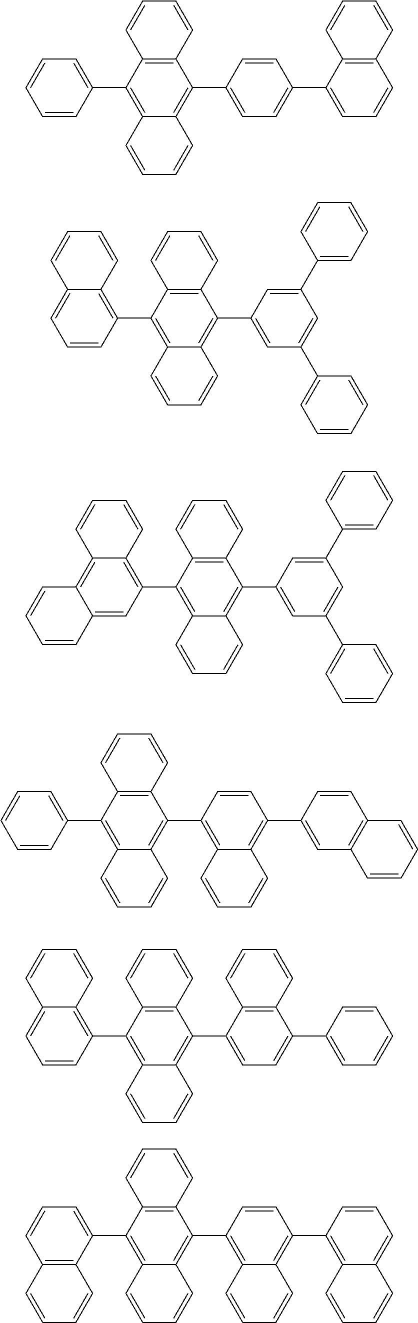

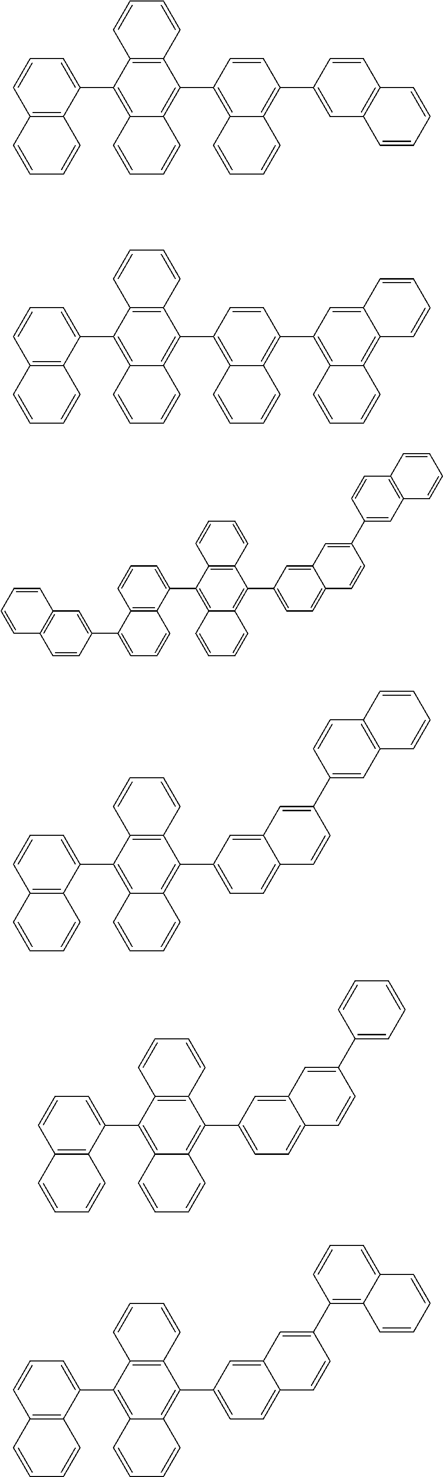

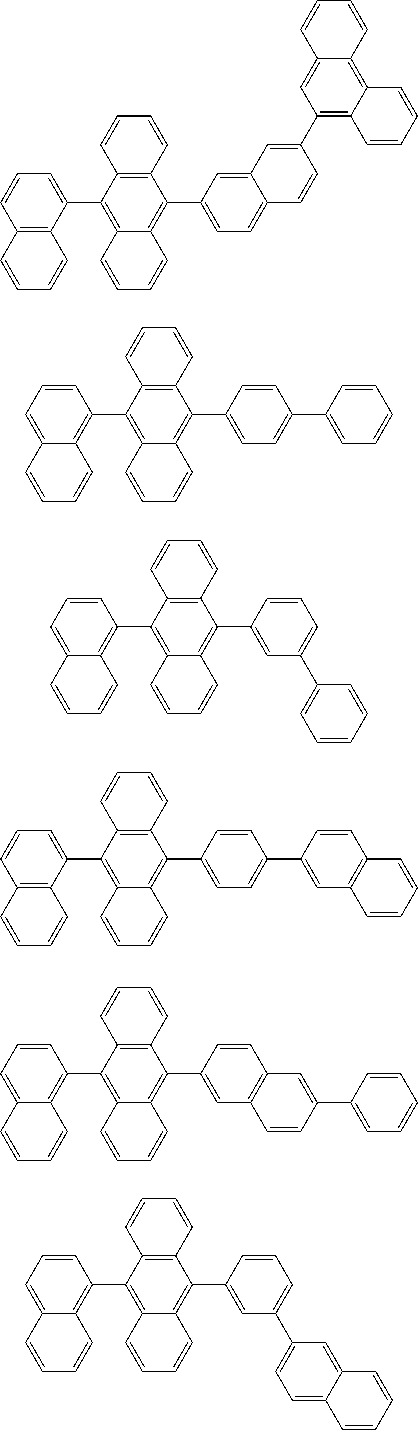

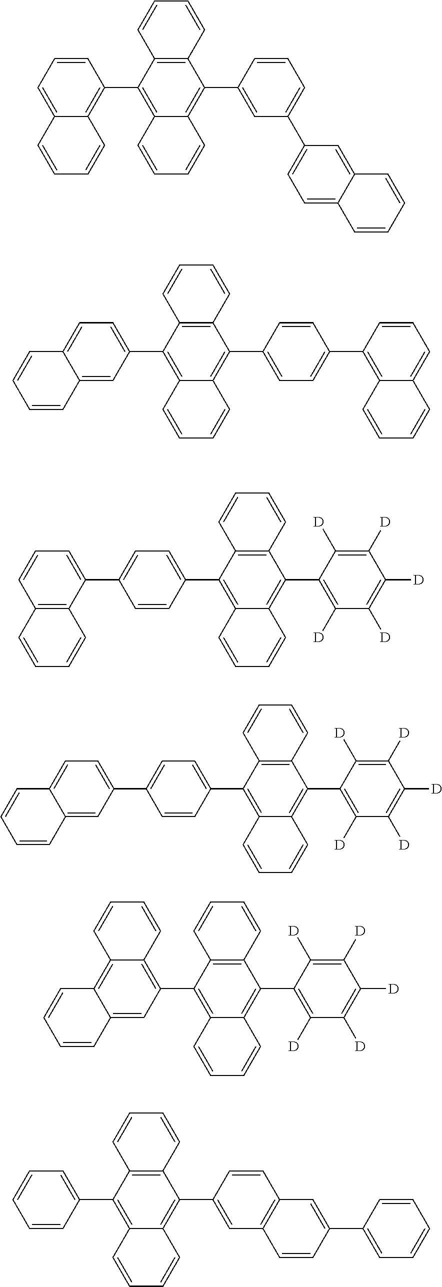

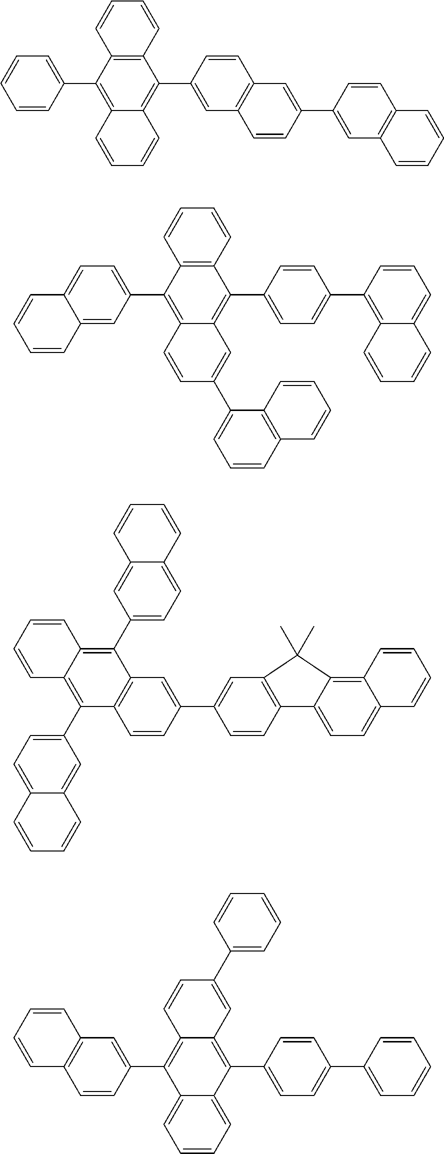

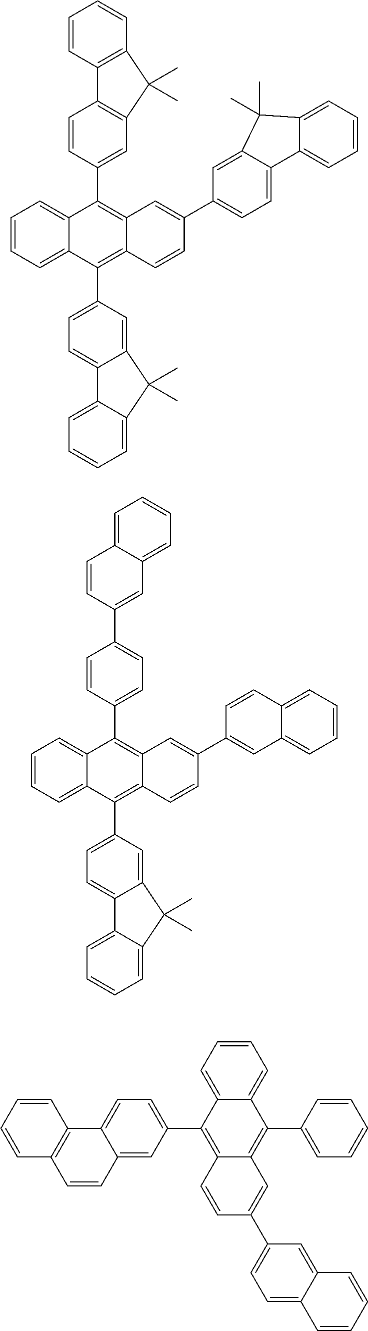

In some embodiments, an anthracene-based compound represented by Formula 401 may be used as the host.

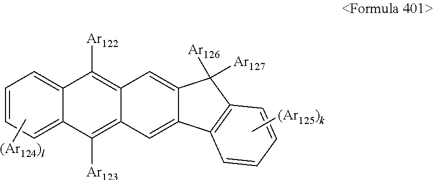

Ar₁₂₂ to Ar₁₂₅ in Formula 401 above may be defined as described above in conjunction with Ar₁₁₃ of Formula 400, and thus detailed descriptions thereof will not be provided here.

Ar₁₂₆ and Ar₁₂₇ in Formula 401 above may be each independently a C₁-C₁₀ alkyl group, for example, a methyl group, an ethyl group, or a propyl group.

In Formula 401, k and l may be each independently an integer of 0 to 4, for example, 0, 1, or 2.

For example, the anthracene compound of Formula 401 may be one of the compounds represented by the following formulae, but is not limited thereto:

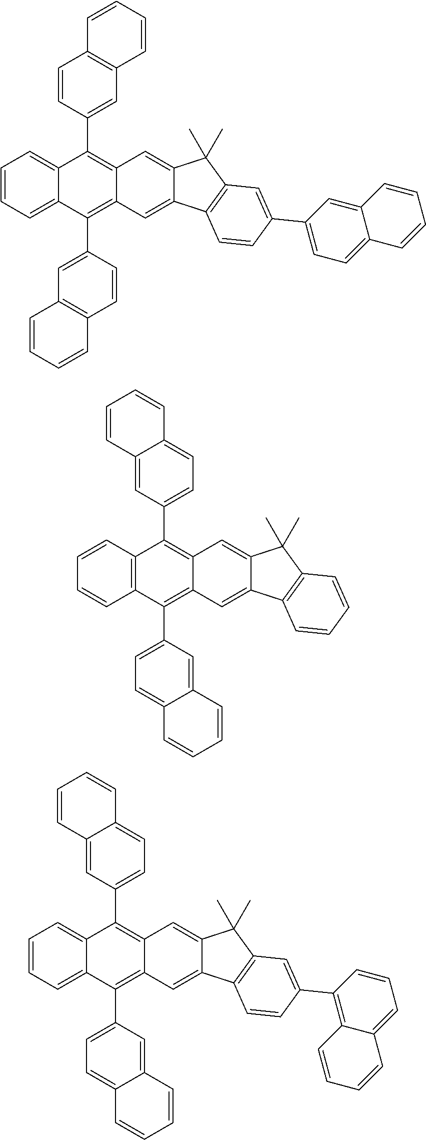

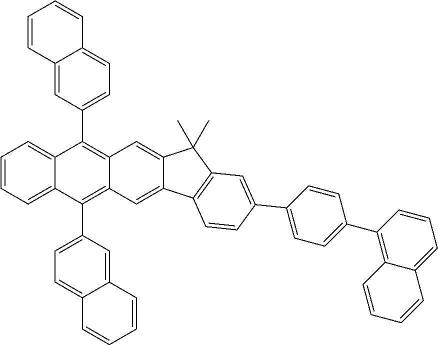 [SMILES: CC1(C)c2cc(-c3ccc(-c4cccc5ccccc45)cc3)ccc2-c2cc3c(-c4ccc5ccccc5c4)c4ccccc4c(-c4ccc5ccccc5c4)c3cc21]

When the organic light-emitting device 100 is a full color organic light-emitting device, the EML 133 may be patterned into a red emission layer, a green emission layer, and a blue emission layer to correspond to individual red, green, and blue subpixels, respectively. For example, the blue emission layer may include the indene-based compound of Formula 1 as a host.

In some embodiments, the EML 133 may have a multi-layer structure in which a red emission layer, a green emission layer and a blue emission layer are stacked upon one another, or a single-layer structure including a red light-emitting material, a green light-emitting material, and a blue light-emitting material, to emit white light. The organic light-emitting device 100 including the EML 133 may further include a red color filter, a green color filter, and a blue color filter to emit light in full-color.

Non-limiting examples of known blue dopants are ter-fluorene and compounds represented by the following formulae.

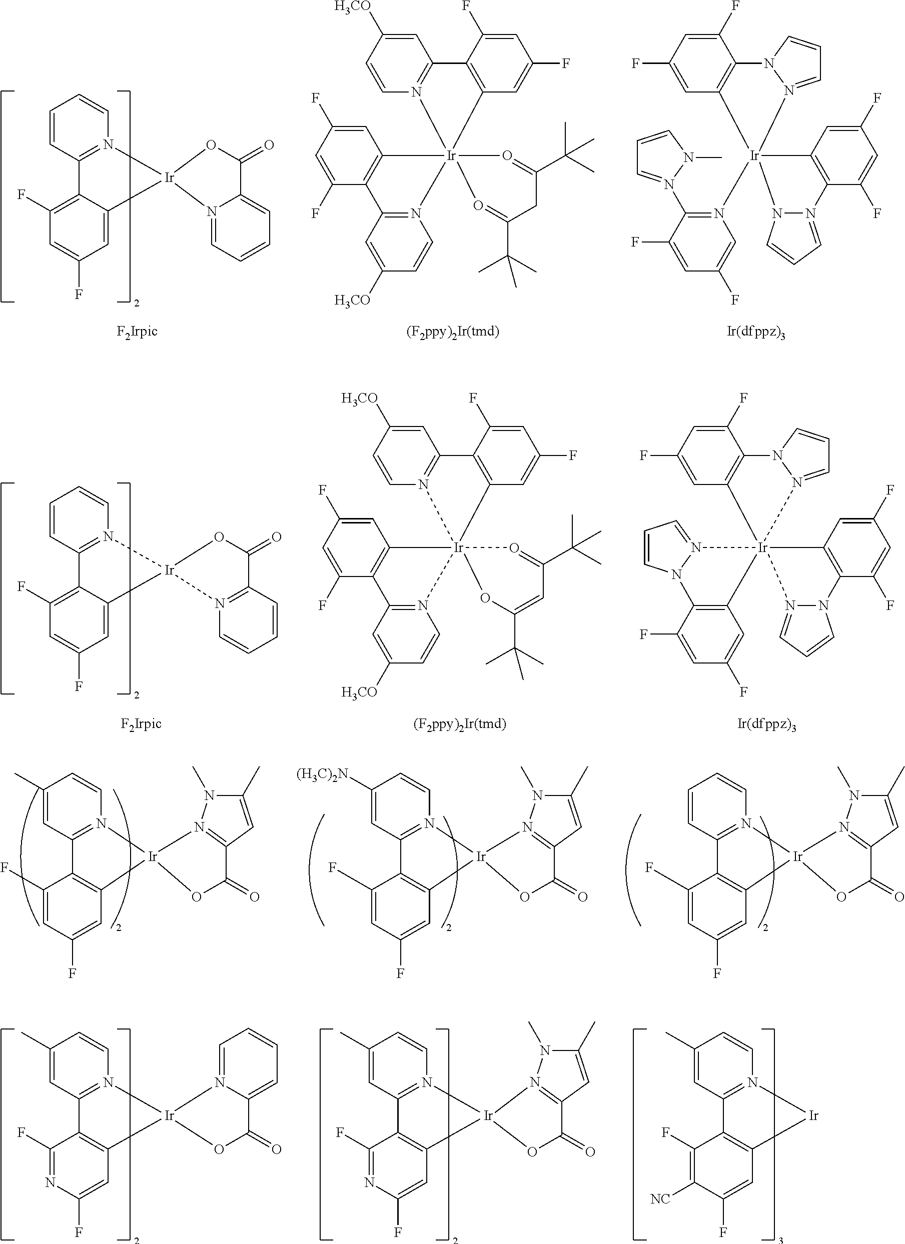

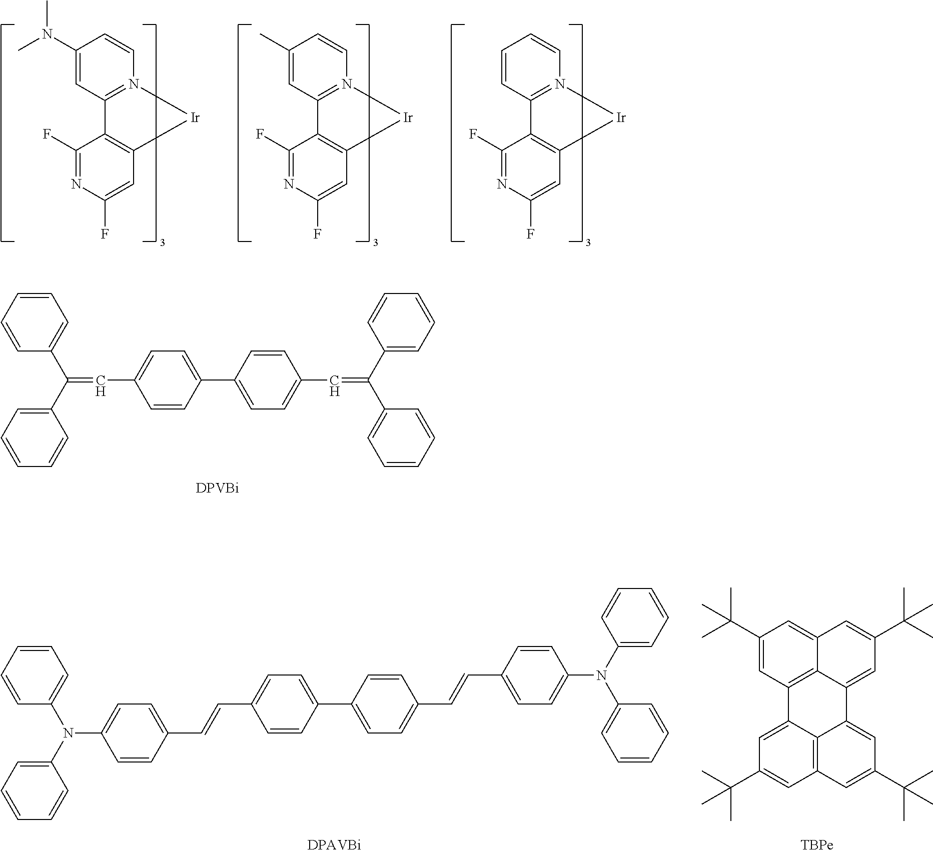

Non-limiting examples of known red dopants are compounds represented by the following formulae.

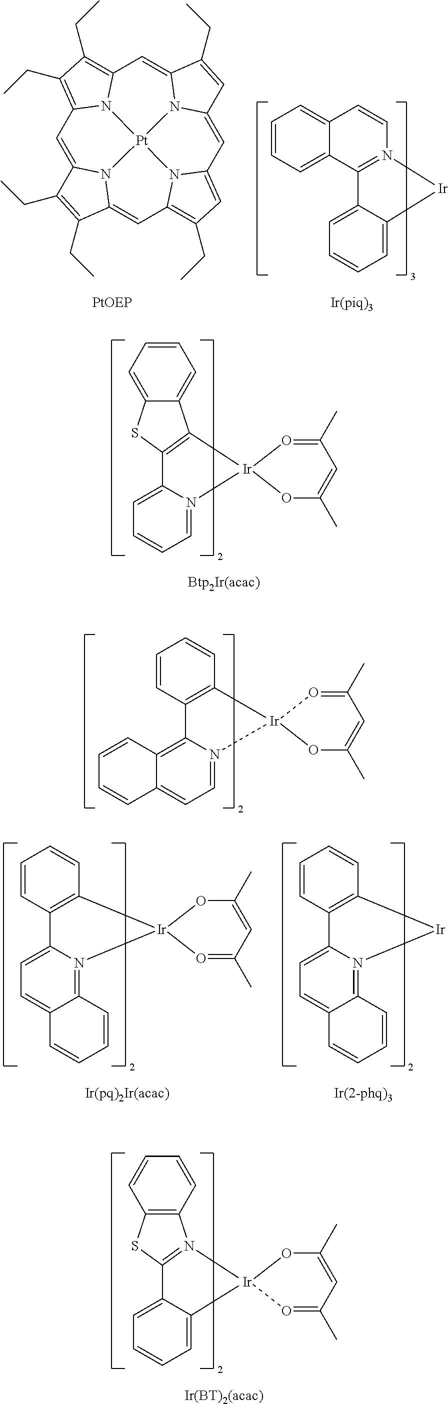

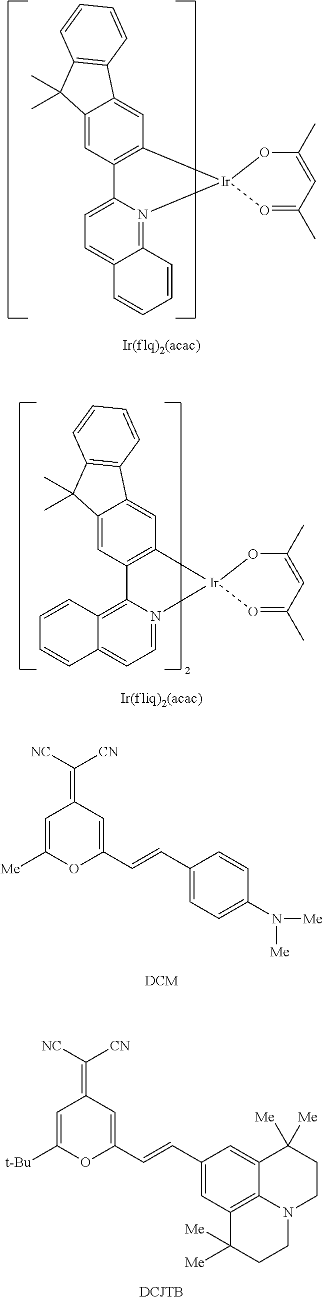

Non-limiting examples of known green dopants are compounds represented by the following formulae.

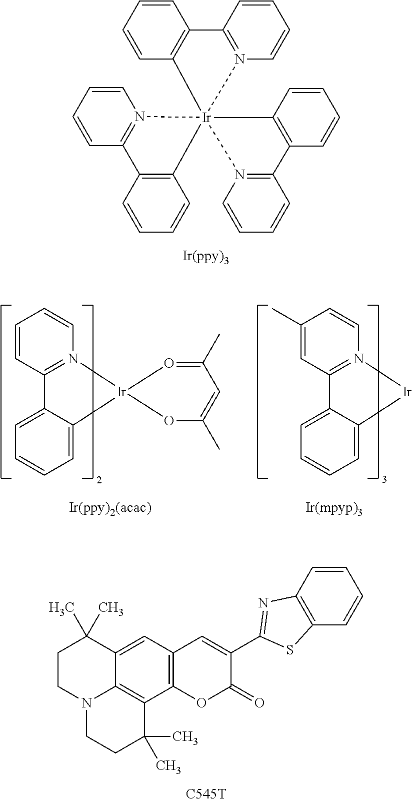

For example, the known dopant for the EML 133 may be a compound represented by Formula 100, but is not limited thereto:

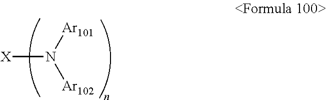

In Formula 100, X may be selected from a substituted or unsubstituted C₉-C₁₀cycloalkylene group, a substituted or unsubstituted C₉-C₁₀cycloalkenylene group, and a substituted or unsubstituted C₉-C₆₀arylene group; Ar₁₀₁ and Ar₁₀₂ may be each independently selected from a substituted or unsubstituted C₆-C₃₀ aryl group and a substituted or unsubstituted C₁-C₃₀ heteroaryl group; and n may be an integer of 2 to 4.

For example, X in Formula 100 may be selected from, but is not limited to, i) an anthracenylene group, a chrysenylene group, a pyrenylene group, and a benzopyrenylene group, and ii) an anthracenylene group, a chrysenylene group, a pyrenylene group, and a benzopyrenylene group, each substituted with at least one of a deuterium, —F, a cyano group, a nitro group, a methyl group, an ethyl group, an n-propyl group, an iso-propyl group, an n-butyl group, a sec-butyl group, an iso-butyl group, and a tert-butyl group.

In some embodiments, X in Formula 100 may be selected from, but is not limited to, an anthracenylene group, a chrysenylene group, a pyrenylene group, and a benzopyrenylene group.

For example, X in Formula 100 may be a pyrenylene group, but is not limited thereto.

For example, Ar₁₀₁ and Ar₁₀₂ in Formula 100 may be each independently selected from, but are not limited thereto, i) a phenyl group, a naphthyl group, and a biphenyl group, and ii) a phenyl group, a naphthyl group, and a biphenyl group, each substituted with at least one of a deuterium, —F, a cyano group, a nitro group, a methyl group, an ethyl group, an n-propyl group, an iso-propyl group, an n-butyl group, a sec-butyl group, an iso-butyl group, a tert-butyl group, and a phenyl group.

In some embodiments, Ar₁₀₁ and Ar₁₀₂ in Formula 100 may be each independently selected from, but are not limited thereto, i) a phenyl group and a biphenyl group, and ii) a phenyl group and a biphenyl group, each substituted with at least one of —F, a methyl group, and a phenyl group.

For example, n in Formula 100 may be an integer of 2, but is not limited thereto.

Non-limiting examples of the known dopant that may be used in the EML 133 are organometallic complexes represented by the following formulae.

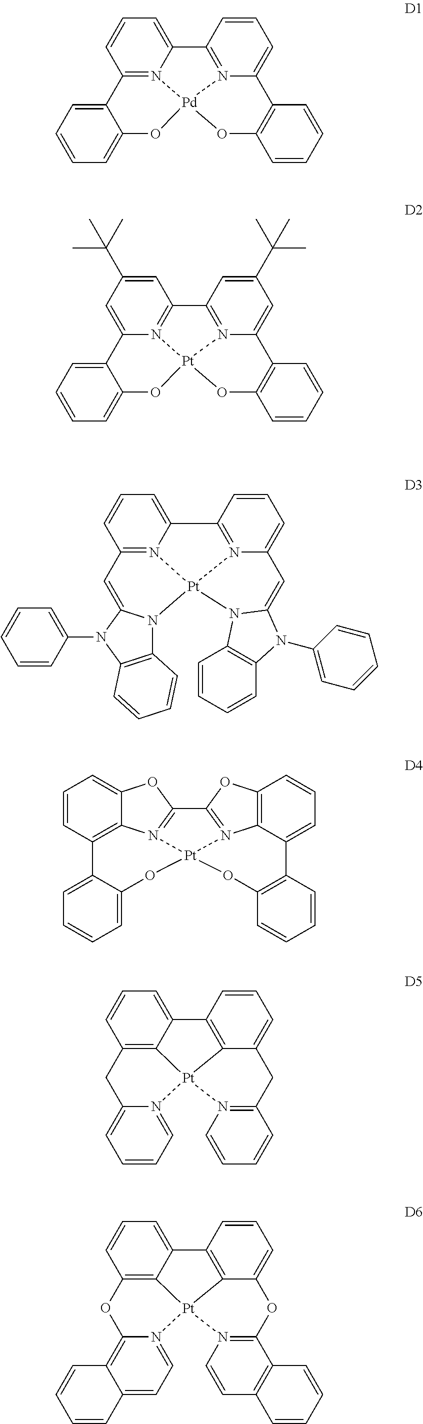

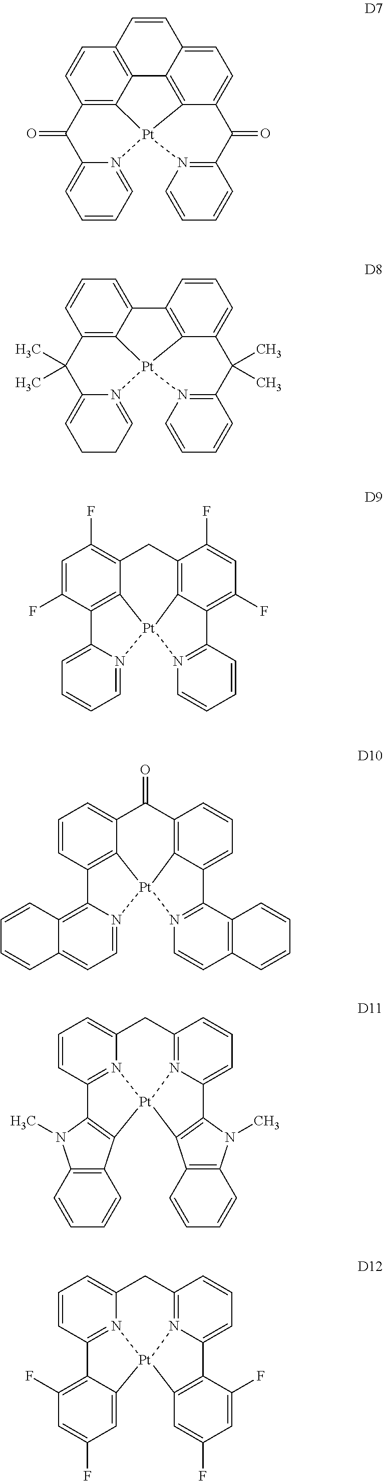

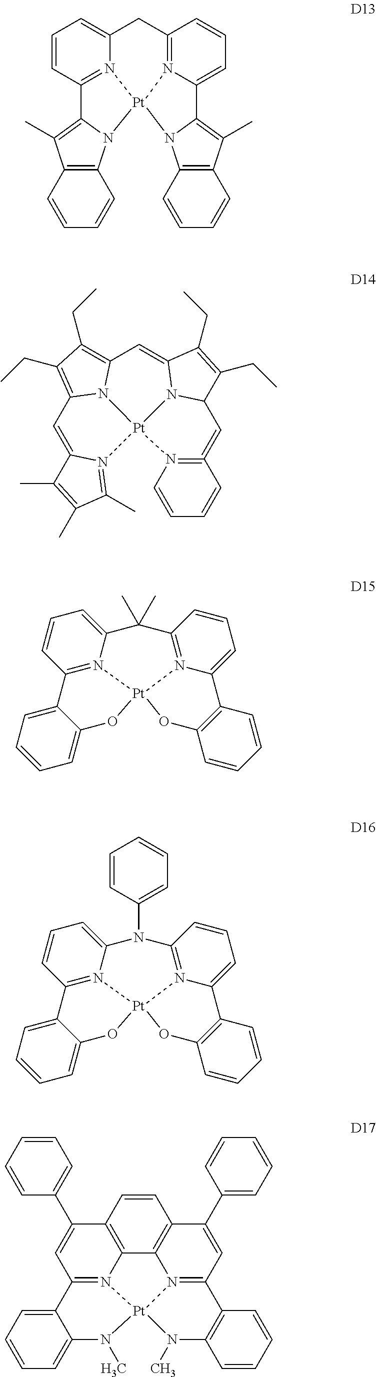

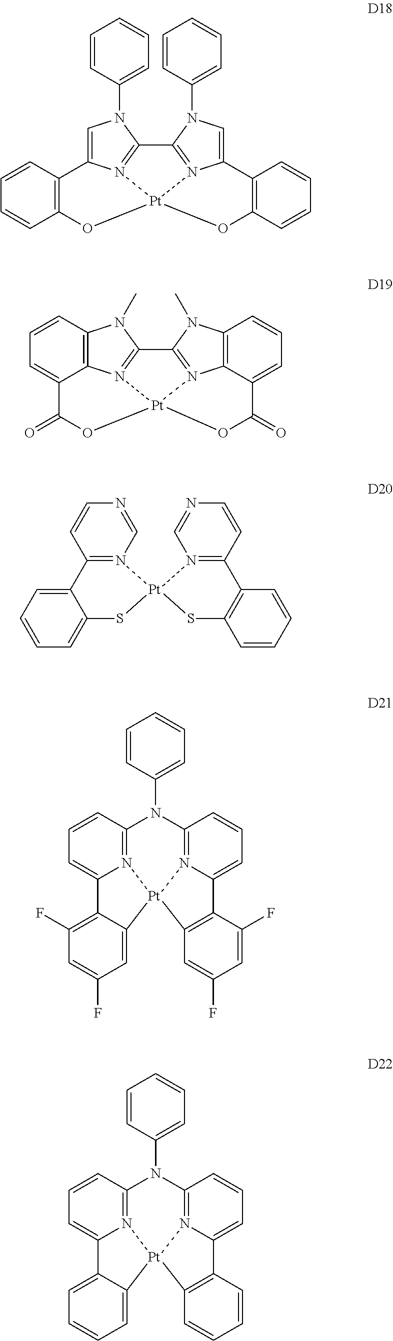

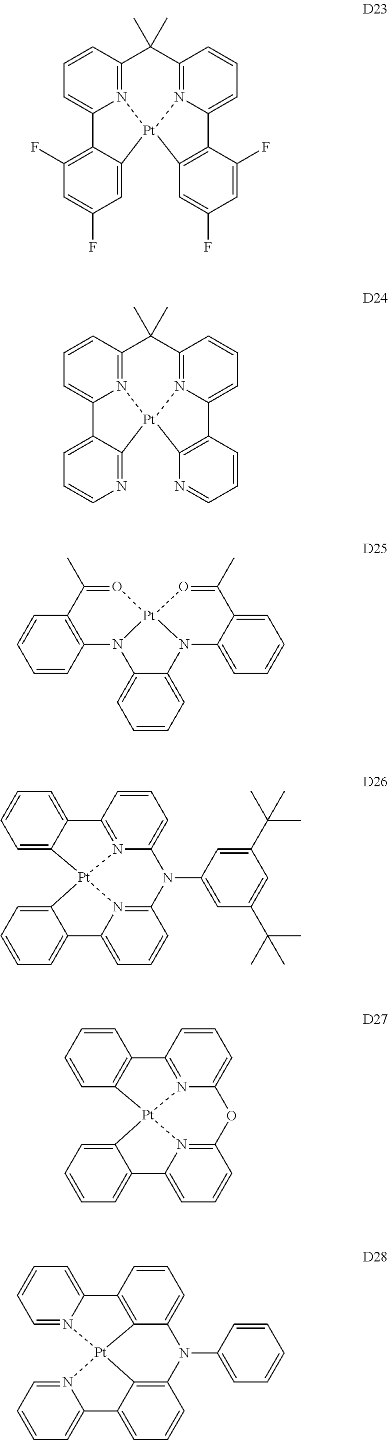

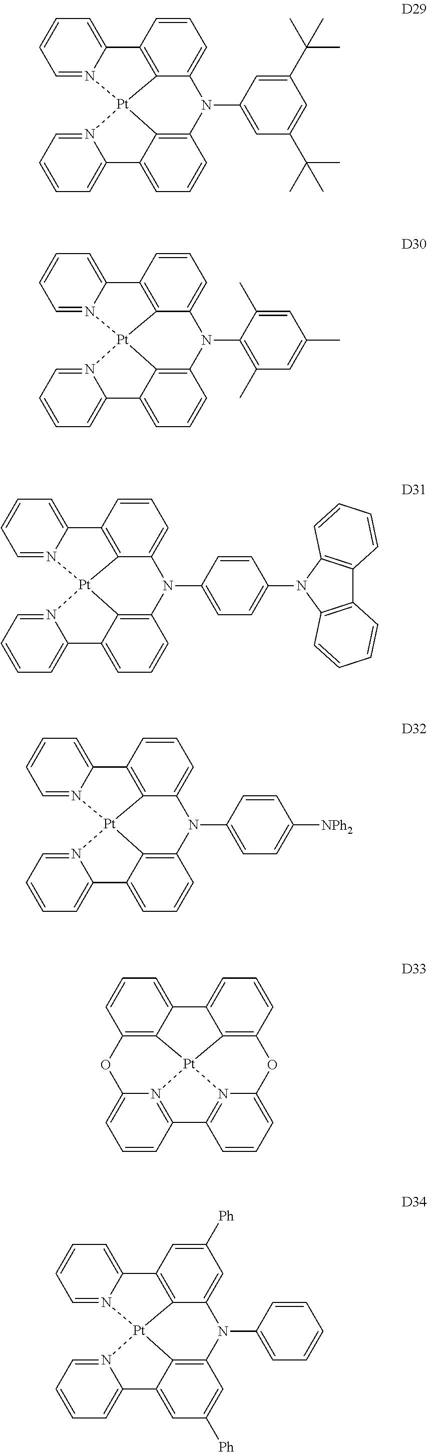

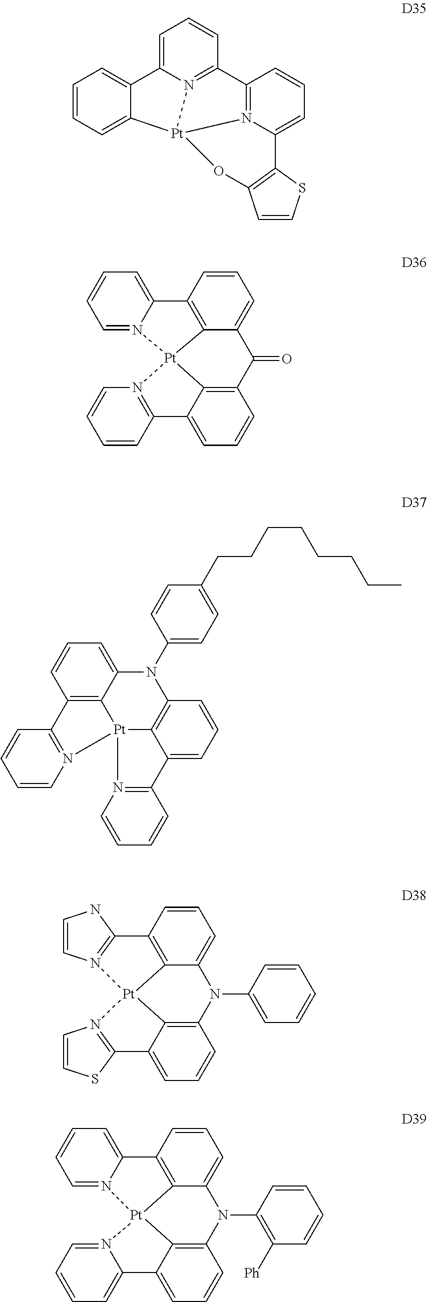

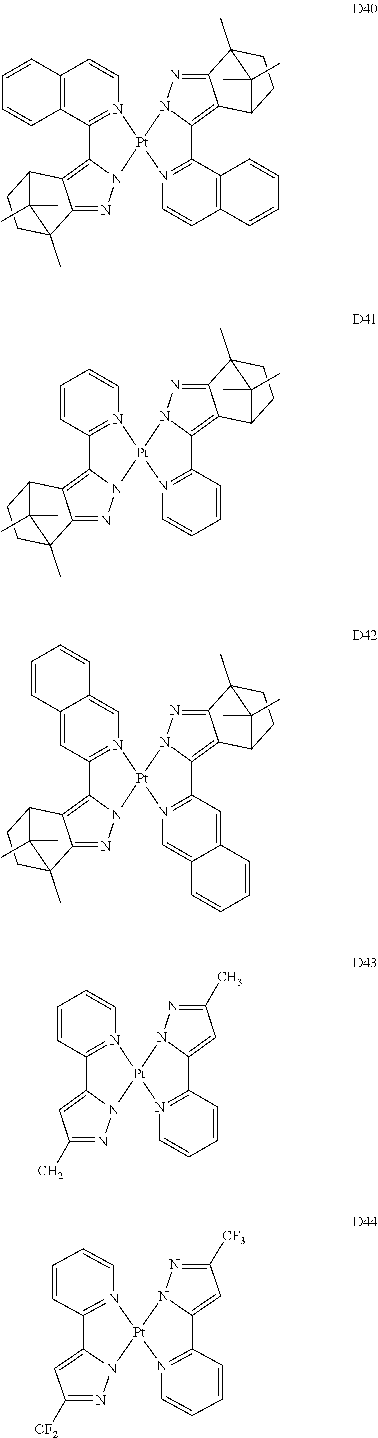

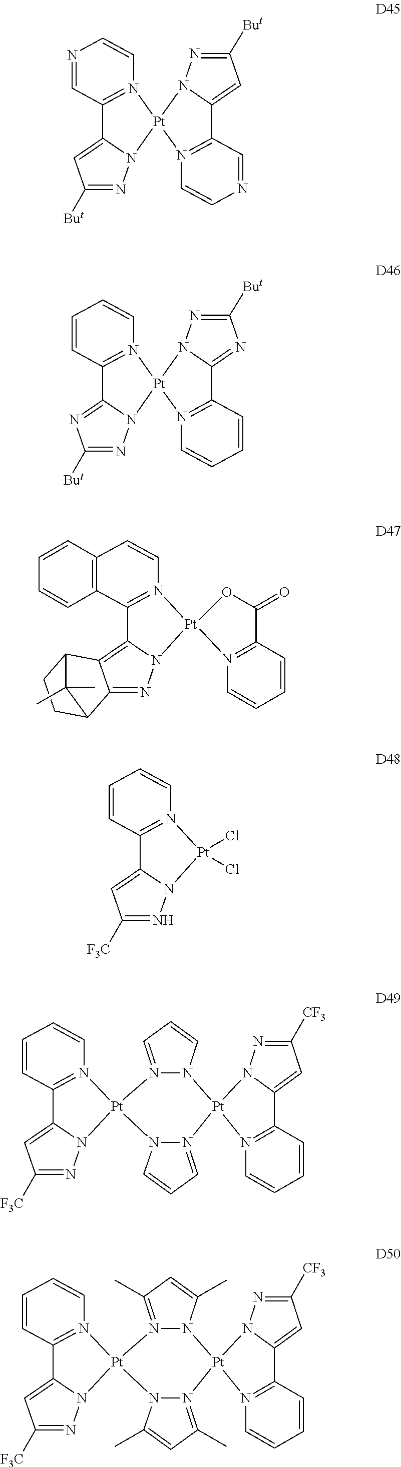

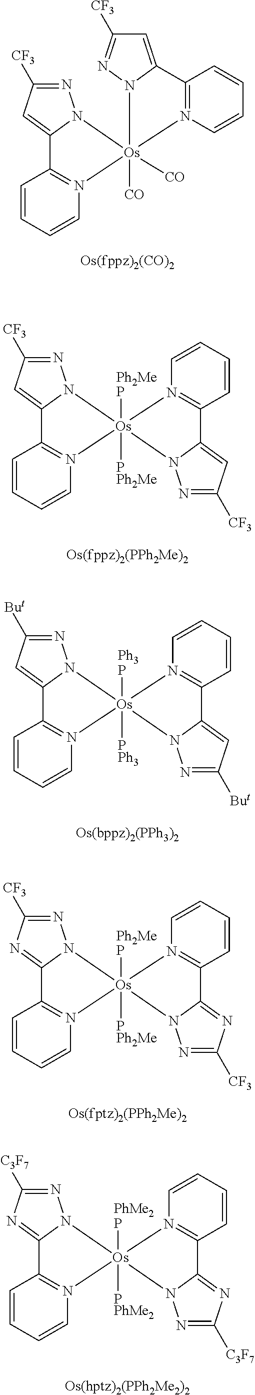

When the EML 133 includes both a host and a dopant, an amount of the dopant may be in a range of about 0.01 wt % to about 15 wt % based on 100 wt % of the EML 133. However, the amount of the dopant is not limited to this range.

A thickness of the EML 133 may be in a range of about 200 Å to about 700 Å. When the thickness of the EML 133 is within this range, the EML 133 may have good light emitting ability without a substantial increase in driving voltage.

Then, the ETL 134 may be formed on the EML 133 by any of a variety of methods, for example, vacuum deposition, spin coating, casting, or the like. When the ETL 134 is formed using vacuum deposition or spin coating, the deposition and coating conditions may be similar to those for the formation of the HIL 131, though the deposition and coating conditions may vary depending on the compound material that is used to form the ETL 134.

A material for forming the ETL 134 may be any known material that can stably transport electrons injected from an electron injecting electrode (cathode). Non-limiting examples of known materials for forming the ETL 134 are quinoline derivatives, such as tris(8-quinolinorate)aluminum (Alq₃), 3-(biphenyl-4-yl)-5-(4-tert-butylphenyl)-4-phenyl-4H-1,2,4-triazole (TAZ), bis(2-methyl-8-quinolinolato-N1,O8)-(1,1′-biphenyl) (B a1 q), beryllium bis(benzoquinolin-10-olate (Bebq₂), 9,10-di(naphthalene-2-yl)anthracene (ADN), Compound 101, Compound 102, and Bphen.

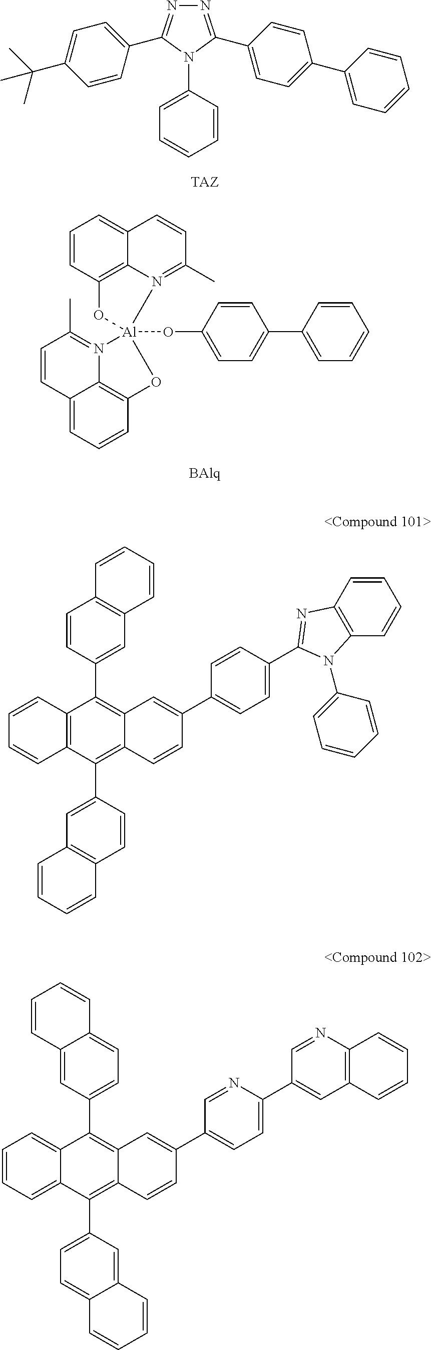

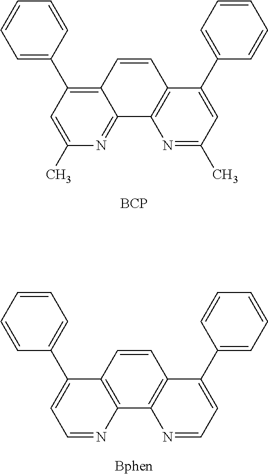 [SMILES: Cc1cc(-c2ccccc2)c2ccc3c(-c4ccccc4)cc(C)nc3c2n1 ; "BCP" ; c1ccc(-c2ccnc3c2ccc2c(-c4ccccc4)ccnc23)cc1]

The thickness of the ETL 134 may be in a range of about 50 Å to about 1,000 Å, and in some embodiments, about 100 Å to about 500 Å. When the thickness of the ETL 134 is within these ranges, the ETL 134 may have satisfactory electron transporting ability without a substantial increase in driving voltage.

In some embodiments, the ETL 134 may further include a metal-containing material, in addition to any known electron-transporting organic compound. The metal-containing material may include a lithium (Li) complex. Non-limiting examples of the Li complex are lithium quinolate (Liq) and Compound 203 below:

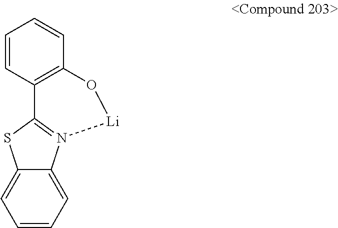

The EIL 135, which facilitates injection of electrons from the cathode, may be disposed on the ETL 134. Any suitable electron-injecting material may be used to form the EIL 135.

Non-limiting examples of materials for forming the EIL 135 are any EIL forming materials known in the art, for example, LiF, NaCl, CsF, Li₂O, and BaO. The deposition and spin coating conditions for forming the EIL 135 may be similar to those for the formation of the HIL 131, though the deposition and coating conditions may vary depending on the material that is used to form the EIL 135.

The thickness of the EIL 135 may be in a range of about 1 Å to about 100 Å, and in some embodiments, about 3 Å to about 90 Å. When the thickness of the EIL 135 is within these ranges, the EIL 135 may have satisfactory electron injection ability without a substantial increase in driving voltage.

The second electrode 140 may be disposed on the organic layer 130. The second electrode 140 may be a cathode as an electron injecting electrode. A material for forming the second electrode 140 may be a metal, an alloy, or an electrically conductive compound that have a low-work function, or a mixture thereof. Non-limiting examples of materials for the second electrode 9 are lithium (Li), magnesium (Mg), aluminum (Al), aluminum (Al)-lithium (Li), calcium (Ca), magnesium (Mg)-indium (In), and magnesium (Mg)-silver (Ag). For example, the second electrode 9 may be formed as a thin film type transmissive electrode by using these materials. In some embodiments, to manufacture a top-emission light-emitting device, the transmissive electrode may comprise indium tin oxide (ITO) or indium zinc oxide (IZO). However, embodiments of the present disclosure are not limited thereto.

When a phosphorescent dopant is used in the EML 133, a HBL may be formed between the ETL 134 and the EML 133 or between the H-functional layer and the EML 133 by using vacuum deposition, spin coating, casting, LB deposition, or the like, in order to prevent diffusion of triplet excitons or holes into the ETL 134. When the HBL is formed using vacuum deposition or spin coating, the conditions for deposition and coating may be similar to those for the formation of the HIL 131, though the conditions for deposition and coating may vary depending on the material that is used to form the HBL. A material for forming the HBL may be any known material used to form HBLs, for example, an oxadiazol derivative, a triazol derivative, or a phenanthroline derivative. For example, bathocuproine (BCP) represented by the following formula may be used as the material for forming the HBL.

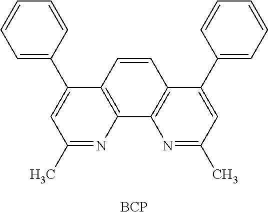 [SMILES: Cc1cc(-c2ccccc2)c2ccc3c(-c4ccccc4)cc(C)nc3c2n1 ; "BCP"]

The thickness of the HBL may be in a range of about 20 Å to about 1000 Å, and in some embodiments, about 30 Å to about 300 Å. When the thickness of the HBL is within these ranges, the HBL may have improved hole blocking ability without a substantial increase in driving voltage.

Although the organic light-emitting device of FIG. 1 is described above, embodiments of the present disclosure are not limited thereto.

As used herein, the unsubstituted C₁-C₆₀ alkyl group (or a C₁-C₆₀ alkyl group) may be a linear or branched alkyl group having 1 to 60 carbon atoms, for example, a methyl group, an ethyl group, a propyl group, an isobutyl group, a sec-butyl group, a pentyl group, an iso-amyl group, or a hexyl group. A substituted C₁-C₆₀ alkyl group refers to such an unsubstituted C₁-C₆₀ alkyl group of which at least one hydrogen atom is substituted with one of

a deuterium, —F, —Cl, —Br, —I, a hydroxyl group, a cyano group, a nitro group, an amino group, an amidino group, a hydrazine, a hydrazone, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one of a deuterium, —F, —Cl, —Br, —I, a hydroxyl group, a cyano group, a nitro group, an amino group, an amidino group, a hydrazine, a hydrazone, a carboxylic acid group or a salt thereof, a sulfonic acid group or a salt thereof, and a phosphoric acid group or a salt thereof;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, and a C₁-C₆₀ heteroaryl group;

a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, and a C₁-C₆₀ heteroaryl group, each substituted with at least one of a deuterium, —F, —Cl, —Br, —I, a hydroxyl group, a cyano group, a nitro group, an amino group, an amidino group, a hydrazine, a hydrazone, a carboxylic acid group or a salt thereof, a sulfonic acid group or a salt thereof, a phosphoric acid group or a salt thereof, a C₁-C₆₀ alkyl group, a C₂-C₆₀ alkenyl group, a C₂-C₆₀ alkynyl group, a C₁-C₆₀ alkoxy group, phenyl group, a naphthyl group, an anthryl group, a fluorenyl group, a dimethylfluorenyl group, a diphenylfluorenyl group, a carbazolyl group, a phenylcarbazolyl group, a pyridyl group, a pyrimidinyl group, a pyrazinyl group, a pyridazinyl group, a triazinyl group, a quinolyl group, and an isoquinolyl group; and —N(Q₁₁)(Q₁₂); and —Si(Q₁₃)(Q₁₄)(Q₁₅), wherein Q₁₁ and Q₁₂ may be each independently a C₆-C₆₀ aryl group, or a C₁-C₆₀ heteroaryl group, and Q₁₃ to Q₁₅ may be each independently a C₁-C₆₀ alkyl group, a C₁-C₆₀ alkoxy group, a C₆-C₆₀ aryl group, or a C₁-C₆₀ heteroaryl group.

As used herein, the unsubstituted C₁-C₆₀ alkoxy group (or a C₁-C₆₀ alkoxy group) may be a group represented by —OA, wherein A is an unsubstituted C₁-C₆₀ alkyl group described above. Examples of the unsubstituted C₁-C₆₀ alkoxy group are a methoxy group, an ethoxy group, and an isopropyloxy group. At least one of the hydrogen atoms in the alkoxy group may be substituted with the substituents described above in conjunction with the substituted C₁-C₆₀ alkyl group.

As used herein, the unsubstituted C₂-C₆₀ alkenyl group (or a C₂-C₆₀ alkenyl group) is a C₂-C₆₀ alkyl group having at least one carbon-carbon triple bond in the center or at a terminal thereof. Examples of the alkenyl group are an ethenyl group, a propenyl group, a butenyl group, and the like. At least one hydrogen atom in the C₂-C₆₀ alkenyl group may be substituted with those substituents described above in conjunction with the substituted C₁-C₆₀ alkyl group.

As used herein, the unsubstituted C₂-C₆₀ alkynyl group (or a C₂-C₆₀ alkynyl group) is a C₂-C₆₀ alkyl group having at least one carbon-carbon triple bond in the center or at a terminal thereof. Examples of the unsubstituted C₂-C₆₀ alkynyl group (or a C₂-C₆₀ alkynyl group) are an ethenyl group, a propynyl group, and the like. At least one hydrogen atom in the C₂-C₆₀ alkynyl group may be substituted with those substituents described above in conjunction with the substituted C₁-C₆₀ alkyl group.

As used herein, the unsubstituted C₃-C₃₀ cycloalkyl group indicates a cyclic, monovalent C3-C30 saturated hydrocarbon group. Non-limiting examples of the unsubstituted C₃-C₃₀ cycloalkyl group are a cyclopropyl group, a cyclobutyl group, a cyclopentyl group, a cyclohexyl group, and a cyclooctyl group. At least one hydrogen atom in the cycloalkyl group may be substituted with those substituents described above in conjunction with the substituted C₁-C₆₀ alkyl group.

As used herein, the unsubstituted C₃-C₃₀ cycloalkenyl group indicates a nonaromatic, cyclic unsaturated hydrocarbon group with at least one carbon-carbon double bond. Examples of the unsubstituted C3-C60 cycloalkenyl group are a cyclopropenyl group, a cyclobutenyl group, a cyclopentenyl group, a cyclohexcenyl group, a cycloheptenyl group, a 1,3-cyclohexadienyl group, a 1,4-cyclohexadienyl group, a 2,4-cycloheptadienyl group, and a 1,5-cyclooctadienyl group. At least one hydrogen atom in the cycloalkenyl group may be substituted with those substituents described above in conjunction with the substituted C₁-C₆₀ alkyl group.

As used herein, the unsubstituted C₆-C₆₀ aryl group is a monovalent group having a carbocyclic aromatic system having 6 to 60 carbon atoms including at least one aromatic ring. The unsubstituted C₆-C₆₀ arylene group is a divalent group having a carbocyclic aromatic system having 6 to 60 carbon atoms including at least one aromatic ring. When the aryl group or the arylene group have at least two rings, they may be fused to each other via a single bond. At least one hydrogen atom in the aryl group and the arylene group may be substituted with those substituents described above in conjunction with the C₁-C₆₀ alkyl group.

Examples of the substituted or unsubstituted C₆-C₆₀ aryl group are a phenyl group, a C₁-C₁₀ alkylphenyl group (e.g., an ethylphenyl group), a C₁-C₁₀ alkylbiphenyl group (e.g., an ethylbiphenyl group), a halophenyl group (e.g., an o-, m- or p-fluorophenyl group and a dichlorophenyl group), a dicyanophenyl group, a trifluoromethoxyphenyl group, an o-, m- or p-tolyl group, an o-, m- or p-cumenyl group, a mesityl group, a phenoxyphenyl group, a (α,α-dimethylbenzene)phenyl group, a (N,N′-dimethyl)aminophenyl group, a (N,N′-diphenyl)aminophenyl group, a pentalenyl group, an indenyl group, a naphthyl group, a halonaphthyl group (e.g., a fluoronaphthyl group), a C₁-C₁₀ alkylnaphthyl group (e.g., a methylnaphthyl group), a C₁-C₁₀ alkoxynaphthyl group (e.g., a methoxynaphthyl group), an anthracenyl group, an azulenyl group, a heptalenyl group, an acenaphthylenyl group, a phenalenyl group, a fluorenyl group, an anthraquinolinyl group, a methylanthryl group, a phenanthryl group, a triphenylenyl group, a pyrenyl group, a chrysenyl group, an ethyl-chrysenyl group, a picenyl group, a perylenyl group, a chloroperylenyl group, a pentaphenyl group, a pentacenyl group, a tetraphenylenyl group, a hexaphenyl group, hexacenyl group, a rubicenyl group, a coronenyl group, a trinaphthylenyl group, a heptaphenyl group, a heptacenyl group, a pyranthrenyl group, and an ovalenyl group. Examples of the substituted C₆-C₆₀ aryl group may be inferred based on those of the unsubstituted C₆-C₆₀ aryl group and the substituted C₁-C₃₀ alkyl group described above. Examples of the substituted or unsubstituted C₆-C₆₀ arylene group may be inferred based on those examples of the substituted or unsubstituted C₆-C₆₀ aryl group described above.

As used herein, the unsubstituted C₁-C₆₀ heteroaryl group is a monovalent carbocyclic aromatic system having at least one aromatic ring and at least one of the heteroatoms selected from the group consisting of N, O, P, and S as a ring-forming atom. The unsubstituted C₁-C₆₀ heteroarylene group is a divalent carbocyclic aromatic system having at least one aromatic ring and at least one aromatic ring and at least one of the heteroatoms selected from the group consisting of N, O, P, and S. In this regard, when the heteroaryl group and the heteroarylene group have at least two rings, they may be fused to each other via a single bond. At least one hydrogen atom in the heteroaryl group and the heteroarylene group may be substituted with those substituents described with reference to the C₁-C₆₀ alkyl group.

Examples of the unsubstituted C₁-C₆₀ heteroaryl group are a pyrazolyl group, an imidazolyl group, an oxazolyl group, a thiazolyl group, a triazolyl group, a tetrazolyl group, an oxadiazolyl group, a pyridinyl group, a pyridazinyl group, a pyrimidinyl group, a triazinyl group, a carbazolyl group, an indolyl group, a quinolinyl group, an isoquinolinyl group, a benzoimidazolyl group, an imidazopyridinyl group and an imidazopyrimidinyl group. Examples of the substituted or unsubstituted C₁-C₆₀ heteroarylene group may be inferred based on those examples of the substituted or unsubstituted C₂-C₆₀ arylene group described above.

As used herein, the substituted or unsubstituted C₆-C₆₀ aryloxy group indicates —OA₂ (where A₂ is a substituted or unsubstituted C₆-C₆₀ aryl group described above). The substituted or unsubstituted C₆-C₆₀ arylthiol group indicates SA₃ (where A₃ is a substituted or unsubstituted C₆-C₆₀ aryl group described above).

Hereinafter, the present disclosure will be described in detail with reference to the following synthesis examples and other examples. However, these examples are for illustrative purposes only and are not intended to limit the scope of the present disclosure.

### EXAMPLES

### Synthesis Example 1

### Synthesis of Compound 1

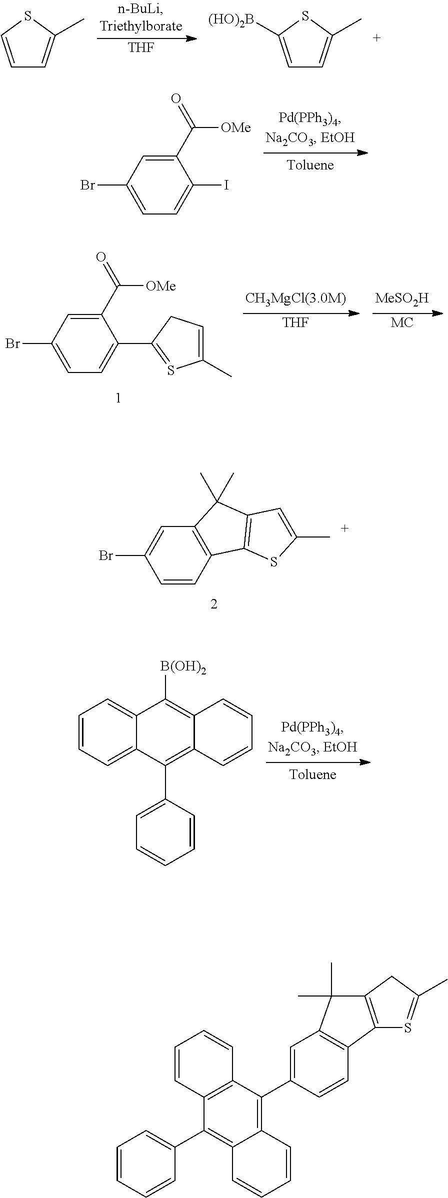

3.6 g (17.3 mmol) of 2-methylthiophene was reacted with n-butyl lithium and triethyl borate at about 78° C. to obtain 4.42 g of 5-methylthiophene-2-ylboronic acid (Yield: 85%). 4.42 g of 5-methylthiophene-2-ylboronic acid was reacted with 5-bromo-2-iodo-benzoic acid methyl ester at about 80° C. for Suzuki coupling to synthesize 7.78 g of Intermediate 1 (Yield: 80%). Intermediate 1 was reacted with CH₃MgCl for cyclization to obtain 3.14 g of Intermediate 2 (Yield: 40%). Intermediate 2 was reacted with 9-phenyl anthracene boronic acid for Suzuki coupling to obtain 3.3 g of compound 1 (Yield: 60%). This compound 1 was identified using ¹H nuclear magnetic resonance (¹H-NMR) and mass spectroscopy (MS).

¹H-NMR: 7.91 (d, 4H), 7.48 (d, 2H), 7.39 (t, 4H), 7.32 (t, 2H), 7.30 (s, 1H), 7.28 (s, 1H), 7.25 (d, 1H), 7.22 (t, 1H), 2.0 (s, 1H), 1.49 (m, 6H), 0.9 (s, 3H).

m/e: 467.18

### Synthesis Example 2

### Synthesis of Compound 10

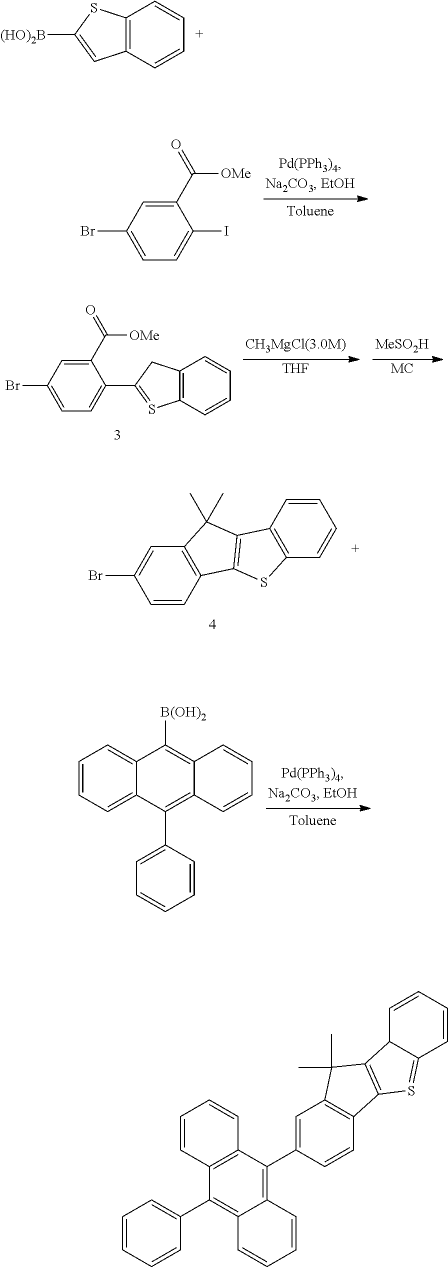

4.1 g (19.5 mmol) of 2-benzothiophene boronic acid was reacted with 5-bromo-2-iodo-benzoic acid methyl ester at about 80° C. for Suzuki coupling to synthesize 6.03 g of Intermediate 3 (Yield: 78%). Intermediate 3 was reacted with CH₃MgCl for cyclization to obtain 2.57 g of Intermediate 4 (Yield: 45%). Intermediate 4 was reacted with 9-phenyl anthracene boronic acid for Suzuki coupling to obtain 2.45 g of compound 1 (Yield: 70%). This compound 10 was identified using ¹H-NMR and MS.

¹H-NMR: 7.91 (d, 4H), 7.48 (d, 2H), 7.39 (t, 4H), 7.32 (t, 2H), 7.30 (s, 1H), 7.28 (s, 1H), 7.25 (d, 1H), 7.22 (t, 1H), 6.5 (s, 1H), 6.16 (s, 1H), 5.66 (s, 1H), 5.2 (s, 1H), 2.9 (s, 1H), 1.49 (m, 6H)

m/e: 503.18

### Synthesis Example 3

### Synthesis of Compound 13

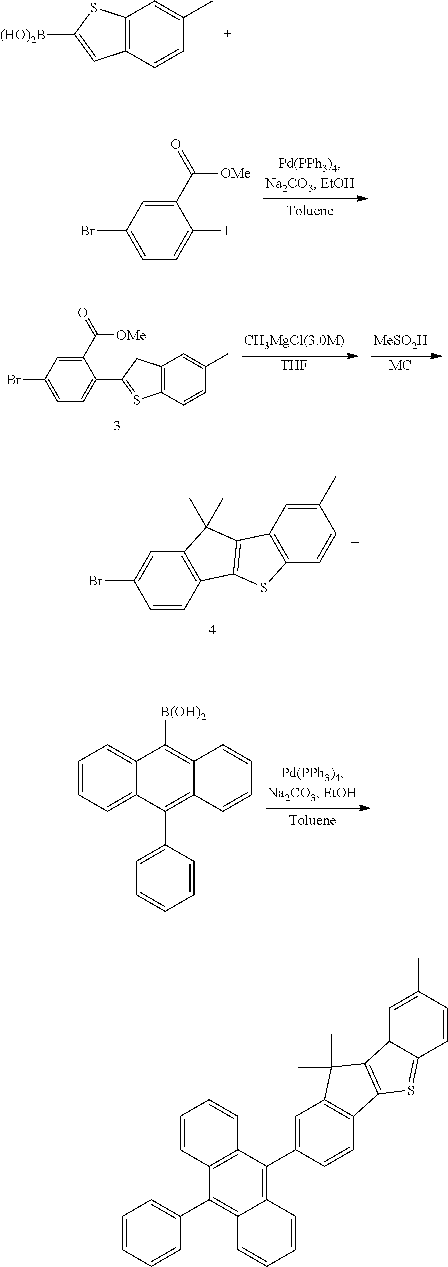

4.4 g (21.5 mmol) of 6-benzothiophene boronic acid was reacted with 5-bromo-2-iodo-benzoic acid methyl ester at about 80° C. for Suzuki coupling to synthesize 6.20 g of Intermediate 5 (Yield: 81%). Intermediate 5 was reacted with CH₃MgCl for cyclization to obtain 2.72 g of Intermediate 6 (Yield: 48%). Intermediate 6 was reacted with 9-phenyl anthracene boronic acid for Suzuki coupling to obtain 4.2 g of compound 13 (Yield: 65%). This compound 13 was identified using ¹H-NMR and MS.

¹H-NMR: 7.91 (d, 4H), 7.48 (d, 2H), 7.39 (t, 4H), 7.32 (t, 2H), 7.30 (s, 1H), 7.28 (s, 1H), 7.25 (d, 1H), 7.22 (t, 1H), 6.5 (s, 1H), 5.44 (s, 1H), 5.2 (s, 1H), 2.9 (s, 1H), 2.0 (s, 1H), 1.49 (m, 6H), 1.71 (s, 3H).

m/e: 517.20

### Synthesis Example 4

### Synthesis of Compound 19

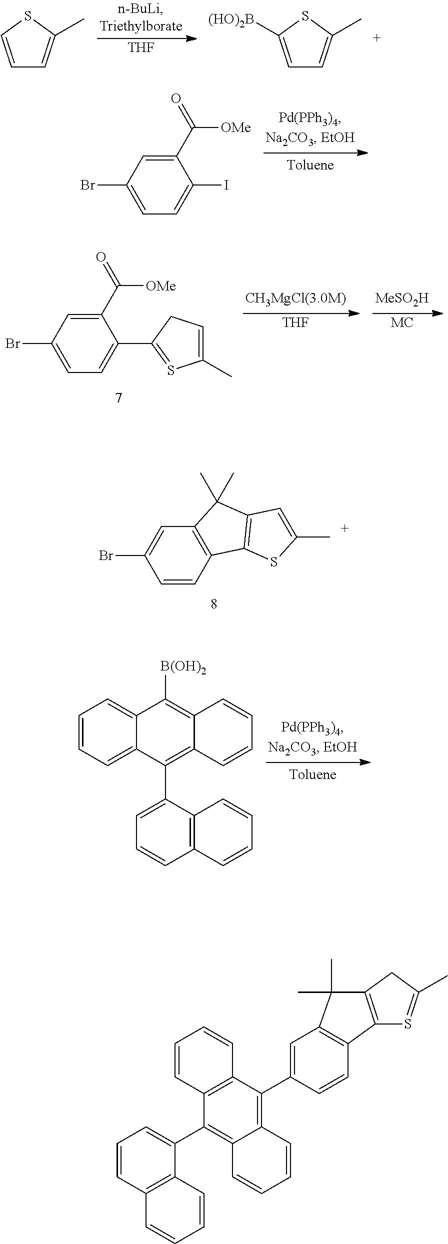

4.1 g (19.5 mmol) of 2-methylthiophene was reacted with n-butyl lithium and triethyl borate at about 78° C. to obtain 5.03 g of 5-methylthiophene-2-ylboronic acid (Yield: 85%). 5.03 g of 5-methylthiophene-2-ylboronic acid was reacted with 5-bromo-2-iodo-benzoic acid methyl ester at about 80° C. for Suzuki coupling to synthesize 6.2 g of Intermediate 7 (Yield: 82%). Intermediate 7 was reacted with CH₃MgCl for cyclization to obtain 2.74 g of Intermediate 8 (Yield: 41%). Intermediate 8 was reacted with 9-phenyl anthracene boronic acid for Suzuki coupling to obtain 4.7 g of compound 19 (Yield: 68%). This compound 19 was identified using ¹H-NMR and MS.

¹H-NMR: 7.91 (d, 4H), 7.67 (d, 1H), 7.63 (d, 1H), 7.54 (d, 1H), 7.39 (t, 4H), 7.38 (t, 1H), 7.32 (t, 2H), 7.30 (s, 1H), 7.28 (s, 1H), 7.25 (d, 1H), 2.0 (s, 1H), 1.49 (m, 6H), 0.9 (s, 3H).

m/e: 517.20

### Example 1

To manufacture an anode, a corning 15 Ω/cm² (1200 Å) ITO glass substrate was cut to a size of 50 mm×50 mm×0.7 mm and then sonicated in isopropyl alcohol and pure water each for five minutes, and then cleaned by irradiation of ultraviolet rays for 30 minutes and exposure to ozone for about 10 minutes. The resulting glass substrate was loaded into a vacuum deposition device.

Then, 4,4′,4″-tris[2-naphthyl(phenyl)amino]triphenylamine (2-TNATA) was vacuum-deposited on the ITO layer to form a HIL having a thickness of 600 Å, and then N,N′-bis(naphthalene-1-yl)-N,N′-bis(dipheny)-benzidine (NPB) was then vacuum-deposited on the HIL to form a HTL having a thickness of 300 Å.

Compound 1 (host) and F₂Irpic (dopant) were co-deposited on the HTL in a weight ratio of about 95:5 to form an EML having a thickness of about 200 Å.

Then, compound 201 was vacuum-deposited on the EML to form an ETL having a thickness of about 300 Å, and then LiF was vacuum-deposited on the ETL to form an EIL having a thickness of about 10 Å. Then, Al was vacuum-deposited on the EIL to form a cathode having a thickness of about 3000 Å, thereby completing the manufacture of an organic light-emitting device.

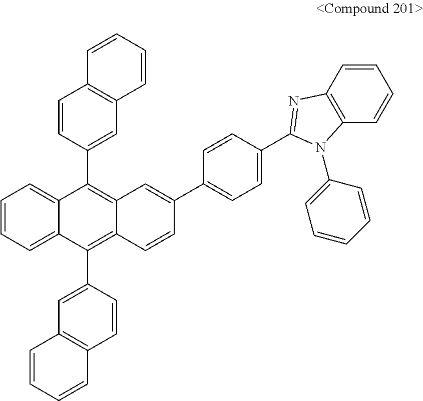 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

The organic light-emitting device had a driving voltage of 3.8 V at a current density of 10 mA/cm², a luminance of 413 cd/m², and an emission efficiency of 4.01 cd/A.

### Example 2

An organic light-emitting device was manufactured in the same manner as in Example 1, except that compound 10 instead of compound 1 was used to form the EML.

The organic light-emitting device had a driving voltage of 3.9 V at a current density of 10 mA/cm², a luminance of 394 cd/m², and an emission efficiency of 3.79 cd/A.

### Example 3

An organic light-emitting device was manufactured in the same manner as in Example 1, except that compound 13 instead of compound 1 was used to form the EML.

The organic light-emitting device had a driving voltage of 3.8 V at a current density of 10 mA/cm², a luminance of 425 cd/m², and an emission efficiency of 4.53 cd/A.

### Example 4

An organic light-emitting device was manufactured in the same manner as in Example 1, except that compound 19 instead of compound 1 was used to form the EML.

The organic light-emitting device had a driving voltage of 3.7 V at a current density of 10 mA/cm², a luminance of 381 cd/m², and an emission efficiency of 3.64 cd/A.

### Comparative Example 1

An organic light-emitting device was manufactured in the same manner as in Example 1, except that 9,10-di(naphthalene-2-yl)anthracene (ADN) instead of compound 1 was used to form the EML.

The organic light-emitting device had a driving voltage of 4.2V at a current density of 10 mA/cm², a luminance of 328 cd/m², and an emission efficiency of 3.10 cd/A.

### Comparative Example 2

An organic light-emitting device was manufactured in the same manner as in Example 1, except that compound A below, instead of compound 1, was used to form the EML.

The organic light-emitting device had a driving voltage of 4.4V at a current density of 10 mA/cm², a luminance of 346 cd/m², and an emission efficiency of 3.31 cd/A.

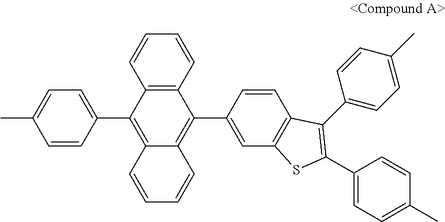

### Comparative Example 3

An organic light-emitting device was manufactured in the same manner as in Example 1, except that compound B below, instead of compound 1, was used to form the EML.

The organic light-emitting device had a driving voltage of 4.5V at a current density of 10 mA/cm², a luminance of 350 cd/m², and an emission efficiency of 3.27 cd/A.

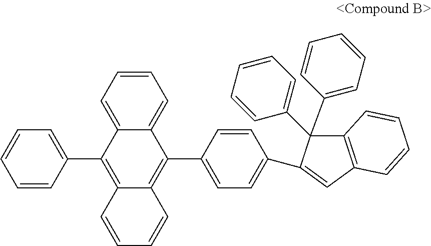 [SMILES: C1=C(c2ccc(-c3c4ccccc4c(-c4ccccc4)c4ccccc34)cc2)C(c2ccccc2)(c2ccccc2)c2ccccc21]

### Evaluation Example

Driving voltages, luminances, and efficiencies of the organic light-emitting devices of Examples 1 to 4 and Comparative Examples 1 to 3 were measured using a PR650 (Spectroscan) Source Measurement Unit (available from Photo Research, Inc.) while supplying power using a Kethley Source-Measure Unit (SMU 236). The results are shown in Table 1 below.

TABLE 1

| | | | Driving | | |
|---|---|---|---|---|---|
| | | Dopant | voltage | Luminance | Efficiency |
| Example | Host material | material | (V) | (cd/m²) | (cd/A) |
| Example 1 | Compound 1 | F₂Irpic | 3.8 | 413 | 4.01 |
| Example 2 | Compound 10 | F₂Irpic | 3.9 | 394 | 3.79 |
| Example 3 | Compound 13 | F₂Irpic | 3.8 | 425 | 4.53 |
| Example 4 | Compound 19 | F₂Irpic | 3.7 | 381 | 3.64 |
| Comparative | ADN | F₂Irpic | 4.2 | 328 | 3.10 |
| Example 1 | | | | | |
| Comparative | Compound A | F₂Irpic | 4.4 | 346 | 3.31 |
| Example 2 | | | | | |
| Comparative | Compound B | F₂Irpic | 4.5 | 350 | 3.27 |
| Example 3 | | | | | |

Referring to Table 1, the organic light-emitting devices of Examples 1 to 4 were found to have improved driving voltages, improved luminances, and improved efficiency characteristics, compared to the organic light-emitting devices of Comparative Examples 1 to 3.

As described above, according to the one or more of the above embodiments of the present disclosure, a high-quality organic light-emitting device, and more particularly, a high-quality organic light-emitting device emitting blue light may be manufactured by using any of the indene-based compounds of Formula 1 in an organic layer thereof

It should be understood that the example embodiments described therein should be considered in a descriptive sense only and not for purposes of limitation. Descriptions of features or aspects within each embodiment should typically be considered as available for other similar features or aspects in other embodiments.

While one or more embodiments of the present disclosure have been described with reference to the figures, it will be understood by those of ordinary skill in the art that various changes in form and details may be made therein without departing from the spirit and scope of the present disclosure as defined by the following claims.

What is claimed is:

1. A compound represented by Formula 1: 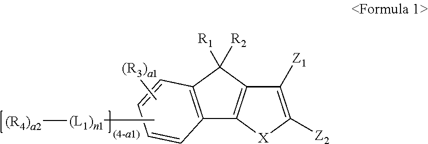
wherein,
X is an oxygen atom, a sulfur atom, NQ₁, or CQ₂Q₃;
L₁ is selected from a substituted or unsubstituted C₃-C₁₀ cycloalkylene group, a substituted or unsubstituted C₃-C₁₀ cycloalkenylene group, a substituted or unsubstituted C₆-C₆₀ arylene group, a substituted or unsubstituted C₁-C₁₀ heterocycloalkylene group, a substituted or unsubstituted C₁-C₁₀ heterocycloalkenylene group, and a substituted or unsubstituted C₁-C₆₀ heteroarylene group;
n1 is an integer of 0 to 6, and when n1 is an integer of 2 or greater, a plurality of L₁s are identical to or different to each other, and are optionally linked to each other to form a substituted or unsubstituted C₆-C₂₀ saturated ring or a substituted or unsubstituted C₆-C₂₀ unsaturated ring;
Z₁, Z₂, R₁, and R₂ are each independently selected from a hydrogen, a deuterium, —F, —Cl, —Br, —I, a hydroxyl group, a cyano group, a nitro group, an amino group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₃-C₃₀ cycloalkyl group, a substituted or unsubstituted C₃-C₃₀ cycloalkenyl group, a substituted or unsubstituted C₆-C₃₀ aryl group, a substituted or unsubstituted C₆-C₃₀ aryloxy group, a substituted or unsubstituted C₆-C₃₀ arylthio group, and a substituted or unsubstituted C₁-C₃₀ heteroaryl group; and R₁ and R₂ are optionally linked to each other to form a substituted or unsubstituted C₆-C₂₀ saturated ring, or a substituted or unsubstituted C₆-C₂₀ unsaturated ring; and Z₁ and Z₂ are optionally linked to each other to form a substituted or unsubstituted C₆-C₂₀ saturated ring or a substituted or unsubstituted C₆-C₂₀ unsaturated ring;
R₃, R₄, and Q₁ to Q₃ are each independently selected from a hydrogen, a deuterium, —F, —Cl, —Br, —I, a hydroxyl group, a cyano group, a nitro group, an amino group, a carboxyl group, a substituted or unsubstituted C₁-C₃₀ alkyl group, a substituted or unsubstituted C₂-C₃₀ alkenyl group, a substituted or unsubstituted C₂-C₃₀ alkynyl group, a substituted or unsubstituted C₁-C₃₀ alkoxy group, a substituted or unsubstituted C₃-C₃₀ cycloalkyl group, a substituted or unsubstituted C₃-C₃₀ cycloalkenyl group, a substituted or unsubstituted C₆-C₃₀ aryl group, a substituted or unsubstituted C₆-C₃₀ aryloxy group, a substituted or unsubstituted C₆-C₃₀ arylthio group, and a substituted or unsubstituted C₁-C₃₀ heteroaryl group; and
a1 and a2 are each independently an integer of 0 to 3.

2. The compound of claim 1, wherein L₁ is selected from
a phenylene group, an anthracenyl group, a fluorenylene group, a chrysenylene group, and a pyrenylene group; and
a phenylene group, an anthracenyl group, a fluorenylene group, a chrysenylene group, and a pyrenylene group, each substituted with at least one selected from
a deuterium, —F, —Cl, —Br, —I, a hydroxyl group, a cyano group, a nitro group, a methyl group, an ethyl group, an n-propyl group, an iso-propyl group, an n-butyl group, a sec-butyl group, an iso-butyl group, and a tert-butyl group,
a phenyl group, a naphthyl group, a pyridyl group, and a triazinyl group, and
a phenyl group, a naphthyl group, a pyridyl group, and a triazinyl group, each substituted with at least one of a deuterium, —F, —Cl, —Br, —I, a hydroxyl group, a cyano group, a nitro group, a methyl group, an ethyl group, an n-propyl group, an iso-propyl group, an n-butyl group, a sec-butyl group, an iso-butyl group, and a tert-butyl group.

3. The compound of claim 1, wherein L₁ is selected from a phenylene group, an anthracenyl group, a chrysenylene group, and a pyrenylene group.

4. The compound of claim 1, wherein Z₁ to Z₂ are each independently selected from
a hydrogen, a deuterium, —F, —Cl, —Br, —I, a cyano group, a nitro group, a methyl group, an ethyl group, an n-propyl group, an iso-propyl group, an n-butyl group, a sec-butyl group, an iso-butyl group, and a tert-butyl group,
a methyl group, an ethyl group, an n-propyl group, an iso-propyl group, an n-butyl group, a sec-butyl group, an iso-butyl group, and a tert-butyl group, each substituted with at least one of a deuterium, —F, —Cl, —Br, —I, a cyano group, and a nitro group,
a phenyl group, a naphthyl group, an anthryl group, a pyridyl group, a pyrimidyl group, and a triazinyl group, and
a phenyl group, a naphthyl group, an anthryl group, a pyridyl group, a pyrimidyl group, and a triazinyl group, each substituted with at least one of a deuterium, —F, —Cl, —Br, —I, a cyano group, a nitro group, a methyl group, an ethyl group, an n-propyl group, an iso-propyl group, an n-butyl group, a sec-butyl group, an iso-butyl group, and a tert-butyl group; and
Z₁ and Z₂ are optionally linked to each other to form a benzene ring, a naphthalene ring, or an anthracene ring, each substituted with at least one of a deuterium, —F, —Cl, —Br, —I, a cyano group, a nitro group, a methyl group, an ethyl group, an n-propyl group, an iso-propyl group, an n-butyl group, a sec-butyl group, an iso-butyl group, and a tert-butyl group.

5. The compound of claim 1, wherein Z₁ to Z₂ are each independently selected from
a hydrogen, a cyano group, and a methyl group,
a phenyl group and a pyridyl group, and
a phenyl group and a pyridyl group, each substituted with at least one of a deuterium, a cyano group, and a methyl group; and
Z₁ and Z₂ are optionally linked to each other to form a benzene ring substituted with at least one of a deuterium, a cyano group, and a methyl group.

6. The compound of claim 1, wherein R₁ and R₂ are each independently selected from a hydrogen, a deuterium, —F, —Cl, —Br, —I, a hydroxyl group, a cyano group, a nitro group, a substituted or unsubstituted C₁-C₁₀ alkyl group, and a substituted or unsubstituted C₆-C₁₆ aryl group; and R₁ and R₂ are optionally linked to each other to form a substituted or unsubstituted C₆-C₂₀ saturated ring or a substituted or unsubstituted C₆-C₂₀ unsaturated ring.

7. The compound of claim 1, wherein R₁ and R₂ are each independently selected from a hydrogen, a deuterium, —F, a hydroxyl group, a cyano group, a nitro group, a methyl group, an ethyl group, an n-propyl group, an iso-propyl group, a tert-butyl group, a phenyl group, and a naphthyl group; and R₁ and R₂ are optionally linked to each other to form an unsubstituted C₆-C₂₀ saturated ring or an unsubstituted C₆-C₂₀ unsaturated ring.

8. The compound of claim 1, wherein R₁ and R₂ are each independently selected from a hydrogen, a deuterium, a methyl group, a phenyl group, and a group represented by Formula 5: 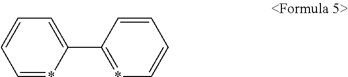
wherein, in Formula 5, * indicates a binding site to an indene-based core.

9. The compound of claim 1, wherein R₃ is selected from
a hydrogen, a deuterium, —F, —Cl, —Br, —I, a hydroxyl group, a cyano group, a nitro group, a methyl group, an ethyl group, an n-propyl group, an iso-propyl group, an n-butyl group, a sec-butyl group, an iso-butyl group, and a tert-butyl group;
a phenyl group, a naphthyl group, a pyridyl group, and a triazinyl group; and
a phenyl group, a naphthyl group, a pyridyl group, and a triazinyl group, each substituted with at least one selected from a deuterium, —F, —Cl, —Br, —I, a hydroxyl group, a cyano group, a nitro group, a methyl group, an ethyl group, an n-propyl group, an iso-propyl group, an n-butyl group, a sec-butyl group, an iso-butyl group, and a tert-butyl group.

10. The compound of claim 1, wherein
R₄ is selected from
a phenyl group, a pentalenyl group, an indenyl group, a naphthyl group, an azulenyl group, a heptalenyl group, an indacenyl group, an acenaphtyl group, a fluorenyl group, a spiro-fluorenyl group, a phenalenyl group, a phenanthrenyl group, an anthryl group, a fluoranthenyl group, a triphenylenyl group, a pyrenyl group, a chrysenyl group, a naphthacenyl group, a picenyl group, a perylenyl group, a pentaphenyl group, a hexacenyl group, a pyrrolyl group, an imidazolyl group, a pyrazolyl group, a pyridyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a benzooxazolyl group, a dibenzofuranyl group, a dibenzothiophenyl group, and a benzocarbazolyl group; and
a phenyl group, a pentalenyl group, an indenyl group, a naphthyl group, an azulenyl group, a heptalenyl group, an indacenyl group, an acenaphtyl group, a fluorenyl group, a spiro-fluorenyl group, a phenalenyl group, a phenanthrenyl group, an anthryl group, a fluoranthenyl group, a triphenylenyl group, a pyrenyl group, a chrysenyl group, a naphthacenyl group, a picenyl group, a perylenyl group, a pentaphenyl group, a hexacenyl group, a pyrrolyl group, an imidazolyl group, a pyrazolyl group, a pyridyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzimidazolyl group, a furanyl group, a benzofuranyl group, a thiophenyl group, a benzothiophenyl group, a thiazolyl group, an isothiazolyl group, a benzothiazolyl group, an isoxazolyl group, an oxazolyl group, a triazolyl group, a tetrazolyl group, an oxadiazolyl group, a triazinyl group, a benzooxazolyl group, a dibenzofuranyl group, a dibenzothiophenyl group, and a benzocarbazolyl group, each substituted with at least one of a deuterium, —F, —Cl, —Br, —I, a hydroxyl group, a cyano group, a nitro group, an amino group, an amidino group, a hydrazine, a hydrazone, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀alkynyl group, a substituted or unsubstituted alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁₀heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, and a substituted or unsubstituted C₁-C₆₀ heteroaryl group.

11. The compound of claim 1, wherein R₄ is selected from
a phenyl group, a naphthyl group, and an anthryl group; and
a phenyl group, a naphthyl group, and an anthryl group, each substituted with at least one of a deuterium, —F, —Cl, —Br, —I, a hydroxyl group, a cyano group, a nitro group, a methyl group, an ethyl group, an n-butyl group, an iso-propyl group, a tert-butyl group, a phenyl group, a naphthyl group, and an anthryl group.

12. The compound of claim 1, wherein R₄ is a group represented by one of Formulae 4-1 to 4-9:

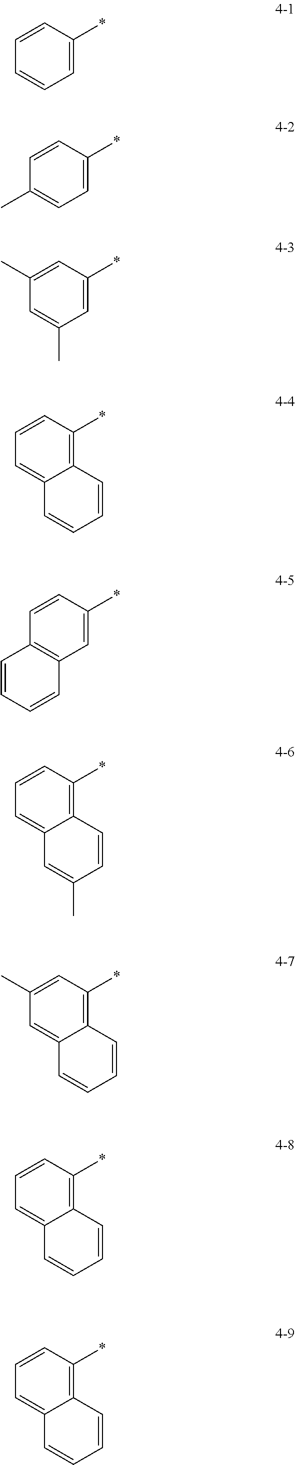

13. The compound of claim 1, wherein Q₁ to Q₃ are each independently selected from a hydrogen, a deuterium, —F, —Cl, —Br, —I, a hydroxyl group, a cyano group, a nitro group, an amino group, a carboxyl group, a methyl group, an ethyl group, and a phenyl group.

14. The compound of claim 1, wherein the compound of Formula 1 is represented by Formula 1a or 1b: 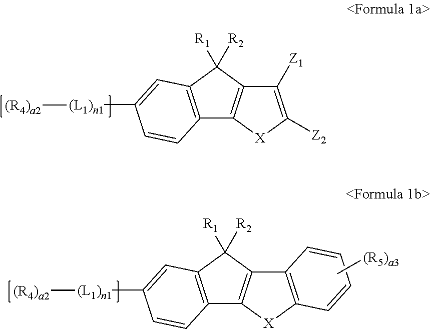
wherein,
X is an oxygen atom, a sulfur atom, N(Q₁), or C(Q₂)(Q₃);
Z₁ to Z₂ are each independently selected from
a hydrogen, a cyano group, and a methyl group,
a phenyl group and a pyridyl group, and
a phenyl group and a pyridyl group, each substituted with at least one of a deuterium, a cyano group, and a methyl group; and
(L₁)ₙ₁ is a moiety represented by one of Formulae 3-1 to 3-4, 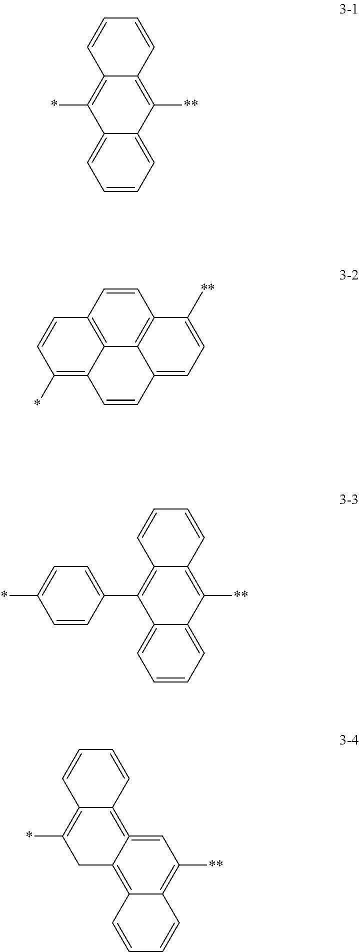
wherein, in Formulae 3-1 to 3-4,
* indicates a binding site with R₄;
** indicates a binding site with an indene-based core; and
R₁ and R₂ are each independently selected from a hydrogen, a deuterium, a methyl group, a phenyl group, and a group represented by Formula 5: 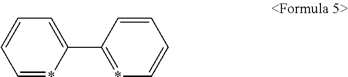
wherein, in Formula 5,
* indicates a binding site with an indene-based core;
R₄ is a group represented by one of Formulae 4-1 to 4-9; 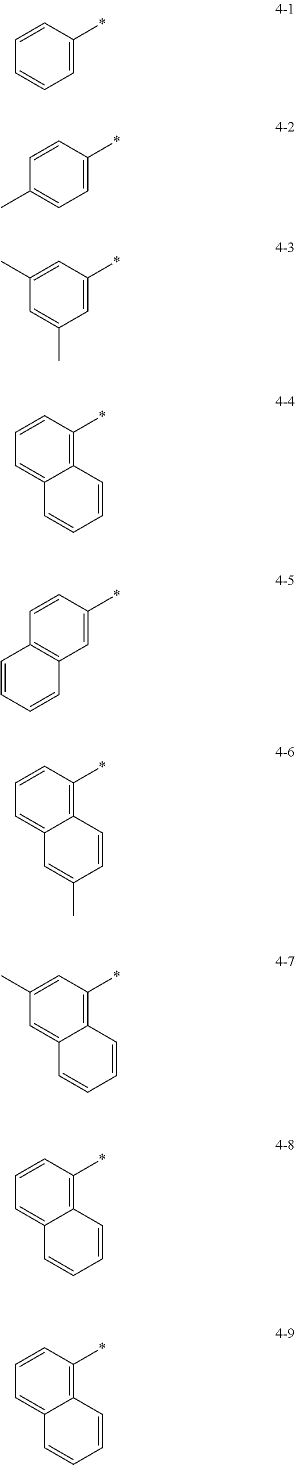
R₅ is selected from a hydrogen, a deuterium, a cyano group, and a methyl group;
a3 is an integer of 0 to 2; and
Q₁ to Q₃ are each independently selected from a hydrogen, a deuterium, —F, —Cl, —Br, —I, a hydroxyl group, a cyano group, a nitro group, an amino group, a carboxyl group, a methyl group, an ethyl group, and a phenyl group.

15. The compound of claim 1, wherein the compound of Formula 1 is one of Compounds 1 to 75:

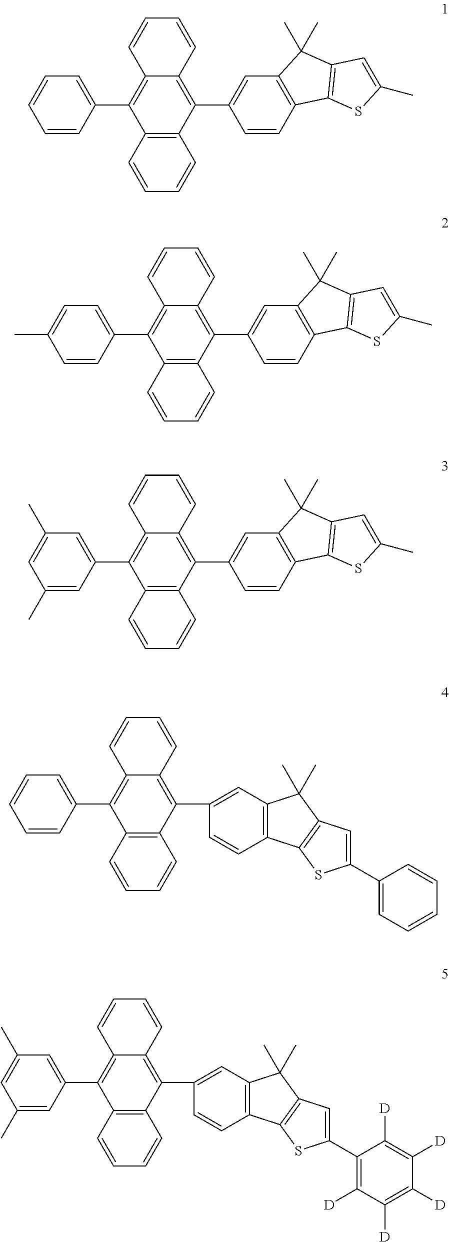

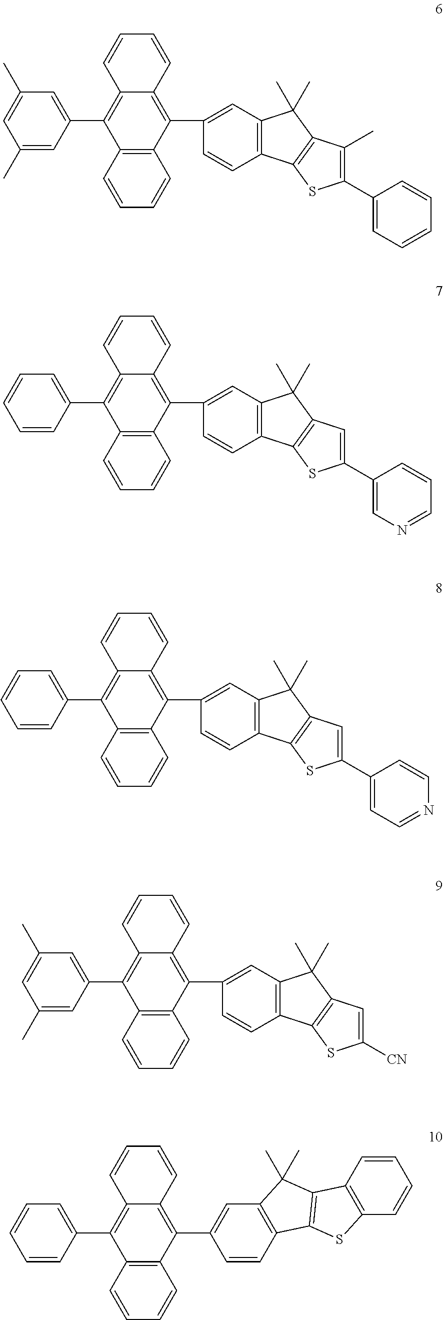 [SMILES: Cc1cc(C)cc(-c2c3ccccc3c(-c3ccc4c(c3)C(C)(C)c3c-4sc(-c4ccccc4)c3C)c3ccccc23)c1 ; CC1(C)c2cc(-c3c4ccccc4c(-c4ccccc4)c4ccccc34)ccc2-c2sc(-c3cccnc3)cc21 ; CC1(C)c2cc(-c3c4ccccc4c(-c4ccccc4)c4ccccc34)ccc2-c2sc(-c3ccncc3)cc21 ; Cc1cc(C)cc(-c2c3ccccc3c(-c3ccc4c(c3)C(C)(C)c3cc(C#N)sc3-4)c3ccccc23)c1 ; CC1(C)c2cc(-c3c4ccccc4c(-c4ccccc4)c4ccccc34)ccc2-c2sc3ccccc3c21]

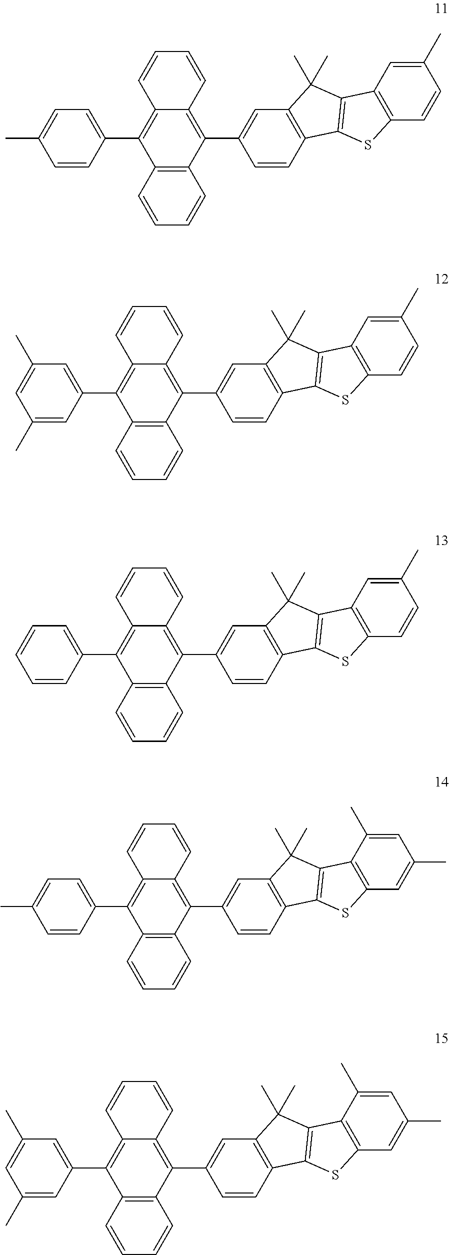

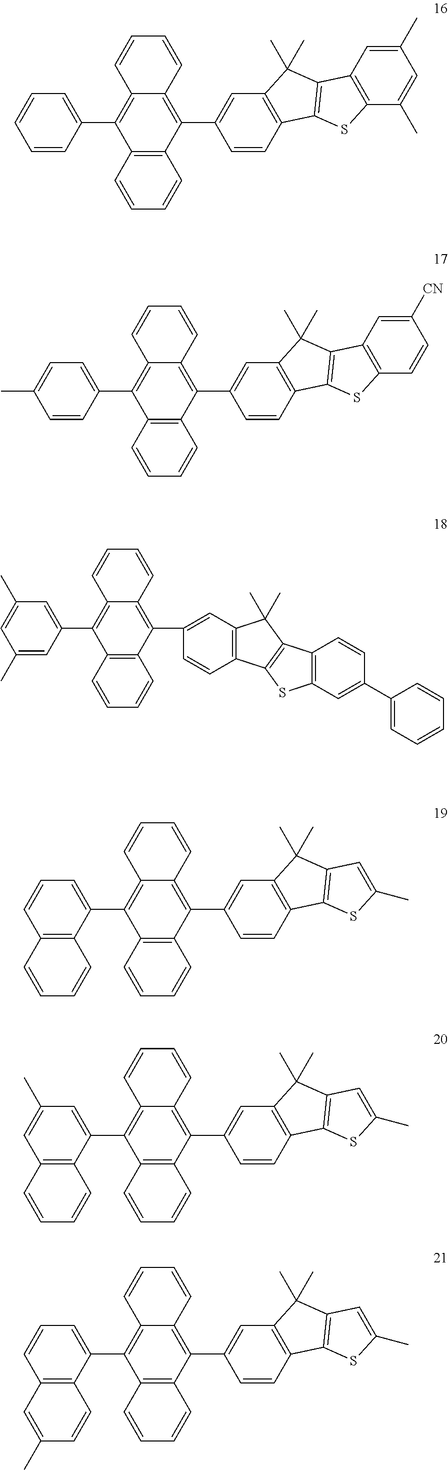

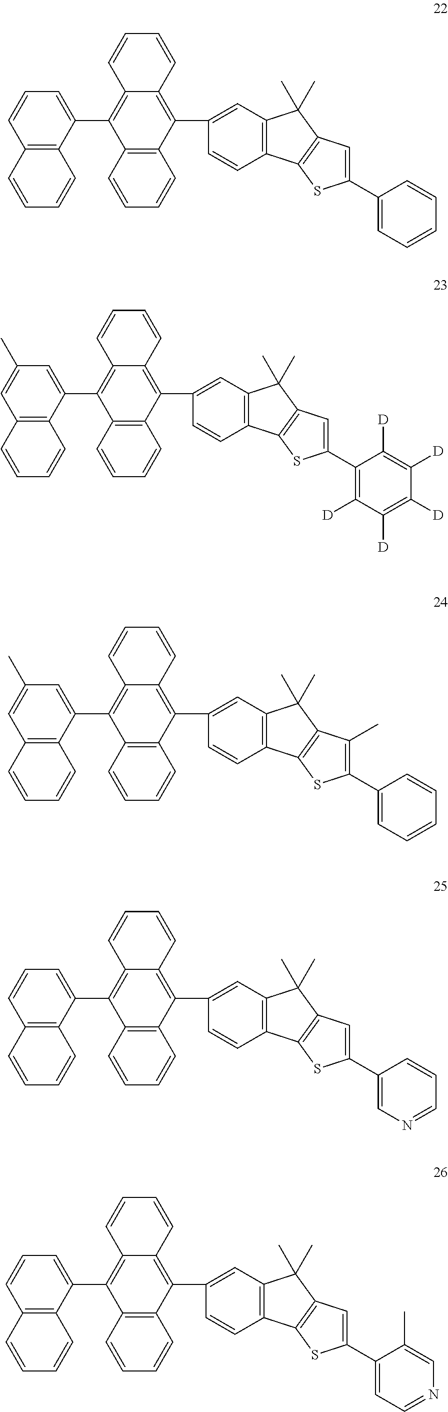 [SMILES: CC1(C)c2cc(-c3c4ccccc4c(-c4cccc5ccccc45)c4ccccc34)ccc2-c2sc(-c3ccccc3)cc21 ; [2H]c1c([2H])c([2H])c(-c2cc3c(s2)-c2ccc(-c4c5ccccc5c(-c5cc(C)cc6ccccc56)c5ccccc45)cc2C3(C)C)c([2H])c1[2H] ; Cc1cc(-c2c3ccccc3c(-c3ccc4c(c3)C(C)(C)c3c-4sc(-c4ccccc4)c3C)c3ccccc23)c2ccccc2c1 ; CC1(C)c2cc(-c3c4ccccc4c(-c4cccc5ccccc45)c4ccccc34)ccc2-c2sc(-c3cccnc3)cc21 ; Cc1cnccc1-c1cc2c(s1)-c1ccc(-c3c4ccccc4c(-c4cccc5ccccc45)c4ccccc34)cc1C2(C)C]

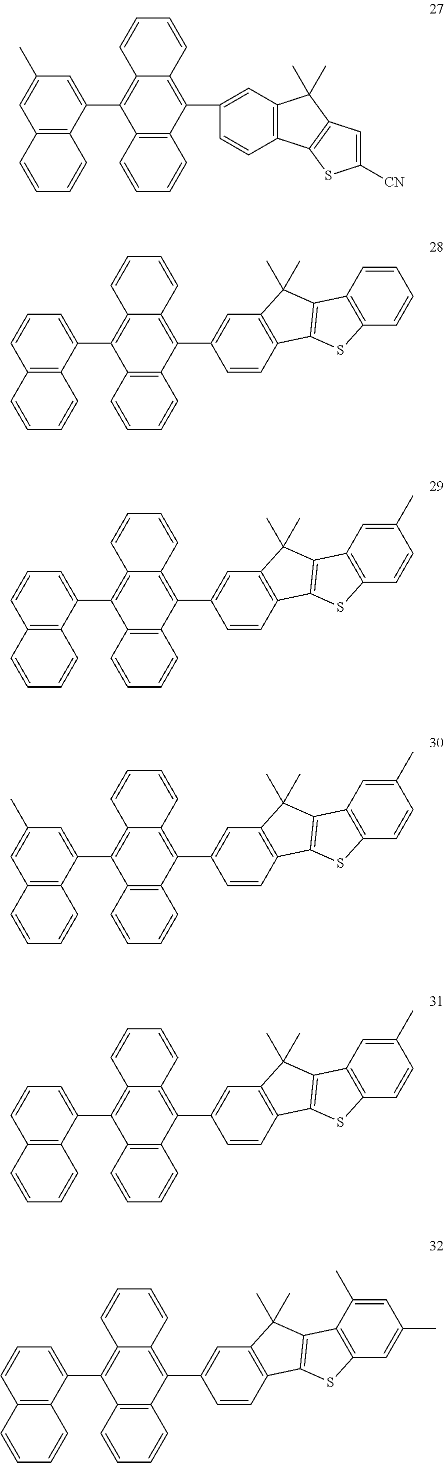 [SMILES: Cc1cc(-c2c3ccccc3c(-c3ccc4c(c3)C(C)(C)c3cc(C#N)sc3-4)c3ccccc23)c2ccccc2c1 ; CC1(C)c2cc(-c3c4ccccc4c(-c4cccc5ccccc45)c4ccccc34)ccc2-c2sc3ccccc3c21 ; Cc1ccc2sc3c(c2c1)C(C)(C)c1cc(-c2c4ccccc4c(-c4cccc5ccccc45)c4ccccc24)ccc1-3 ; Cc1cc(-c2c3ccccc3c(-c3ccc4c(c3)C(C)(C)c3c-4sc4ccc(C)cc34)c3ccccc23)c2ccccc2c1 ; Cc1ccc2sc3c(c2c1)C(C)(C)c1cc(-c2c4ccccc4c(-c4cccc5ccccc45)c4ccccc24)ccc1-3 ; Cc1cc(C)c2c3c(sc2c1)-c1ccc(-c2c4ccccc4c(-c4cccc5ccccc45)c4ccccc24)cc1C3(C)C]

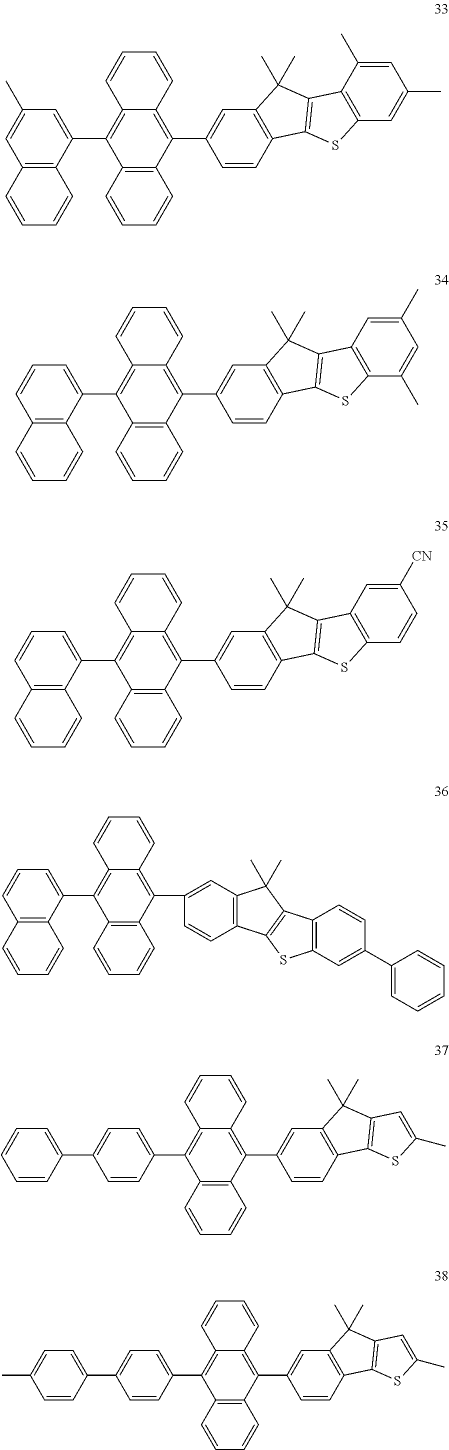

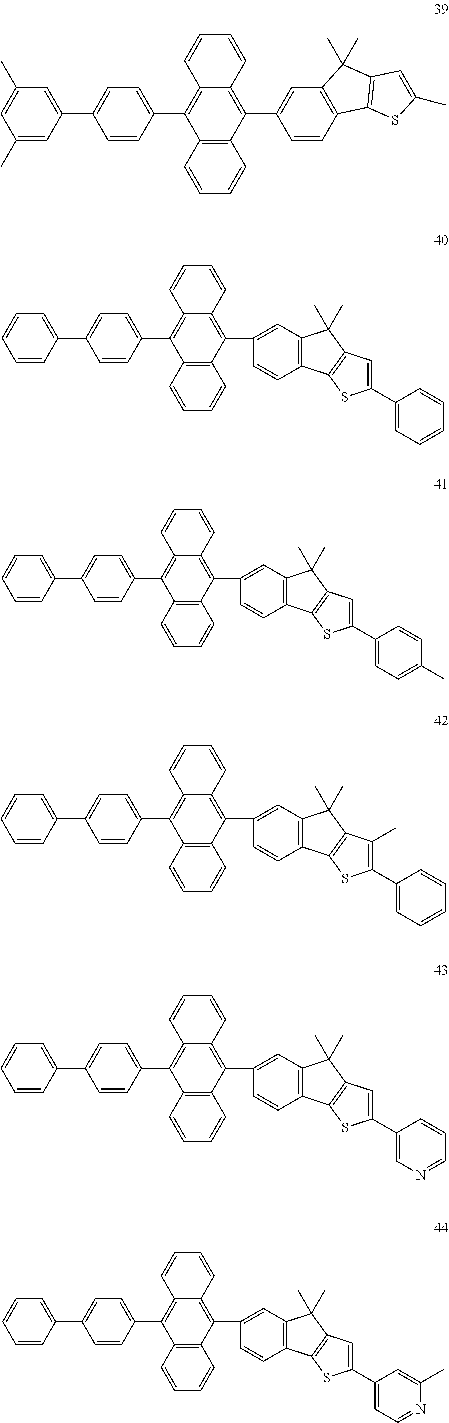 [SMILES: Cc1cc(C)cc(-c2ccc(-c3c4ccccc4c(-c4ccc5c(c4)C(C)(C)c4cc(C)sc4-5)c4ccccc34)cc2)c1 ; CC1(C)c2cc(-c3c4ccccc4c(-c4ccc(-c5ccccc5)cc4)c4ccccc34)ccc2-c2sc(-c3ccccc3)cc21 ; Cc1ccc(-c2cc3c(s2)-c2ccc(-c4c5ccccc5c(-c5ccc(-c6ccccc6)cc5)c5ccccc45)cc2C3(C)C)cc1 ; Cc1c(-c2ccccc2)sc2c1C(C)(C)c1cc(-c3c4ccccc4c(-c4ccc(-c5ccccc5)cc4)c4ccccc34)ccc1-2 ; CC1(C)c2cc(-c3c4ccccc4c(-c4ccc(-c5ccccc5)cc4)c4ccccc34)ccc2-c2sc(-c3cccnc3)cc21 ; Cc1cc(-c2cc3c(s2)-c2ccc(-c4c5ccccc5c(-c5ccc(-c6ccccc6)cc5)c5ccccc45)cc2C3(C)C)ccn1]

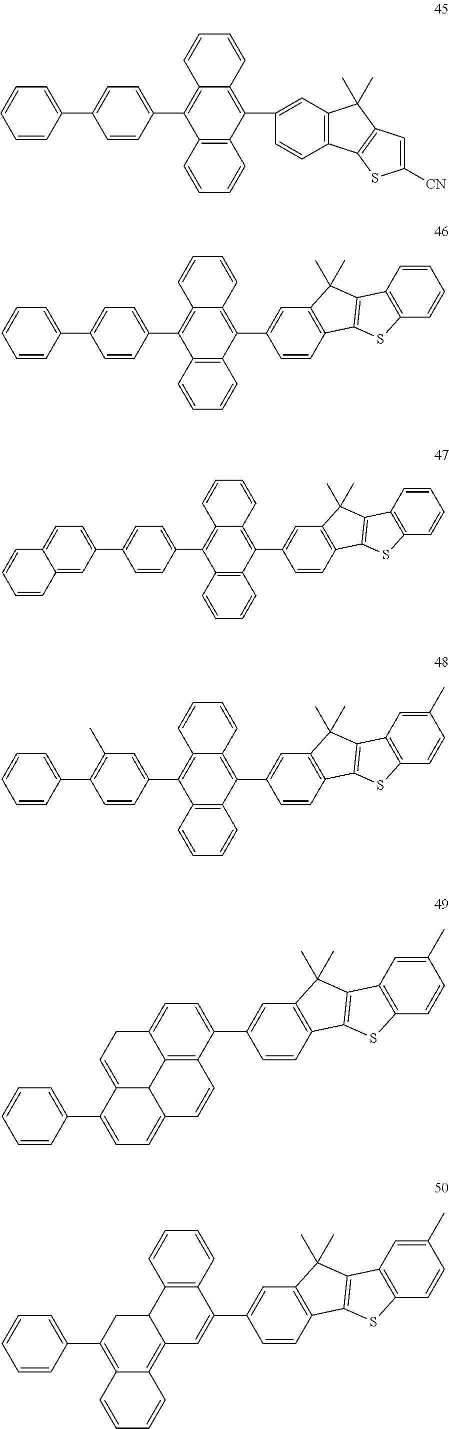 [SMILES: CC1(C)c2cc(-c3c4ccccc4c(-c4ccc(-c5ccccc5)cc4)c4ccccc34)ccc2-c2sc(C#N)cc21 ; CC1(C)c2cc(-c3c4ccccc4c(-c4ccc(-c5ccccc5)cc4)c4ccccc34)ccc2-c2sc3ccccc3c21 ; CC1(C)c2cc(-c3c4ccccc4c(-c4ccc(-c5ccc6ccccc6c5)cc4)c4ccccc34)ccc2-c2sc3ccccc3c21 ; Cc1ccc2sc3c(c2c1)C(C)(C)c1cc(-c2c4ccccc4c(-c4ccc(-c5ccccc5)c(C)c4)c4ccccc24)ccc1-3 ; Cc1ccc2sc3c(c2c1)C(C)(C)c1cc(-c2ccc4c5c2C=CC2=CC=C(c6ccccc6)C(=CC4)C25)ccc1-3 ; Cc1ccc2sc3c(c2c1)C(C)(C)c1cc(C2=CC4=c5ccccc5=C(c5ccccc5)CC4c4ccccc42)ccc1-3]

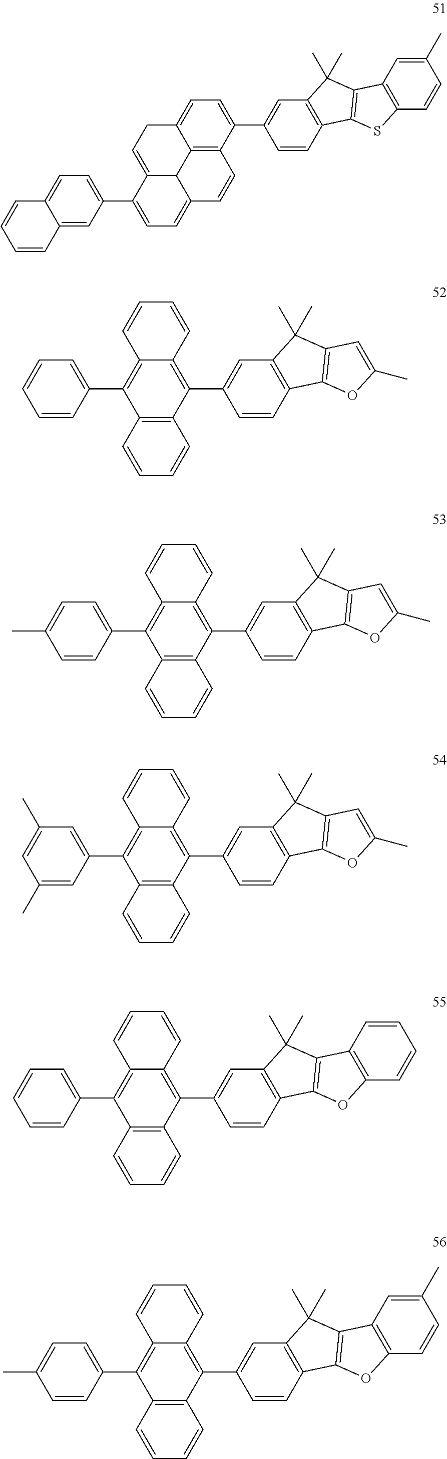

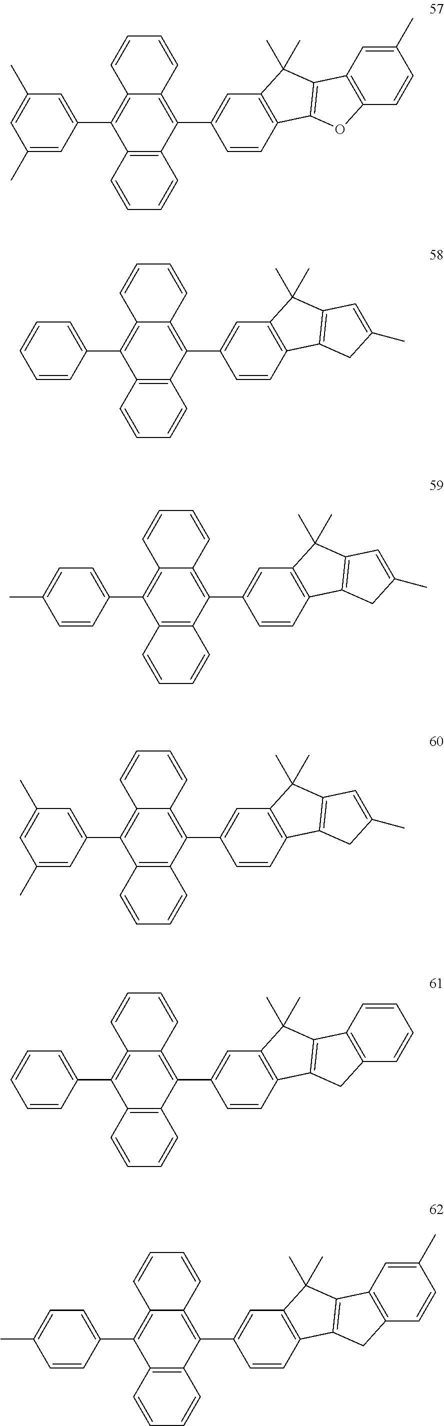

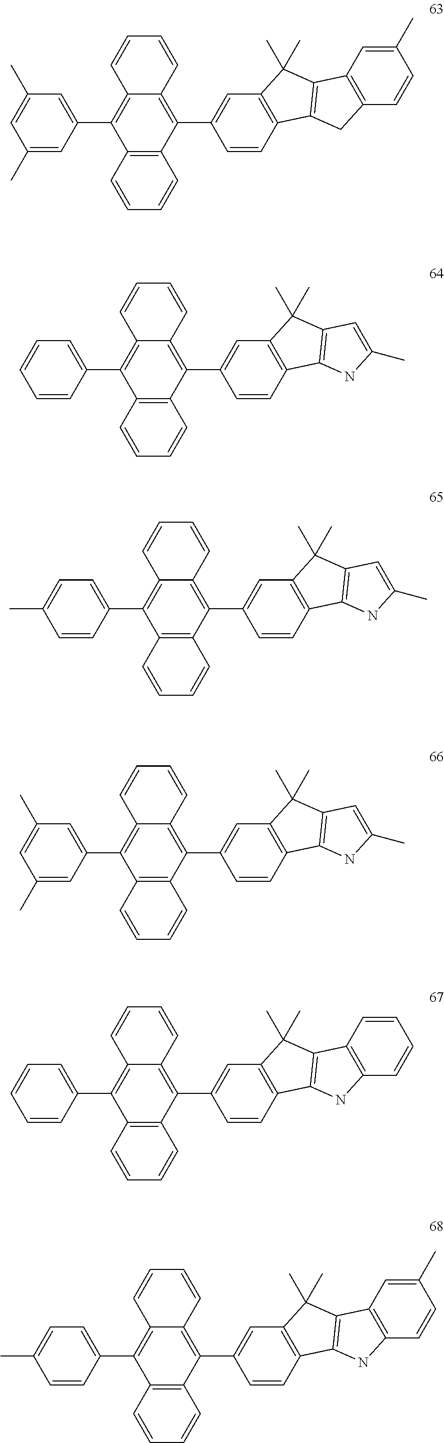

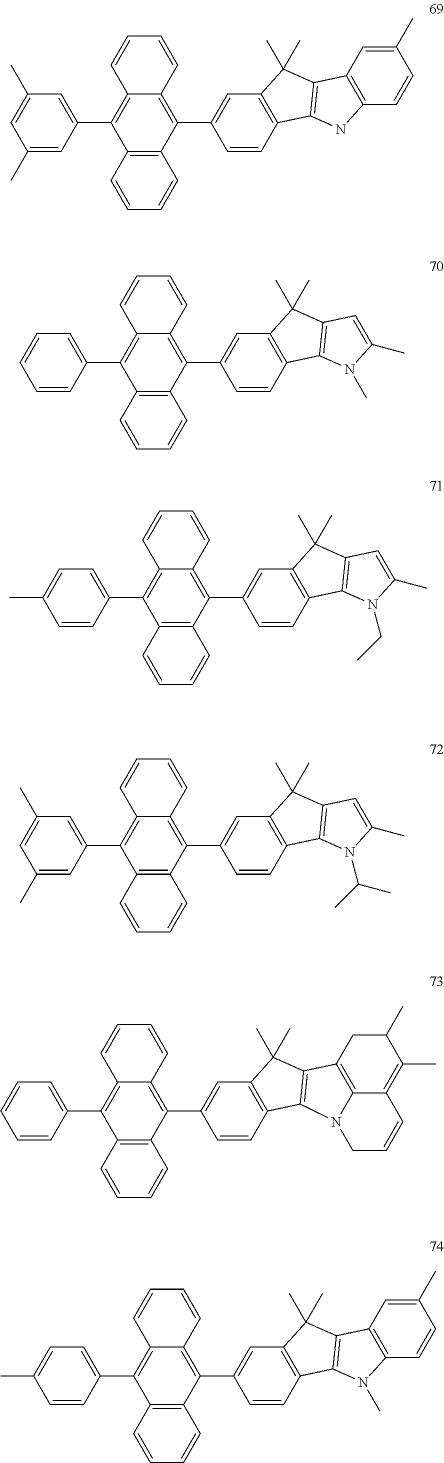

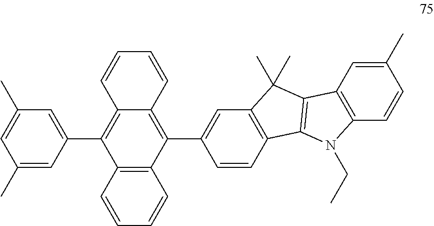 [SMILES: CCn1c2c(c3cc(C)ccc31)C(C)(C)c1cc(-c3c4ccccc4c(-c4cc(C)cc(C)c4)c4ccccc34)ccc1-2]

16. An organic light-emitting device comprising: a first electrode; a second electrode disposed opposite to the first electrode; and an organic layer disposed between the first electrode and the second electrode and comprising an emission layer, wherein the organic layer comprises at least one of the indene-based compounds of claim 1.

17. The organic light-emitting device of claim 16, wherein the organic layer comprises a hole transport region between the first electrode and the emission layer, and an electron transport region between the emission layer and the second electrode, the hole transport region comprising at least one of a hole injection layer, a hole transport layer, a functional layer having both hole injection and hole transport capabilities, a buffer layer, an electron blocking layer, and the electron transport region comprising at least one of a hole blocking layer, an electron transport layer, and an electron injection layer.

18. The organic light-emitting device of claim 16, wherein the emission layer comprises the indene-based compound.

19. The organic light-emitting device of claim 18, wherein the emission layer further comprises a dopant, and the indene-based compound is a host.

20. The organic light-emitting device of claim 18, wherein the indene-based compound is a blue host.
